(19) United States
(12) Patent Application Publication
(10) Pub. No.: US 2025/0324726 A1
(43) Pub. Date: Oct. 16, 2025

(54) SEMICONDUCTOR DEVICE AND STORAGE DEVICE

(71) Applicant: Semiconductor Energy Laboratory Co., Ltd., Atsugi-shi, Kanagawa-ken (JP)

(72) Inventors: Hitoshi KUNITAKE, Machida (JP); Hiromi SAWAI, Atsugi (JP); Shiyuu NUMATA, Atsugi (JP); Kazuaki OHSHIMA, Atsugi (JP)

(21) Appl. No.: 18/872,982

(22) PCT Filed: Jun. 2, 2023
(86) PCT No.: PCT/IB2023/055668

§ 371 Date: Dec. 9, 2024

(30) Foreign Application Priority Data
Jun. 17, 2022 (JP) 2022-098103
Jul. 14, 2022 (JP) 2022-113447
May 2, 2023 (JP) 2023-076110

(51) Int. Cl. H10D 64/68; H10B 53/10; H10B 53/20; H10D 30/67

(52) U.S. Cl. CPC H10D 64/693; H10B 53/10; H10B 53/20; H10D 30/6755; H10D 30/6757; H10D 64/691

(57) ABSTRACT

A semiconductor device having favorable electrical characteristics is provided. The semiconductor device includes a first stack, a semiconductor layer including a channel formation region under the first stack, and a second stack under the semiconductor layer. The first stack and the second stack each include at least a first insulator and a second insulator. In this case, the first insulator of the first stack and the first insulator of the second stack include a region where they overlap with each other with the channel formation region therebetween, and the second insulator of the first stack and the second insulator of the second stack include a region where they overlap with each other with the first insulator of the first stack, the channel formation region, and the first insulator of the second stack therebetween. The first insulator of the first stack and the first insulator of the second stack have a common function, and the second insulator of the first stack and the second insulator of the second stack have a common function.

### TECHNICAL FIELD

One embodiment of the present invention relates to a semiconductor device, a storage device, and an electronic appliance. Another embodiment of the present invention relates to methods for fabricating a semiconductor device and a storage device.

Note that one embodiment of the present invention is not limited to the above technical field. Examples of the technical field of one embodiment of the present invention include a semiconductor device, a display device, a light-emitting device, a power storage device, a storage device, an electronic appliance, a lighting device, an input device (e.g., a touch sensor), an input/output device (e.g., a touch panel), a method for driving any of them, and a method for manufacturing any of them.

Note that in this specification and the like, a semiconductor device refers to a general device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an imaging device, an electronic appliance, and the like include a semiconductor device.

### BACKGROUND ART

In recent years, semiconductor devices have been developed; an LSI (Large Scale Integration), a CPU (Central Processing Unit), a memory, and the like have been mainly used for semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. As another example, Patent Document 2 discloses a storage device that can retain stored contents for a long time by utilizing the feature of the low leakage current of the transistor using an oxide semiconductor.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

### Problems to be Solved by the Invention

One object of one embodiment of the present invention is to provide a semiconductor device having favorable electrical characteristics. Another object is to provide a highly reliable semiconductor device. Another object is to provide a semiconductor device with a small variation in electrical characteristics of transistors. Another object is to provide a semiconductor device that can be miniaturized or highly integrated. Another object is to provide a semiconductor device with a high operation speed. Another object is to provide a semiconductor device with a high on-state current. Another object is to provide a semiconductor device with low power consumption. Another object is to provide a novel semiconductor device. Another object is to provide a method for fabricating a semiconductor device with high productivity. Another object is to provide a method for fabricating a novel semiconductor device.

Another object of one embodiment of the present invention is to provide a storage device with a large storage capacity. Another object is to provide a storage device with a high operation speed. Another object is to provide a storage device with low power consumption. Another object is to provide a novel storage device. Another object is to provide a method for fabricating a novel storage device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a first stack, a semiconductor layer under the first stack, and a second stack under the semiconductor layer. The semiconductor layer includes a first region, and a second region and a third region that are provided such that the first region is sandwiched therebetween. The first stack and the second stack are provided symmetrically with respect to the first region. The first stack includes a first insulator and a second insulator over the first insulator. The second stack includes a third insulator and a fourth insulator under the third insulator. The second insulator is less permeable to hydrogen than the first insulator is. The fourth insulator is less permeable to hydrogen than the third insulator is. The first insulator and the third insulator each contain silicon and oxygen. The second insulator and the fourth insulator each contain silicon and nitrogen.

In the above semiconductor device, it is preferable that the third insulator have an island shape, and a side end portion of the third insulator be aligned with a side end portion of the semiconductor layer in a cross-sectional view.

In the above semiconductor device, it is preferable that the first stack further include a fifth insulator under the first insulator, the second stack further include a sixth insulator over the third insulator, the fifth insulator be less permeable to oxygen than the first insulator is, the sixth insulator be less permeable to oxygen than the second insulator is, and the fifth insulator and the sixth insulator each contain aluminum.

In the above semiconductor device, it is preferable that the third insulator and the sixth insulator form a stacked-layer structure, the stacked-layer structure have an island shape, and a side end portion of the stacked-layer structure be aligned with a side end portion of the semiconductor layer in a cross-sectional view.

Another embodiment of the present invention is a semiconductor device including a first stack, a semiconductor layer under the first stack, and a second stack under the semiconductor layer. The semiconductor layer includes a first region, and a second region and a third region that are provided such that the first region is sandwiched therebetween. The first stack and the second stack are provided symmetrically with respect to the first region. The first stack includes a first insulator, a second insulator over the first insulator, and a third insulator over the second insulator. The second stack includes a first metal oxide, a fourth insulator under the first metal oxide, and a fifth insulator under the fourth insulator. The first insulator is less permeable to oxygen than the second insulator is. The third insulator is less permeable to hydrogen than the second insulator is. The first metal oxide is less permeable to oxygen than the fourth insulator is. The fifth insulator is less permeable to hydrogen than the fourth insulator is. The first insulator and the first metal oxide each contain at least one of gallium and aluminum. The second insulator and the fourth insulator each contain silicon and oxygen. The third insulator and the fifth insulator each contain silicon and nitrogen.

In the above semiconductor device, it is preferable that the semiconductor layer include a second metal oxide, the first metal oxide and the second metal oxide each contain indium, and an atomic ratio of at least one of gallium and aluminum to indium in the first metal oxide be higher than an atomic ratio of at least one of gallium and aluminum to indium in the second metal oxide.

It is preferable that the above semiconductor device further include a sixth insulator between the fourth insulator and the fifth insulator and the sixth insulator have a function of capturing or fixing hydrogen.

It is preferable that the above semiconductor device further include a seventh insulator between the second insulator and the third insulator and the seventh insulator have a function of capturing or fixing hydrogen.

It is preferable that the above semiconductor device further include a first conductor and a second conductor, the first conductor be positioned above the first stack, and the second conductor be positioned below the second stack.

It is preferable that the above semiconductor device further include a third conductor and a fourth conductor, the second region overlap with the third conductor, and the third region overlap with the fourth conductor.

Another embodiment of the present invention is a storage device including the above semiconductor device and a capacitor. The capacitor is a ferroelectric capacitor.

### Effect of the Invention

According to one embodiment of the present invention, a semiconductor device having favorable electrical characteristics can be provided. Alternatively, a highly reliable semiconductor device can be provided. Alternatively, a semiconductor device with a small variation in electrical characteristics of transistors can be provided. Alternatively, a semiconductor device that can be miniaturized or highly integrated can be provided. Alternatively, a semiconductor device with a high operation speed can be provided. Alternatively, a semiconductor device with a high on-state current can be provided. Alternatively, a semiconductor device with low power consumption can be provided. Alternatively, a novel semiconductor device can be provided. Alternatively, a method for fabricating a semiconductor device with high productivity can be provided. Alternatively, a method for fabricating a novel semiconductor device can be provided.

According to one embodiment of the present invention, a storage device having a large storage capacity can be provided. Alternatively, a storage device with a high operation speed can be provided. Alternatively, a storage device with low power consumption can be provided. Alternatively, a novel storage device can be provided. Alternatively, a method for fabricating a novel semiconductor device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2A and FIG. 2B are cross-sectional views illustrating an example of a semiconductor device.

FIG. 3A is a top view illustrating an example of a semiconductor device. FIG. 3B and FIG. 3C are cross-sectional views illustrating the example of the semiconductor device.

FIG. 4A to FIG. 4D are cross-sectional views illustrating examples of semiconductor devices.

FIG. 5A to FIG. 5D are cross-sectional views illustrating examples of semiconductor devices.

FIG. 6A is a top view illustrating an example of a semiconductor device. FIG. 6B and FIG. 6C are cross-sectional views illustrating the example of the semiconductor device.

FIG. 7A to FIG. 7D are cross-sectional views illustrating examples of semiconductor devices.

FIG. 8A is a top view illustrating an example of a semiconductor device. FIG. 8B and FIG. 8C are cross-sectional views illustrating the example of the semiconductor device.

FIG. 9A to FIG. 9F are cross-sectional views illustrating examples of semiconductor devices.

FIG. 10A to FIG. 10F are cross-sectional views illustrating examples of semiconductor devices.

FIG. 11A to FIG. 11D are cross-sectional views illustrating examples of semiconductor devices.

FIG. 12A to FIG. 12D are cross-sectional views illustrating examples of semiconductor devices.

FIG. 13A to FIG. 13F are cross-sectional views illustrating examples of semiconductor devices.

FIG. 14A to FIG. 14F are cross-sectional views illustrating examples of semiconductor devices.

FIG. 15A is a top view illustrating an example of a semiconductor device. FIG. 15B to FIG. 15D are cross-sectional views illustrating the example of the semiconductor device.

FIG. 16A and FIG. 16B are cross-sectional views illustrating an example of a semiconductor device.

FIG. 17A and FIG. 17B are cross-sectional views illustrating an example of a semiconductor device.

FIG. 18A and FIG. 18B are cross-sectional views illustrating examples of semiconductor devices.

FIG. 19A is a top view illustrating an example of a semiconductor device. FIG. 19B and FIG. 19C are cross-sectional views illustrating the example of the semiconductor device.

FIG. 20A is a top view illustrating an example of a semiconductor device. FIG. 20B is a cross-sectional view illustrating the example of the semiconductor device.

FIG. 21 is a cross-sectional view illustrating an example of a semiconductor device.

FIG. 22 is a cross-sectional view illustrating an example of a semiconductor device.

FIG. 23A is a top view illustrating an example of a semiconductor device. FIG. 23B is a cross-sectional view illustrating the example of the semiconductor device.

FIG. 24A is a top view illustrating an example of a semiconductor device. FIG. 24B is a cross-sectional view illustrating the example of the semiconductor device.

FIG. 25A is a top view illustrating an example of a semiconductor device. FIG. 25B is a cross-sectional view illustrating the example of the semiconductor device.

FIG. 26 is a cross-sectional view illustrating an example of a storage device.

FIG. 27 is a cross-sectional view illustrating an example of a storage device.

FIG. 28A is a block diagram illustrating a structure example of a storage device of one embodiment of the present invention. FIG. 28B is a perspective view illustrating a structure example of a storage device of one embodiment of the present invention.

FIG. 29A to FIG. 29I are circuit diagrams illustrating structure examples of storage devices of one embodiment of the present invention.

FIG. 30 is a cross-sectional view illustrating an example of a storage device.

FIG. 31A is a diagram illustrating a circuit structure example of a memory cell. FIG. 31B is a graph showing an example of hysteresis characteristics. FIG. 31C is a timing chart showing an example of a method for driving the memory cell.

FIG. 32A and FIG. 32B are schematic views of a semiconductor device of one embodiment of the present invention.

FIG. 33A to FIG. 33E are diagrams for explaining examples of storage devices.

FIG. 34A and FIG. 34B are diagrams illustrating examples of electronic components.

FIG. 35A and FIG. 35B are diagrams illustrating examples of electronic appliances, and FIG. 35C to 35E are diagrams illustrating an example of a large computer.

FIG. 36 is a diagram illustrating an example of a device for space.

FIG. 37 is a diagram illustrating an example of a storage system that can be used in a data center.

FIG. 38 is a diagram showing a GIXRD measurement result.

FIG. 39A and FIG. 39B are diagrams showing the results of surface observation using AFM. FIG. 39C and FIG. 39D are diagrams showing the results of image analysis. FIG. 39E and FIG. 39F are diagrams showing the results of grain size distribution evaluation.

FIG. 40A is a diagram showing an input voltage waveform. FIG. 40B is a diagram showing P-E characteristics.

FIG. 41A is a diagram showing an input voltage waveform. FIG. 41B is a diagram showing endurance characteristics.

FIG. 42A and FIG. 42B are diagrams showing endurance characteristics.

FIG. 43A and FIG. 43B are diagrams illustrating a retention measurement method.

FIG. 44 is a diagram showing the results of retention measurement.

FIG. 45 is a diagram showing J-V characteristics.

FIG. 46 is a cross-sectional STEM image of a fabricated sample.

FIG. 47A is a diagram illustrating a memory cell circuit. FIG. 47B is an optical micrograph.

FIG. 48 is a diagram showing the characteristics of a source follower.

FIG. 49A and FIG. 49B are diagrams illustrating a method for evaluating positive polarization writing and reading.

FIG. 50A and FIG. 50B are diagrams illustrating a method for evaluating positive polarization writing and reading.

FIG. 51 is a diagram showing voltage waveforms.

FIG. 52 is a diagram showing changes in ΔV_{BL}.

FIG. 53 is a diagram showing changes in ΔV_{BL}.

FIG. 54A and FIG. 54B are diagrams showing endurance characteristics.

FIG. 55A and FIG. 55B are diagrams showing the results of retention measurement.

FIG. 56A is a schematic view of a sample, and FIG. 56B is a cross-sectional view of the sample.

FIG. 57 is a cross-sectional STEM image of a fabricated sample.

FIG. 58 is a diagram showing the Id-Vg characteristics of the sample.

FIG. 59 is a diagram showing threshold voltages.

FIG. 60 is a diagram showing the Id-Vg characteristics of the sample.

FIG. 61A is a diagram showing the threshold voltages of the sample. FIG. 61B is a diagram showing the sheet resistances of the sample. FIG. 61C is a diagram showing the contact resistances of the sample.

FIG. 62 is a graph showing the Id-Vg characteristics of the sample.

FIG. 63A to FIG. 63C are diagrams showing the contact resistances of the sample.

FIG. 64A is a circuit diagram illustrating a circuit structure of a sample. FIG. 64B is a diagram showing leakage current measurement results.

FIG. 65A is a circuit diagram illustrating a circuit structure of a sample. FIG. 65B is a circuit diagram showing the Id-V_{CWL} characteristics of the sample. FIG. 65C is a diagram showing the potential Vsh of the sample.

FIG. 66A is a diagram showing the results of a data retention evaluation test on a sample. FIG. 66B is a diagram showing the results of a data rewriting evaluation test on the sample.

FIG. 67A is a diagram showing contact resistances. FIG. 67B is a diagram showing sheet resistances.

FIG. 68 is a cross-sectional STEM image of an example.

FIG. 69A and FIG. 69B are diagrams showing the results of a drain breakdown voltage test.

FIG. 70 is a diagram showing the result of a drain breakdown voltage test.

FIG. 71 is a diagram showing P-V characteristics.

FIG. 72 is a diagram showing endurance characteristics.

FIG. 73 is a diagram showing changes in ΔV_{BL}.

FIG. 74 is a diagram showing the results of retention measurement.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in the structures of the invention described below, the same reference numerals are used in common for the same portions or portions having similar functions in different drawings, and repeated description thereof is omitted. The same hatching pattern is applied to portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances.

The term “opening” includes a groove and a slit, for example. A region where an opening is formed is referred to as an opening portion in some cases.

In the drawings used in embodiments, a sidewall of an insulator in an opening portion in the insulator is illustrated as being substantially perpendicular to a substrate surface or a formation surface, but the sidewall may have a tapered shape.

Note that in this specification and the like, the tapered shape refers to a shape such that at least part of a side surface of a component is inclined to a substrate surface or a formation surface. For example, the tapered shape preferably includes a region where the angle formed between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or substantially flat with slight unevenness.

In this specification and the like, the expression “level with” indicates a structure having the same level from a reference surface (e.g., a flat surface such as a substrate surface) in a cross-sectional view. For example, in a manufacturing process of a semiconductor device, planarization treatment (typically, CMP (Chemical Mechanical Polishing) treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level with” in this specification and the like. For example, the expression “level with” also includes the case where two layers having different levels with respect to the reference surface (here, given as a first layer and a second layer) are provided to have a difference of less than or equal to 20 nm between the top-surface level of the first layer and the top-surface level of the second layer.

In this specification and the like, the expression “end portions are aligned” means that at least outlines of stacked layers partly overlap with each other in a top view. For example, the case of processing an upper layer and a lower layer with the use of the same mask pattern or mask patterns that are partly the same is included. Note that, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

Note that it is generally difficult to clearly differentiate “perfectly aligned” from “substantially aligned”. Therefore, in this specification and the like, the expression “aligned” includes both “perfectly aligned” and “substantially aligned”.

In this specification and the like, leakage current sometimes expresses the same meaning as off-state current. Furthermore, in this specification and the like, the off-state current sometimes refers to current that flows between a source and a drain of a transistor in an off state, for example.

### Embodiment 1

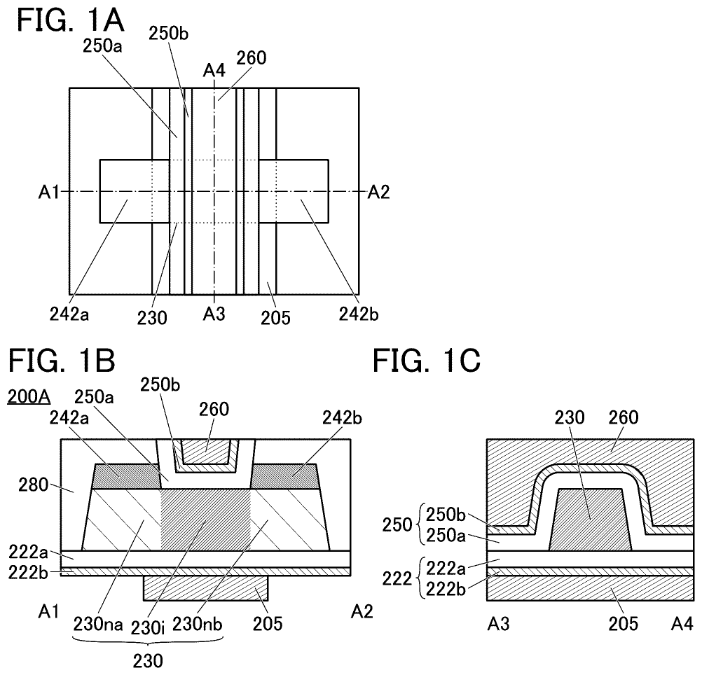

In this embodiment, structure examples of a semiconductor device of one embodiment of the present invention will be described with reference to FIG. 1A to FIG. 25B. Note that the semiconductor device of one embodiment of the present invention includes a transistor.

### Structure Example 1

A structure example of the semiconductor device of one embodiment of the present invention is described with reference to FIG. 1A to FIG. 1C. FIG. 1A is a top view of the semiconductor device, and FIG. 1B and FIG. 1C are cross-sectional views of the semiconductor device. Here, FIG. 1B is a cross-sectional view of a portion indicated by the dashed-dotted line A1-A2 in FIG. 1A. FIG. 1C is a cross-sectional view of a portion indicated by the dashed-dotted line A3-A4 in FIG. 1A. Note that some components are omitted in the top view in FIG. 1A for clarity of the drawing.

The semiconductor device illustrated in FIG. 1A to FIG. 1C includes a transistor 200A. Thus, FIG. 1B can also be referred to as a cross-sectional view of the transistor 200A in the channel length direction. FIG. 1C can also be referred to as a cross-sectional view of the transistor 200A in the channel width direction.

The transistor 200A includes a conductor 205, an insulator 222 (an insulator 222b and an insulator 222a) over the conductor 205, an oxide 230 over the insulator 222, a conductor 242a and a conductor 242b over the oxide 230, an insulator 250 (an insulator 250a and an insulator 250b) over the oxide 230, and a conductor 260 over the insulator 250.

An insulator 280 is provided over the insulator 222, the conductor 242a, and the conductor 242b. The top surface of the insulator 280 may be planarized. The insulator 250 and the conductor 260 are provided to fill an opening portion formed in the insulator 280.

The oxide 230 includes a region functioning as a channel formation region. The conductor 260 includes a region functioning as a first gate electrode (an upper gate electrode). The insulator 250 includes a region functioning as a first gate insulator. The conductor 205 includes a region functioning as a second gate electrode (a lower gate electrode). The insulator 222 includes a region functioning as a second gate insulator. The conductor 242a includes a region functioning as one of a source electrode and a drain electrode. The conductor 242b includes a region functioning as the other of the source electrode and the drain electrode.

Since the oxide 230 includes the region functioning as the channel formation region, the oxide 230 can be rephrased as a semiconductor layer of the transistor 200A in this specification and the like. In addition, the semiconductor layer can be rephrased as the oxide 230.

As illustrated in FIG. 1B, the oxide 230 includes a region 230i, and a region 230na and a region 230nb provided such that the region 230i is sandwiched therebetween. Here, the region 230i functions as the channel formation region. The region 230na functions as one of a source region and a drain region, and the region 230nb functions as the other of the source region and the drain region. At least part of the region 230i overlaps with the conductor 260 and the conductor 205. The region 230na overlaps with the conductor 242a, and the region 230nb overlaps with the conductor 242b.

The region 230i has a smaller amount of oxygen vacancies or a lower concentration of impurities than the region 230na and the region 230nb, and thus is a high-resistance region with a low carrier concentration. Thus, the region 230i can be regarded as being i-type (intrinsic) or substantially i-type.

The region 230na and the region 230nb have a larger amount of oxygen vacancies or a higher concentration of impurities such as hydrogen, nitrogen, and a metal element than the region 230i, and thus are low-resistance regions with a high carrier concentration. In other words, the region 230na and the region 230nb are each an n-type region (a low-resistance region) having a higher carrier concentration than the region 230i.

Note that the carrier concentration of the region 230i is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the region 230i is not particularly limited and can be, for example, 1×10⁻⁹ cm⁻³.

In order to reduce the carrier concentration in the oxide 230, the impurity concentration in the oxide 230 is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration is sometimes referred to as a highly purified intrinsic or substantially highly purified intrinsic oxide semiconductor (or metal oxide).

In order to obtain stable electrical characteristics of the transistor 200A, reducing the impurity concentration in the oxide 230 is effective. In order to reduce the impurity concentration in the oxide 230, it is preferable that the impurity concentration in an adjacent film be also reduced. Examples of impurities include hydrogen, nitrogen, an alkali metal, an alkaline earth metal, iron, nickel, and silicon. Note that an impurity in the oxide 230 refers to, for example, an element other than the main components of the oxide 230. For example, an element with a concentration lower than 0.1 atomic % can be regarded as an impurity.

In the oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, a region closer to the region 230i may have lower concentrations of impurity elements such as hydrogen and nitrogen.

The oxide 230 may have a single-layer structure or a stacked-layer structure.

A metal oxide functioning as a semiconductor (hereinafter also referred to as an oxide semiconductor) is preferably used as the oxide 230.

The metal oxide functioning as a semiconductor preferably has a band gap higher than or equal to 2 eV, further preferably higher than or equal to 2.5 eV. With the use of a metal oxide having a wide band gap, the off-state current of the transistor can be reduced. Such a transistor including a metal oxide in a channel formation region is referred to as an OS transistor. The off-state current of the OS transistor is low, so that power consumption of the semiconductor device can be adequately reduced. The OS transistor has excellent frequency characteristics, which enables the semiconductor device to operate at high speed.

The oxide 230 preferably includes a metal oxide (an oxide semiconductor). Examples of the metal oxide that can be used for the oxide 230 include indium oxide, gallium oxide, and zinc oxide. The metal oxide preferably contains at least indium (In) or zinc (Zn). The metal oxide preferably contains two or three kinds selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, for the oxide 230, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element Min the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

As described above, electrical characteristics and reliability of a transistor vary depending on the composition of the metal oxide used for the oxide 230. Therefore, by changing the composition of the metal oxide in accordance with the electrical characteristics and reliability required for the transistor, the semiconductor device can have both excellent electrical characteristics and high reliability.

Specifically, as the oxide 230, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. It is preferable to use at least one of gallium and aluminum as the element M.

When the metal oxide is deposited by a sputtering method, the above atomic ratio is not limited to the atomic ratio of the deposited metal oxide and may be the atomic ratio of a sputtering target used for depositing the metal oxide.

A transistor using an oxide semiconductor is likely to have its electrical characteristics changed by impurities and oxygen vacancies in a channel formation region in the oxide semiconductor, which might adversely affect the reliability. In some cases, a defect that is an oxygen vacancy into which hydrogen in the vicinity of the oxygen vacancy has entered (hereinafter sometimes referred to as VoH) is formed, which generates an electron serving as a carrier. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and VoH are preferably reduced as much as possible in the channel formation region in the oxide semiconductor. In other words, the channel formation region in the oxide semiconductor is preferably an i-type (intrinsic) or substantially i-type region with a reduced carrier concentration.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the region 230na or the region 230nb might cause a decrease in the on-state current or field-effect mobility of the transistor 200A. Furthermore, a variation of the amount of oxygen supplied to the region 230na or the region 230nb in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the region 230i is preferably an i-type or substantially i-type region with a reduced carrier concentration, whereas the region 230na and the region 230nb are preferably n-type regions with high carrier concentrations. That is, the amounts of oxygen vacancies and VoH in the region 230i are preferably reduced. Supply of an excess amount of oxygen to the region 230na and the region 230nb and excessive reduction in the amount of VoH in the region 230na and the region 230nb are preferably inhibited. Furthermore, a structure is preferable in which a reduction in the conductivity of the conductor 260, the conductor 242a, the conductor 242b, and the like is inhibited. For example, a structure is preferable in which oxidation of the conductor 260, the conductor 242a, the conductor 242b, and the like is inhibited. Note that hydrogen in the oxide semiconductor can form VoH; thus, the hydrogen concentration needs to be reduced in order to reduce the amount of VoH.

Thus, the semiconductor device in this embodiment has a structure in which oxygen is supplied to the region 230i and hydrogen is inhibited from diffusing into the region 230i. The semiconductor device also has a structure in which oxidation of the conductor 242a, the conductor 242b, and the conductor 260 is inhibited. The semiconductor device also has a structure in which the hydrogen concentration in the region 230i is reduced.

In a cross-sectional view of the transistor 200A in the channel width direction, the conductor 260 preferably covers the side surface and the top surface of the oxide 230 as illustrated in FIG. 1C. With such a structure, the channel formation region can be electrically surrounded by the electric field of the gate electrode. Note that in this specification and the like, a transistor structure where a channel formation region is electrically surrounded by at least the electric field of a first gate electrode is referred to as a surrounded channel (S-channel) structure. When the transistor 200A has the S-channel structure, the channel formation region that is formed at the interface between the oxide 230 and the gate insulator or in the vicinity of the interface can correspond to the entire bulk of the oxide 230. Accordingly, the density of current flowing through the transistor can be increased, which can be expected to increase the on-state current of the transistor or increase the field-effect mobility of the transistor.

As described above, the transistor 200A has a structure in which the channel formation region is surrounded by the electric field of the gate electrode. In this regard, a structure is preferable in which oxygen is uniformly supplied to the entire channel formation region (the top surface, the side surface, and the bottom surface of the channel formation region) and hydrogen is inhibited from diffusing thereinto. For example, it is preferable that a first insulator containing a material that is highly permeable to oxygen be provided to surround the channel formation region and a second insulator having a function of inhibiting hydrogen diffusion be further provided to surround the channel formation region and the first insulator. Specifically, it is preferable that first insulators be provided over and under the region 230i and second insulators be further provided over and under the first insulators. Here, the stack of the first insulator over the channel formation region and the second insulator over the first insulator is referred to as a first stack. The stack of the first insulator under the region 230i and the second insulator under the first insulator is referred to as a second stack. In that case, the first stack and the second stack are provided symmetrically with respect to or about the channel formation region. In other words, the first stack and the second stack are provided symmetrically with respect to a plane or a line penetrating the channel formation region. Moreover, the first stack and the second stack are provided symmetrically with the channel formation region serving as the center.

Note that in this specification and the like, a structure in which the first stack and the second stack are provided symmetrically with respect to a component refers to a structure in which the first stack and the second stack are provided such that the component is sandwiched therebetween and in which the stacking order of layers included in the first stack and the stacking order of layers included in the second stack are identical with respect to the component. In other words, the structure refers to a structure in which the first stack and the second stack are provided such that the component is sandwiched therebetween and in which the stacking order of layers included in the first stack is opposite to the stacking order of layers included in the second stack along the direction from the first stack to the second stack through the component. Note that the first stack, the component, and the second stack may be arranged in this order in a direction perpendicular to the substrate surface or in a direction parallel to the substrate surface. In the case where the first stack, the component, and the second stack are arranged in this order in the direction perpendicular to the substrate surface, it can be said that the first stack and the second stack are provided over and under the component.

Note that the first stack and the second stack each include two or more layers. The number of layers included in the first stack is preferably equal to the number of layers included in the second stack. Note that one layer included in the first stack sometimes has functions of a plurality of layers included in the second stack, and vice versa. A component consisting of a plurality of layers included in the first stack sometimes has a function of one layer included in the second stack, and vice versa. Thus, the number of layers included in the first stack may be different from the number of layers included in the second stack in some cases. One layer and another layer included in the first stack do not necessarily have overlapping outlines. The same applies to the second stack.

The semiconductor device described in this embodiment includes the first stack, the metal oxide including the channel formation region under the first stack, and the second stack under the metal oxide. The first stack and the second stack each include at least the first insulator and the second insulator. In this case, the first insulator included in the first stack and the first insulator included in the second stack include a region where they overlap with each other with the channel formation region therebetween, and the second insulator included in the first stack and the second insulator included in the second stack include a region where they overlap with each other with the first insulator included in the first stack, the channel formation region, and the first insulator included in the second stack therebetween.

Note that the first insulator included in the first stack and the first insulator included in the second stack may differ in thickness, material, formation method, or the like as long as they have a common property or function. Specifically, the first insulator included in the first stack and the first insulator included in the second stack may differ in thickness, material, formation method, or the like as long as they have the property of being highly permeable to oxygen. Note that the first insulators may have one or more common properties or functions. The same applies to the second insulator included in the first stack and the second insulator included in the second stack; specifically, the second insulator included in the first stack and the second insulator included in the second stack may differ in thickness, material, formation method, or the like as long as they have a function of inhibiting hydrogen diffusion.

As illustrated in FIG. 1B and FIG. 1C, the insulator 250 preferably has a stacked-layer structure of the insulator 250a and the insulator 250b over the insulator 250a. The insulator 222 preferably has a stacked-layer structure of the insulator 222a and the insulator 222b under the insulator 222a. That is, it is preferable that the insulator 250a and the insulator 222a be provided such that the region 230i of the oxide 230 is sandwiched therebetween and the insulator 250b and the insulator 222b be provided such that the insulator 250a, the region 230i, and the insulator 222a are sandwiched therebetween. In other words, the insulator 250a and the insulator 222a include a region where they overlap with each other with the region 230i therebetween, and the insulator 250b and the insulator 222b include a region where they overlap with each other with the insulator 250a, the region 230i, and the insulator 222a therebetween.

In the structure illustrated in FIG. 1B and FIG. 1C, the insulator 250 corresponds to the above-described first stack, and the insulator 222 corresponds to the above-described second stack. The insulator 250a and the insulator 222a correspond to the above-described first insulators, and the insulator 250b and the insulator 222b correspond to the above-described second insulators. In this case, it can be said that the conductor 260 is positioned above the first stack. It can also be said that the conductor 205 is positioned below the second stack.

As illustrated in FIG. 1B and FIG. 1C, the insulator 250a and the insulator 222a preferably include a region where they do not overlap with the oxide 230 and are in contact with each other. With such a structure, the oxide 230 can be surrounded by the insulator 250a and the insulator 222a.

As the insulator 250a and the insulator 222a, an insulator that is highly permeable to oxygen is preferably used. With such a structure, oxygen contained in the insulator 280 can be supplied to the region 230i through the insulator 250a and the insulator 222a. An insulator containing excess oxygen may also be used as the insulator 250a and the insulator 222a. With such a structure, oxygen contained in the insulator 250a and the insulator 222a can be supplied to the region 230i.

For example, silicon oxide, silicon oxynitride, or silicon nitride oxide can be used as the insulator 250a and the insulator 222a. As another example, silicon oxide to which fluorine is added, silicon oxide to which carbon is added, or silicon oxide to which carbon and nitrogen are added can be used. As another example, porous silicon oxide or the like can be used. These silicon oxides may contain nitrogen. In particular, silicon oxide and silicon oxynitride, which are thermally stable, are preferable. The insulator 250a and the insulator 222a in this case contain at least oxygen and silicon.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The concentration of impurities such as water and hydrogen in the insulator 250a and the insulator 222a is preferably reduced.

The insulator 250b and the insulator 222b preferably have a barrier property against hydrogen. Thus, impurities such as hydrogen contained in the conductor 260 and the conductor 205 can be inhibited from diffusing into the region 230i. For the insulator 250b and the insulator 222b, aluminum oxide, magnesium oxide, hafnium oxide, gallium oxide, indium gallium zinc oxide, silicon nitride, silicon nitride oxide, or the like are preferably used, for example. In particular, silicon nitride is suitably used for the insulator 250b and the insulator 222b because of its high hydrogen barrier property. In this case, the insulator 250b and the insulator 222b contain at least nitrogen and silicon.

Note that the insulator 250b is less permeable to hydrogen than the insulator 250a, for example. The insulator 250b is formed using a material that is less permeable to hydrogen than the insulator 250a, for example. Similarly, the insulator 222b is less permeable to hydrogen than the insulator 222a, for example. The insulator 222b is formed using a material that is less permeable to hydrogen than the insulator 222a, for example.

Note that the barrier property in this specification and the like refers to a property that does not easily allow diffusion of a target substance (also referred to as a property that does not easily allow passage of a target substance, a property with low permeability to a target substance, or a function of inhibiting diffusion of a target substance). Alternatively, the barrier property refers to a function of capturing or fixing (also referred to as gettering) a target substance. In this specification and the like, an insulator having a barrier property is referred to as a barrier insulator in some cases.

The insulator 250b and the insulator 222b further preferably have a barrier property against oxygen. The insulator 250b is provided between the insulator 250a and the conductor 260. Thus, diffusion of oxygen contained in the insulator 250a into the conductor 260 can be prevented, so that oxidation of the conductor 260 can be inhibited. A reduction in the amount of oxygen supplied to the region 230i can be inhibited. The insulator 222b is provided between the insulator 222a and the conductor 205. Thus, diffusion of oxygen contained in the insulator 222a into the conductor 205 can be prevented, so that oxidation of the conductor 205 can be inhibited. A reduction in the amount of oxygen supplied to the region 230i can be inhibited.

Note that the insulator 250b is less permeable to oxygen than the insulator 250a, for example. The insulator 250b is formed using a material that is less permeable to oxygen than the insulator 250a, for example. Similarly, the insulator 222b is less permeable to oxygen than the insulator 222a, for example. The insulator 222b is formed using a material that is less permeable to oxygen than the insulator 222a, for example.

Silicon nitride has a barrier property against oxygen and thus can be suitably used for the insulator 250b and the insulator 222b.

With the above-described structure, the transistor 200 can have favorable electrical characteristics and reliability. Thus, a semiconductor device having favorable electrical characteristics and a semiconductor device having high reliability can be obtained. The insulator 250a and the insulator 222a have the same function, and the insulator 250b and the insulator 222b have the same function. Thus, the first stack and the second stack can be provided symmetrically with respect to the channel formation region.

The insulator 280 functions as an interlayer film. The insulator 280 is preferably formed using a material with a low permittivity. The insulator 280 preferably has a lower permittivity than the insulator 250b, for example. When a material with a low permittivity is used for an interlayer film, parasitic capacitance generated between wirings can be reduced.

Note that the ratio of the permittivity of a medium to the permittivity of a vacuum is referred to as a dielectric constant. That is, the dielectric constant is a permittivity that is made dimensionless by the electric constant. Thus, the permittivity can be rephrased as the dielectric constant.

For example, an insulator that can be used as the insulator 250a and the insulator 222a can be used as the insulator 280. In particular, a material such as silicon oxide, silicon oxynitride, or porous silicon oxide is preferably used, in which case a region containing excess oxygen can be easily formed.

The concentration of impurities such as water and hydrogen in the insulator 280 is preferably reduced. For example, the insulator 280 preferably includes an oxide containing silicon, such as silicon oxide or silicon oxynitride.

The conductor 260 and the insulator 250 are provided to fill the opening portion formed in the insulator 280. The conductor 260 is provided in the opening portion to cover at least part of the side surface and at least part of the top surface of the oxide 230 with the insulator 250 therebetween. The conductor 260 is provided such that its top surface is level with the top surface of the insulator 250 and the top surface of the insulator 280.

Note that a sidewall of the insulator 280 in the opening portion which is formed in the insulator 280 and in which the conductor 260 and the insulator 250 are provided may be substantially perpendicular to the top surface of the insulator 222 or may be tapered. The tapered shape of the sidewall of the insulator 280 in the opening portion can improve the coverage with the insulator 250 and the like provided in the opening portion, so that defects such as voids can be reduced.

The conductor 260 preferably extends in the channel width direction as illustrated in FIG. 1A and FIG. 1C. With such a structure, the conductor 260 functions as a wiring when a plurality of transistors are provided.

Each of the conductor 260, the conductor 242a, the conductor 242b, and the conductor 205 is preferably formed using a conductive material that is less likely to be oxidized or a conductive material that has a function of inhibiting diffusion of oxygen. Examples of the conductive material include a conductive material containing nitrogen and a conductive material containing oxygen. Thus, a decrease in the conductivity of the conductor 260, the conductor 242a, the conductor 242b, and the conductor 205 can be inhibited. In the case where the conductor 260, the conductor 242a, the conductor 242b, and the conductor 205 are formed using a conductive material containing a metal and nitrogen, the conductor 260, the conductor 242a, the conductor 242b, and the conductor 205 contain at least the metal and nitrogen.

The conductor 260 may have a single-layer structure or a stacked-layer structure. The conductor 242a and the conductor 242b may each have a single-layer structure or a stacked-layer structure.

The conductor 242a and the conductor 242b are preferably formed using a conductive material containing nitrogen; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

Note that hydrogen contained in the oxide 230 or the like diffuses into the conductor 242a or the conductor 242b in some cases. In particular, when a nitride containing tantalum is used for the conductor 242a and the conductor 242b, hydrogen contained in the oxide 230 or the like is likely to diffuse into the conductor 242a or the conductor 242b, and the diffused hydrogen is bonded to nitrogen contained in the conductor 242a or the conductor 242b in some cases. That is, hydrogen contained in the oxide 230 or the like is absorbed by the conductor 242a or the conductor 242b in some cases.

The conductor 205 is placed to overlap with the oxide 230 and the conductor 260. Moreover, the conductor 205 is preferably provided to extend in the channel width direction as illustrated in FIG. 1A and FIG. 1C. With such a structure, the conductor 205 functions as a wiring when a plurality of transistors are provided.

The conductor 205 may have a single-layer structure or a stacked-layer structure.

The conductor 205 can function as the second gate electrode. In that case, by changing a potential applied to the conductor 205 not in conjunction with but independently of a potential applied to the conductor 260, the threshold voltage (Vth) of the transistor 200 can be controlled. In particular, by application of a negative potential to the conductor 205, Vth of the transistor 200 can be increased and the off-state current can be decreased. Thus, a drain current at the time when a potential applied to the conductor 260 is 0 V can be lower in the case where a negative potential is applied to the conductor 205 than in the case where the negative potential is not applied to the conductor 205.

Note that the potential applied to the conductor 205 may be equal to the potential applied to the conductor 260. In that case, the electric fields of the conductor 260 and the conductor 205 can be applied to the entire channel formation region of the oxide 230. It is thus possible to increase the channel width of the transistor without increasing the size thereof. Thus, the on-state current of the transistor can be increased while miniaturization of the transistor is achieved. The increase in the on-state current of the transistor can improve the frequency characteristics.

Although FIG. 1B and FIG. 1C illustrate a structure in which the stacked-layer structure of the insulator 222b and the insulator 222a is used as the second gate insulator, the present invention is not limited thereto. For example, a stack of the insulator 222 and an island-shaped insulator over the insulator 222 may be used as the second gate insulator. In other words, an island-shaped insulator may be provided between the insulator 222 and the oxide 230.

Note that in this specification and the like, an island shape refers to a state where two or more layers formed using the same material in the same step are physically separated from each other.

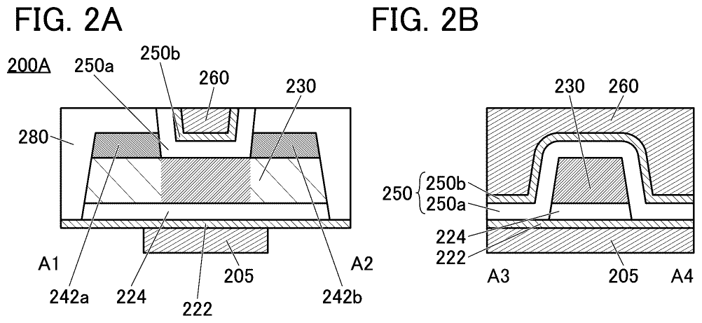

FIG. 2A and FIG. 2B illustrate an example of a structure different from the structure illustrated in FIG. 1B and FIG. 1C. FIG. 2A and FIG. 2B are cross-sectional views of a semiconductor device including the transistor 200A. Here, FIG. 2A is a cross-sectional view of the transistor 200A in the channel length direction, and FIG. 2B is a cross-sectional view of the transistor 200A in the channel width direction. Note that FIG. 1A can be referred to for the top view of the semiconductor device illustrated in FIG. 2A and FIG. 2B.

The transistor 200A illustrated in FIG. 2A and FIG. 2B is different from the transistor 200A illustrated in FIG. 1B and FIG. 1C mainly in that the insulator 222 is a single layer and an insulator 224 having an island shape is included.

In the transistor 200A illustrated in FIG. 2A and FIG. 2B, the insulator 224 having an island shape is provided between the insulator 222 and the oxide 230. As illustrated in FIG. 2A and FIG. 2B, a side end portion of the insulator 224 is aligned with a side end portion of the oxide 230 in a cross-sectional view of the transistor 200A.

The insulator 222 and the insulator 224 each include a region functioning as the second gate insulator.

The insulator 250a includes a region in contact with the top surface of the insulator 222, a region in contact with the side surface of the insulator 224, a region in contact with the side surface of the oxide 230, and a region in contact with the top surface of the oxide 230. In this case, the region 230i of the oxide 230 is surrounded by the insulator 250a and the insulator 224.

The insulator 222 is preferably formed using any of the above-described materials that can be used for the insulator 222b. The insulator 224 is preferably formed using any of the above-described materials that can be used for the insulator 222a. In such a structure, a stack of the insulator 222 and the insulator 224 having an island shape can be regarded as the second stack. In this case, it can be said that the transistor 200A illustrated in FIG. 2A and FIG. 2B has a structure in which the first stack and the second stack are provided symmetrically with respect to the channel formation region.

### Structure Example 2

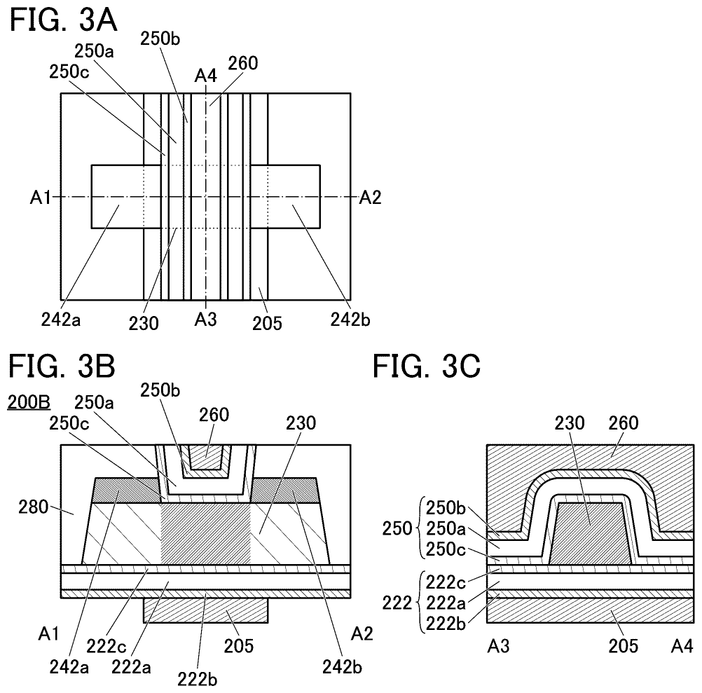

FIG. 3A to FIG. 3C illustrate a structure example different from that of the above-described transistor 200A. FIG. 3A is a top view of a semiconductor device, and FIG. 3B and FIG. 3C are cross-sectional views of the semiconductor device. Here, FIG. 3B is a cross-sectional view of a portion indicated by the dashed-dotted line A1-A2 in FIG. 3A. FIG. 3C is a cross-sectional view of a portion indicated by the dashed-dotted line A3-A4 in FIG. 3A. Note that some components are omitted in the top view in FIG. 3A for clarity of the drawing.

The semiconductor device illustrated in FIG. 3A to FIG. 3C includes a transistor 200B. Thus, FIG. 3B can also be referred to as a cross-sectional view of the transistor 200B in the channel length direction. FIG. 3C can also be referred to as a cross-sectional view of the transistor 200B in the channel width direction.

The transistor 200B illustrated in FIG. 3B and FIG. 3C is different from the transistor 200A illustrated in FIG. 1B and FIG. 1C mainly in that the insulator 222 and the insulator 250 each have a stacked-layer structure of three layers. Specifically, the transistor 200B illustrated in FIG. 3B and FIG. 3C is different from the transistor 200A illustrated in FIG. 1B and FIG. 1C mainly in that the insulator 250 further includes an insulator 250c under the insulator 250a and the insulator 222 further includes an insulator 222c over the insulator 222a. Differences from the above-described structure example 1 are mainly described below, and common portions are not described.

The insulator 250 includes the insulator 250c, the insulator 250a over the insulator 250c, and the insulator 250b over the insulator 250a. The insulator 222 includes the insulator 222b, the insulator 222a over the insulator 222b, and the insulator 222c over the insulator 222a. In this case, the insulator 250c and the insulator 222c include a region where they overlap with each other with the region 230i therebetween; the insulator 250a and the insulator 222a include a region where they overlap with each other with the insulator 250c, the region 230i, and the insulator 222c therebetween; and the insulator 250b and the insulator 222b include a region where they overlap with each other with the insulator 250a, the insulator 250c, the region 230i, the insulator 222c, and the insulator 222a therebetween. It can be said that the insulator 250c is positioned between the insulator 250a and the region 230i and the insulator 222c is positioned between the insulator 222a and the region 230i.

The insulator 250c and the insulator 222c preferably have a barrier property against oxygen. The insulator 250c includes a region in contact with the side surface of the conductor 242a and a region in contact with the side surface of the conductor 242b. When the insulator 250c has a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200B can be inhibited. Examples of the barrier insulator against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Each of the insulator 250c and the insulator 222c preferably has a single-layer structure or a stacked-layer structure of the barrier insulator against oxygen. Note that the insulator 250c is less permeable to oxygen than the insulator 250a, for example. The insulator 250c is formed using a material that is less permeable to oxygen than the insulator 250a, for example. Similarly, the insulator 222c is less permeable to oxygen than the insulator 222a, for example. The insulator 222c is formed using a material that is less permeable to oxygen than the insulator 222a, for example.

The insulator 250c is provided in contact with the top surface and the side surface of the oxide 230 and the top surface of the insulator 222c. That is, the region 230i is surrounded by the insulator 250c and the insulator 222c. When the insulator 250c and the insulator 222c have a barrier property against oxygen, release of oxygen from the region 230i at the time of performing heat treatment or the like can be inhibited. This can inhibit formation of oxygen vacancies in the region 230i.

By providing the insulator 250c and the insulator 222c, even when the insulator 280 contains an excess amount of oxygen, excessive supply of oxygen to the region 230i can be inhibited and an appropriate amount of oxygen can be supplied to the region 230i. Accordingly, the region 230na and the region 230nb can be inhibited from being excessively oxidized, and thus a decrease in the on-state current or field-effect mobility of the transistor 200B can be inhibited.

The insulator 222c is provided between the insulator 222a and the region 230na or the region 230nb. Thus, diffusion of oxygen from below the insulator 222c into the region 230na and the region 230nb can be inhibited. The conductor 242a is provided over the region 230na, and the conductor 242b is provided over the region 230nb. Accordingly, an excess amount of oxygen is not supplied to the region 230na and the region 230nb in the structure of this embodiment.

An insulator including an oxide containing one or both of aluminum and hafnium is preferably used as the insulator 250c and the insulator 222c. In this embodiment, aluminum oxide is used for the insulator 250c and the insulator 222c. In this case, the insulator 250c and the insulator 222c each contain at least oxygen and aluminum.

With the above-described structure, the insulator 250c and the insulator 222c have the same function. Thus, the first stack and the second stack can be provided symmetrically with respect to the channel formation region.

Note that the second gate insulator may be formed with the stack of the insulator 222 and the insulator 224 having an island shape as in the structure illustrated in FIG. 2A and FIG. 2B.

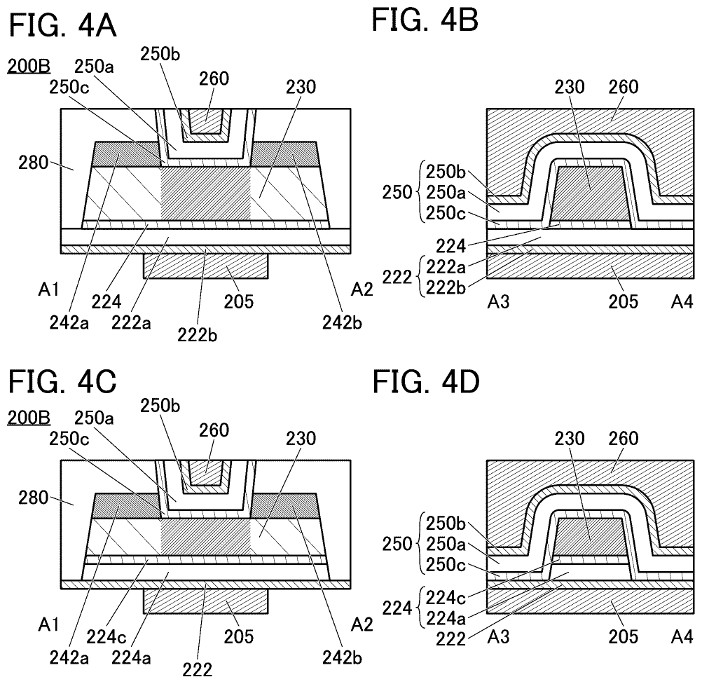

FIG. 4A and FIG. 4B illustrate an example of a structure different from the structure illustrated in FIG. 3B and FIG. 3C. FIG. 4A and FIG. 4B are cross-sectional views of a semiconductor device including the transistor 200B. Here, FIG. 4A is a cross-sectional view of the transistor 200B in the channel length direction, and FIG. 4B is a cross-sectional view of the transistor 200B in the channel width direction. Note that FIG. 3A can be referred to for the top view of the semiconductor device illustrated in FIG. 4A and FIG. 4B.

The transistor 200B illustrated in FIG. 4A and FIG. 4B is different from the transistor 200B illustrated in FIG. 3B and FIG. 3C mainly in that the insulator 222 has a stacked-layer structure of two layers and the insulator 224 having an island shape is included.

In the transistor 200B illustrated in FIG. 4A and FIG. 4B, the insulator 222 has a stacked-layer structure of the insulator 222b and the insulator 222a over the insulator 222b. The insulator 224 having an island shape is provided between the insulator 222 and the oxide 230.

The insulator 250c includes a region in contact with the top surface of the insulator 222a, a region in contact with the side surface of the insulator 224, a region in contact with the side surface of the oxide 230, and a region in contact with the top surface of the oxide 230. In this case, the region 230i of the oxide 230 is surrounded by the insulator 250c and the insulator 224.

The insulator 224 is preferably formed using any of the above-described materials that can be used for the insulator 222c.

Note that the structures of the insulator 222 and the insulator 224 are not limited to those illustrated in FIG. 4A and FIG. 4B. FIG. 4C and FIG. 4D illustrate an example of a structure different from the structure illustrated in FIG. 4A and FIG. 4B. FIG. 4C and FIG. 4D are cross-sectional views of a semiconductor device including the transistor 200B. Here, FIG. 4C is a cross-sectional view of the transistor 200B in the channel length direction, and FIG. 4D is a cross-sectional view of the transistor 200B in the channel width direction. Note that FIG. 3A can be referred to for the top view of the semiconductor device illustrated in FIG. 4C and FIG. 4D.

As illustrated in FIG. 4C and FIG. 4D, the insulator 222 may have a single-layer structure, and the insulator 224 may have a stacked-layer structure of an insulator 224a and an insulator 224c over the insulator 224a. In that case, the insulator 222 is preferably formed using any of the above-described materials that can be used for the insulator 222b. It is preferable that the insulator 224a be formed using any of the above-described materials that can be used for the insulator 222a and the insulator 224c be formed using any of the above-described materials that can be used for the insulator 222c.

With the above-described structure, the stack of the insulator 222 and the insulator 224 can be regarded as the second stack. In this case, it can be said that the transistor 200B illustrated in FIG. 4A and FIG. 4B and the transistor 200B illustrated in FIG. 4C and FIG. 4D each have a structure in which the first stack and the second stack are provided symmetrically with respect to the channel formation region.

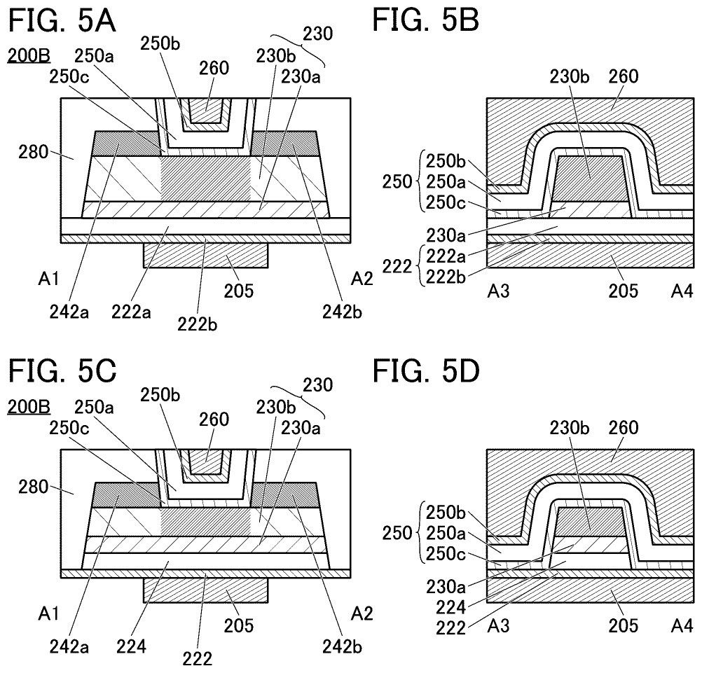

Although FIG. 4A and FIG. 4B illustrate a structure in which the insulator 224 having a barrier property against oxygen is provided between the region 230i and the insulator 222a, the present invention is not limited thereto. FIG. 5A and FIG. 5B illustrate an example of a structure different from the structure illustrated in FIG. 4A and FIG. 4B.

FIG. 5A and FIG. 5B are cross-sectional views of a semiconductor device including the transistor 200B. Here, FIG. 5A is a cross-sectional view of the transistor 200B in the channel length direction, and FIG. 5B is a cross-sectional view of the transistor 200B in the channel width direction. Note that FIG. 3A can be referred to for the top view of the semiconductor device illustrated in FIG. 5A and FIG. 5B.

The transistor 200B illustrated in FIG. 5A and FIG. 5B is different from the transistor 200B illustrated in FIG. 4A and FIG. 4B mainly in that the insulator 222 has the stacked-layer structure of two layers, the insulator 224 is not included, and the oxide 230 has a stacked-layer structure of two layers.

As illustrated in FIG. 5A and FIG. 5B, the insulator 222 has the stacked-layer structure of the insulator 222b and the insulator 222a over the insulator 222b. The oxide 230 has a stacked-layer structure of an oxide 230a and an oxide 230b over the oxide 230a. It is preferable that the oxide 230a be formed using a semiconductor material having a barrier property against oxygen and the oxide 230b be formed using any of the above-described materials that can be used for the oxide 230.

Note that the oxide 230a is less permeable to oxygen than the insulator 222a, for example. The oxide 230a is formed using a material that is less permeable to oxygen than the insulator 222a, for example.

For example, a metal oxide containing at least the element M is preferably used as the oxide 230a. Note that the oxide 230b may contain or does not necessarily contain the element M. In this case, the atomic ratio of the element M to a metal element that is a main component in the oxide 230a is preferably greater than the atomic ratio of the element M to a metal element that is a main component in the oxide 230b. Furthermore, in the case where the oxide 230a and the oxide 230b each contain In, the atomic ratio of the element M to In in the oxide 230a is preferably greater than the atomic ratio of the element M to In in the oxide 230b. With such a structure, impurities and oxygen can be inhibited from diffusing into the oxide 230b from a component formed below the oxide 230a.

As the oxide 230a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used, for example.

It is preferable to use at least one of gallium and aluminum as the element M. In the case where aluminum oxide is used for the insulator 250c as described above, the oxide 230a and the insulator 250c each contain at least one of gallium and aluminum.

In the above-described structure, the stack of the insulator 222 and the oxide 230a can be regarded as the second stack. In this case, it can be said that the transistor 200B illustrated in FIG. 5A and FIG. 5B has a structure in which the first stack and the second stack are provided symmetrically with respect to the channel formation region.

Note that in the case where the oxide 230 has the stacked-layer structure of the oxide 230a and the oxide 230b, the region 230i, the region 230na, and the region 230nb are sometimes formed not only in the oxide 230b but also in the oxide 230a.

FIG. 5C and FIG. 5D illustrate an example of a structure different from the structure illustrated in FIG. 5A and FIG. 5B. FIG. 5C and FIG. 5D are cross-sectional views of a semiconductor device including the transistor 200B. Here, FIG. 5C is a cross-sectional view of the transistor 200B in the channel length direction, and FIG. 5D is a cross-sectional view of the transistor 200B in the channel width direction. Note that FIG. 3A can be referred to for the top view of the semiconductor device illustrated in FIG. 5C and FIG. 5D.

As illustrated in FIG. 5C and FIG. 5D, the insulator 222 may have a single-layer structure, and the insulator 224 may be provided between the insulator 222 and the oxide 230a. In this case, the insulator 250c and the oxide 230a include a region where they overlap with each other with the region 230i therebetween; the insulator 250a and the insulator 224 include a region where they overlap with each other with the insulator 250c, the region 230i, and the oxide 230a therebetween; and the insulator 250b and the insulator 222 include a region where they overlap with each other with the insulator 250a, the insulator 250c, the region 230i, the oxide 230a, and the insulator 224 therebetween.

The insulator 222 is preferably formed using any of the above-described materials that can be used for the insulator 222b. The insulator 224 is preferably formed using any of the above-described materials that can be used for the insulator 222a. In such a structure, a component including the insulator 222, the insulator 224, and the oxide 230a can be regarded as the second stack. In this case, the second stack includes the oxide 230a, the insulator 224 under the oxide 230a, and the insulator 222 under the insulator 224. It can be said that the transistor 200B illustrated in FIG. 5C and FIG. 5D has a structure in which the first stack and the second stack are provided symmetrically with respect to the channel formation region.

### Structure Example 3

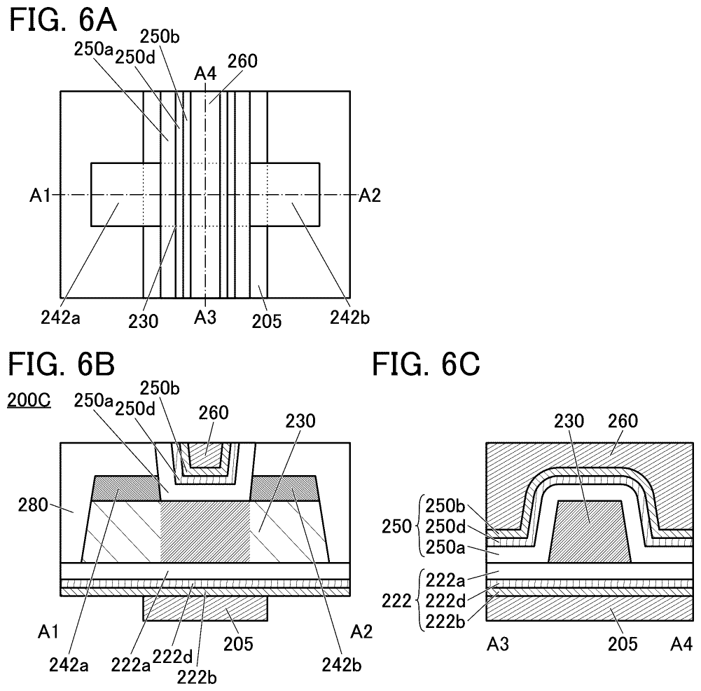

FIG. 6A to FIG. 6C illustrate a structure example different from that of the above-described transistor 200A. FIG. 6A is a top view of a semiconductor device, and FIG. 6B and FIG. 6C are cross-sectional views of the semiconductor device. Here, FIG. 6B is a cross-sectional view of a portion indicated by the dashed-dotted line A1-A2 in FIG. 6A. FIG. 6C is a cross-sectional view of a portion indicated by the dashed-dotted line A3-A4 in FIG. 6A. Note that some components are omitted in the top view in FIG. 6A for clarity of the drawing.

The semiconductor device illustrated in FIG. 6A to FIG. 6C includes a transistor 200C. Thus, FIG. 6B can also be referred to as a cross-sectional view of the transistor 200C in the channel length direction. FIG. 6C can also be referred to as a cross-sectional view of the transistor 200C in the channel width direction.

The transistor 200C illustrated in FIG. 6B and FIG. 6C is different from the transistor 200A illustrated in FIG. 1B and FIG. 1C mainly in that the insulator 222 and the insulator 250 each have a stacked-layer structure of three layers. Specifically, the transistor 200C illustrated in FIG. 6B and FIG. 6C is different from the transistor 200A illustrated in FIG. 1B and FIG. 1C mainly in that an insulator 250d is included between the insulator 250a and the insulator 250b and an insulator 222d is included between the insulator 222a and the insulator 222b. Differences from the above-described structure example 1 are mainly described below, and common portions are not described.

The insulator 250 includes the insulator 250a, the insulator 250d over the insulator 250a, and the insulator 250b over the insulator 250d. The insulator 222 includes the insulator 222b, the insulator 222d over the insulator 222b, and the insulator 222a over the insulator 222d. In this case, the insulator 250a and the insulator 222a include a region where they overlap with each other with the region 230i therebetween; the insulator 250d and the insulator 222d include a region where they overlap with each other with the insulator 250a, the region 230i, and the insulator 222a therebetween; and the insulator 250b and the insulator 222b include a region where they overlap with each other with the insulator 250d, the insulator 250a, the region 230i, the insulator 222a, and the insulator 222d therebetween.

The insulator 250d and the insulator 222d preferably have a function of capturing or fixing hydrogen. When an insulator having a function of capturing or fixing hydrogen is provided inside a region surrounded by the insulator 250b and the insulator 222b, hydrogen inside the region can be captured or fixed more effectively. That is, hydrogen contained in the insulator 250a, the region 230i of the oxide 230b, and the insulator 222a can be captured or fixed more effectively. Thus, the hydrogen concentration in the region 230i can be reduced. Accordingly, the amount of VoH in the region 230i can be reduced, whereby the region 230i can be an i-type or substantially i-type region.

Examples of the insulator having a function of capturing or fixing hydrogen include a metal oxide having an amorphous structure. For the insulator 250d and the insulator 222d, for example, a metal oxide such as magnesium oxide or an oxide containing one or both of aluminum and hafnium is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

The insulator 250d and the insulator 222d are preferably formed using a high dielectric constant (high-k) material. Note that examples of the high-k material include an oxide containing one or both of aluminum and hafnium, tantalum oxide, zirconium oxide, and hafnium zirconium oxide. As miniaturization and high integration of transistors progress, a problem such as a leakage current may arise because of a thinner gate insulator. With the use of the high-k material for the insulator 250d and the insulator 222d, a gate potential applied during the operation of the transistor can be reduced while the physical thickness of the gate insulator is maintained. In addition, the equivalent oxide thickness (EOT) of the insulator functioning as the gate insulator can be reduced. Note that a substance with a high permittivity such as lead zirconate titanate (PZT), strontium titanate (SrTiO₃), or (Ba,Sr)TiO₃ (BST) can be used for the insulator 250d and the insulator 222d in some cases.

As described above, for the insulator 250d and the insulator 222d, an oxide containing one or both of aluminum and hafnium is preferably used, and an oxide containing one or both of aluminum and hafnium and having an amorphous structure is further preferably used. In this embodiment, hafnium oxide is used for the insulator 250d and the insulator 222d. In this case, the insulator 250d and the insulator 222d each contain at least oxygen and hafnium. The hafnium oxide has an amorphous structure. In this case, the insulator 250d and the insulator 222d have an amorphous structure.

With the above-described structure, the insulator 250d and the insulator 222d have the same function. Thus, the first stack and the second stack can be provided symmetrically with respect to the channel formation region.

Note that the second gate insulator may be formed with the stack of the insulator 222 and the insulator 224 having an island shape as in the structure illustrated in FIG. 2A and FIG. 2B.

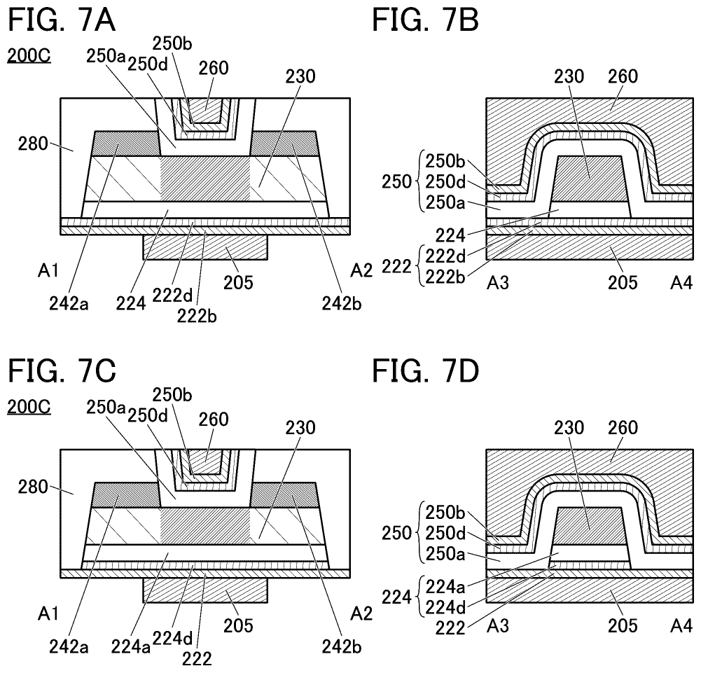

FIG. 7A and FIG. 7B illustrate an example of a structure different from the structure illustrated in FIG. 6B and FIG. 6C. FIG. 7A and FIG. 7B are cross-sectional views of a semiconductor device including the transistor 200C. Here, FIG. 7A is a cross-sectional view of the transistor 200C in the channel length direction, and FIG. 7B is a cross-sectional view of the transistor 200C in the channel width direction. Note that FIG. 6A can be referred to for the top view of the semiconductor device illustrated in FIG. 7A and FIG. 7B.

The transistor 200C illustrated in FIG. 7A and FIG. 7B is different from the transistor 200C illustrated in FIG. 6B and FIG. 6C mainly in that the insulator 222 has a stacked-layer structure of two layers and the insulator 224 having an island shape is included.

In the transistor 200C illustrated in FIG. 7A and FIG. 7B, the insulator 222 has a stacked-layer structure of the insulator 222b and the insulator 222d over the insulator 222b. The insulator 224 having an island shape is provided between the insulator 222 and the oxide 230.

The insulator 250a includes a region in contact with the top surface of the insulator 222d, a region in contact with the side surface of the insulator 224, a region in contact with the side surface of the oxide 230, and a region in contact with the top surface of the oxide 230. In this case, the region 230i of the oxide 230 is surrounded by the insulator 250a and the insulator 224.

The insulator 224 is preferably formed using any of the above-described materials that can be used for the insulator 222a.

Note that the structures of the insulator 222 and the insulator 224 are not limited to those illustrated in FIG. 7A and FIG. 7B. FIG. 7C and FIG. 7D illustrate an example of a structure different from the structure illustrated in FIG. 7A and FIG. 7B. FIG. 7C and FIG. 7D are cross-sectional views of a semiconductor device including the transistor 200C. Here, FIG. 7C is a cross-sectional view of the transistor 200C in the channel length direction, and FIG. 7D is a cross-sectional view of the transistor 200C in the channel width direction. Note that FIG. 6A can be referred to for the top view of the semiconductor device illustrated in FIG. 7C and FIG. 7D.

As illustrated in FIG. 7C and FIG. 7D, the insulator 222 may have a single-layer structure, and the insulator 224 may have the stacked-layer structure of the insulator 224d and the insulator 224a over the insulator 224d. In that case, the insulator 222 is preferably formed using any of the above-described materials that can be used for the insulator 222b. It is preferable that the insulator 224d be formed using any of the above-described materials that can be used for the insulator 222d and the insulator 224a be formed using any of the above-described materials that can be used for the insulator 222a.

With the above-described structure, the stack of the insulator 222 and the insulator 224 can be regarded as the second stack. In this case, it can be said that the transistor 200C illustrated in FIG. 7A and FIG. 7B and the transistor 200C illustrated in FIG. 7C and FIG. 7D each have a structure in which the first stack and the second stack are provided symmetrically with respect to the channel formation region.

### Structure Example 4

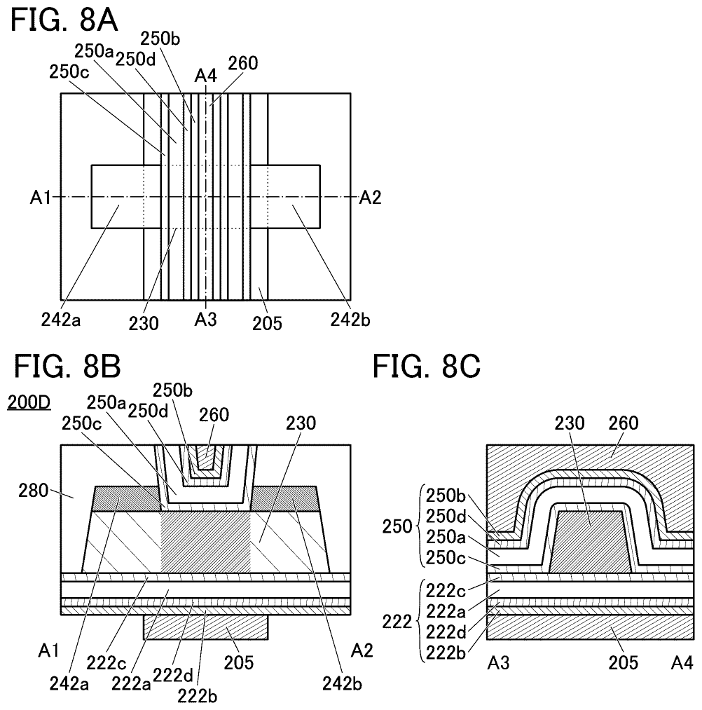

FIG. 8A to FIG. 8C illustrate a structure example different from those of the transistor 200A to the transistor 200C described above. FIG. 8A is a top view of a semiconductor device, and FIG. 8B and FIG. 8C are cross-sectional views of the semiconductor device. Here, FIG. 8B is a cross-sectional view of a portion indicated by the dashed-dotted line A1-A2 in FIG. 8A. FIG. 8C is a cross-sectional view of a portion indicated by the dashed-dotted line A3-A4 in FIG. 8A. Note that some components are omitted in the top view in FIG. 8A for clarity of the drawing.

The semiconductor device illustrated in FIG. 8A to FIG. 8C includes a transistor 200D. Thus, FIG. 8B can also be referred to as a cross-sectional view of the transistor 200D in the channel length direction. FIG. 8C can also be referred to as a cross-sectional view of the transistor 200D in the channel width direction.

The transistor 200D illustrated in FIG. 8B and FIG. 8C is different from the transistor 200A to the transistor 200C mainly in that the insulator 222 and the insulator 250 each have a stacked-layer structure of four layers. The transistor 200D illustrated in FIG. 8B and FIG. 8C can be regarded as having a structure obtained by adding the insulator 250d and the insulator 222d to the transistor 200B illustrated in FIG. 3A to FIG. 3C. Alternatively, it can be regarded as having a structure obtained by adding the insulator 250c and the insulator 222c to the transistor 200C illustrated in FIG. 6A to FIG. 6C. Differences from the structure example 1 to the structure example 3 described above are mainly described below, and common portions are not described.

The insulator 250 includes the insulator 250c, the insulator 250a over the insulator 250c, the insulator 250d over the insulator 250a, and the insulator 250b over the insulator 250d. The insulator 222 includes the insulator 222b, the insulator 222d over the insulator 222b, the insulator 222a over the insulator 222d, and the insulator 222c over the insulator 222a. In this case, the insulator 250c and the insulator 222c include a region where they overlap with each other with the region 230i therebetween; the insulator 250a and the insulator 222a include a region where they overlap with each other with the insulator 250c, the region 230i, and the insulator 222c therebetween; the insulator 250d and the insulator 222d include a region where they overlap with each other with the insulator 250a, the insulator 250c, the region 230i, the insulator 222c, and the insulator 222a therebetween; and the insulator 250b and the insulator 222b include a region where they overlap with each other with the insulator 250d, the insulator 250a, the insulator 250c, the region 230i, the insulator 222c, the insulator 222a, and the insulator 222d therebetween.

With the above-described structure, the first stack and the second stack can be provided symmetrically with respect to the channel formation region.

Note that the second gate insulator may be formed with the insulator 222 and the insulator 224 having an island shape as in the structure illustrated in FIG. 2A and FIG. 2B.

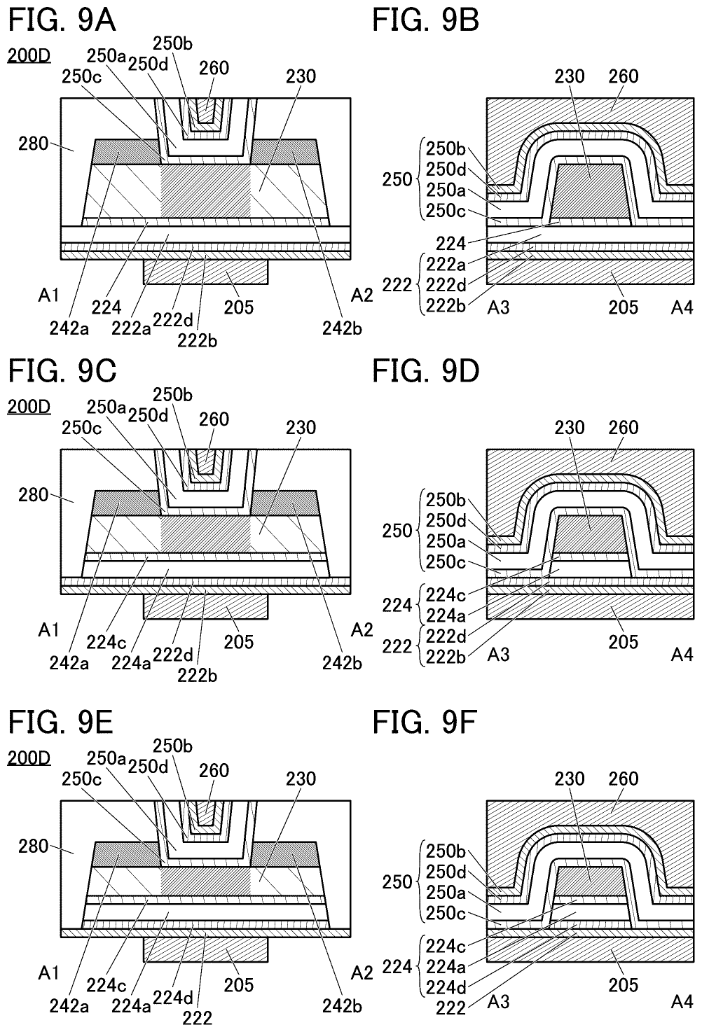

FIG. 9A and FIG. 9B, FIG. 9C and FIG. 9D, and FIG. 9E and FIG. 9F illustrate examples of structures different from the structure illustrated in FIG. 8B and FIG. 8C. FIG. 9A and FIG. 9B, FIG. 9C and FIG. 9D, and FIG. 9E and FIG. 9F are cross-sectional views of semiconductor devices including the transistors 200D. Here, FIG. 9A, FIG. 9C, and FIG. 9E are cross-sectional views of the transistors 200D in the channel length direction, and FIG. 9B, FIG. 9D, and FIG. 9F are cross-sectional views of the transistors 200D in the channel width direction. Note that FIG. 8A can be referred to for the top views of the semiconductor device illustrated in FIG. 9A and FIG. 9B, the semiconductor device illustrated in FIG. 9C and FIG. 9D, and the semiconductor device illustrated in FIG. 9E and FIG. 9F.

The transistor 200D illustrated in FIG. 9A and FIG. 9B, the transistor 200D illustrated in FIG. 9C and FIG. 9D, and the transistor 200D illustrated in FIG. 9E and FIG. 9F are different from the transistor 200D illustrated in FIG. 8B and FIG. 8C mainly in that the insulator 224 having an island shape is included between the insulator 222 and the oxide 230.

In the transistor 200D illustrated in FIG. 9A and FIG. 9B, the insulator 222 has a stacked-layer structure of the insulator 222b, the insulator 222d over the insulator 222b, and the insulator 222a over the insulator 222d, and the insulator 224 has a single-layer structure. The insulator 224 is preferably formed using any of the above-described materials that can be used for the insulator 222c.

In the transistor 200D illustrated in FIG. 9C and FIG. 9D, the insulator 222 has a stacked-layer structure of the insulator 222b and the insulator 222d over the insulator 222b, and the insulator 224 has a stacked-layer structure of the insulator 224a and the insulator 224c over the insulator 224a. It is preferable that the insulator 224a be formed using any of the above-described materials that can be used for the insulator 222a and the insulator 224c be formed using any of the above-described materials that can be used for the insulator 222c.

In the transistor 200D illustrated in FIG. 9E and FIG. 9F, the insulator 222 has a single-layer structure, and the insulator 224 has a stacked-layer structure of the insulator 224d, the insulator 224a over the insulator 224d, and the insulator 224c over the insulator 224a. The insulator 222 is preferably formed using any of the above-described materials that can be used for the insulator 222b. It is preferable that the insulator 224d be formed using any of the above-described materials that can be used for the insulator 222d, the insulator 224a be formed using any of the above-described materials that can be used for the insulator 222a, and the insulator 224c be formed using any of the above-described materials that can be used for the insulator 222c.

With the above-described structure, the stack of the insulator 222 and the insulator 224 can be regarded as the second stack. In this case, it can be said that the transistor 200D illustrated in FIG. 9A and FIG. 9B, the transistor 200D illustrated in FIG. 9C and FIG. 9D, and the transistor 200D illustrated in FIG. 9E and FIG. 9F each have a structure in which the first stack and the second stack are provided symmetrically with respect to the channel formation region.

Note that as in the structure illustrated in FIG. 5A and FIG. 5B, the oxide 230 may have the stacked-layer structure of the oxide 230a and the oxide 230b, and the oxide 230a be formed using a semiconductor material having a barrier property against oxygen.

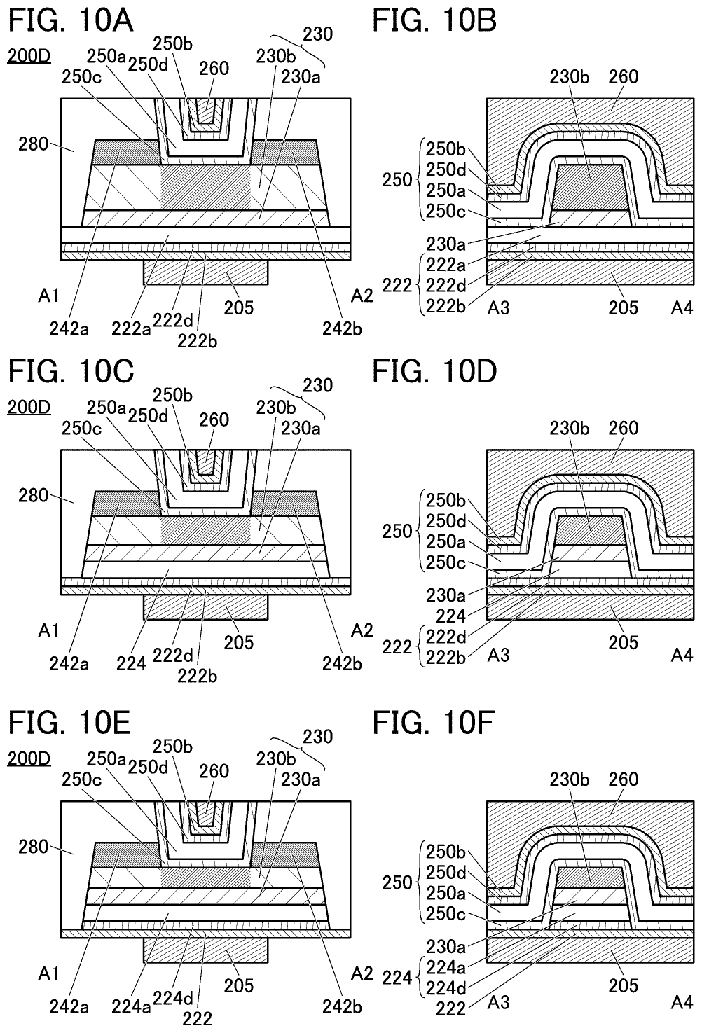

FIG. 10A and FIG. 10B, FIG. 10C and FIG. 10D, and FIG. 10E and FIG. 10F illustrate examples of structures different from the structure illustrated in FIG. 8B and FIG. 8C. FIG. 10A and FIG. 10B, FIG. 10C and FIG. 10D, and FIG. 10E and FIG. 10F are cross-sectional views of semiconductor devices including the transistors 200D. Here, FIG. 10A, FIG. 10C, and FIG. 10E are cross-sectional views of the transistors 200D in the channel length direction, and FIG. 10B, FIG. 10D, and FIG. 10F are cross-sectional views of the transistors 200D in the channel width direction. Note that FIG. 8A can be referred to for the top views of the semiconductor device illustrated in FIG. 10A and FIG. 10B, the semiconductor device illustrated in FIG. 10C and FIG. 10D, and the semiconductor device illustrated in FIG. 10E and FIG. 10F.

The transistor 200D illustrated in FIG. 10A and FIG. 10B is different from the transistor 200D illustrated in FIG. 8B and FIG. 8C mainly in that the oxide 230 has a stacked-layer structure of two layers. The transistor 200D illustrated in FIG. 10C and FIG. 10D and the transistor 200D illustrated in FIG. 10E and FIG. 10F are different from the transistor 200D illustrated in FIG. 8B and FIG. 8C mainly in that the insulator 224 having an island shape is included and the oxide 230 has a stacked-layer structure of two layers.

In the transistor 200D illustrated in FIG. 10A and FIG. 10B, the insulator 222 has a stacked-layer structure of the insulator 222b, the insulator 222d over the insulator 222b, and the insulator 222a over the insulator 222d, and the oxide 230 has a stacked-layer structure of the oxide 230a and the oxide 230b over the oxide 230a. In such a structure, the stack of the insulator 222 and the oxide 230a can be regarded as the second stack. In this case, it can be said that the transistor 200D illustrated in FIG. 10A and FIG. 10B has a structure in which the first stack and the second stack are provided symmetrically with respect to the channel formation region.

In the transistor 200D illustrated in FIG. 10C and FIG. 10D, the insulator 222 has a stacked-layer structure of the insulator 222b and the insulator 222d over the insulator 222b. The oxide 230 has a stacked-layer structure of the oxide 230a and the oxide 230b over the oxide 230a. The insulator 224 is preferably formed using any of the above-described materials that can be used for the insulator 222a.

In the transistor 200D illustrated in FIG. 10E and FIG. 10F, the insulator 224 includes the insulator 224d and the insulator 224a over the insulator 224d. The oxide 230 has a stacked-layer structure of the oxide 230a and the oxide 230b over the oxide 230a. The insulator 222 is preferably formed using any of the above-described materials that can be used for the insulator 222b. It is preferable that the insulator 224d be formed using any of the above-described materials that can be used for the insulator 222d and the insulator 224a be formed using any of the above-described materials that can be used for the insulator 222a.

With the above-described structure, the stack of the insulator 222, the insulator 224, and the oxide 230a can be regarded as the second stack. In this case, it can be said that the transistor 200D illustrated in FIG. 10C and FIG. 10D and the transistor 200D illustrated in FIG. 10E and FIG. 10F each have a structure in which the first stack and the second stack are provided symmetrically with respect to the channel formation region.

Note that one of the insulator 250d and the insulator 222d may be provided when the hydrogen concentration in the insulator 250a, the insulator 222a, or the region 230i is sufficiently low.

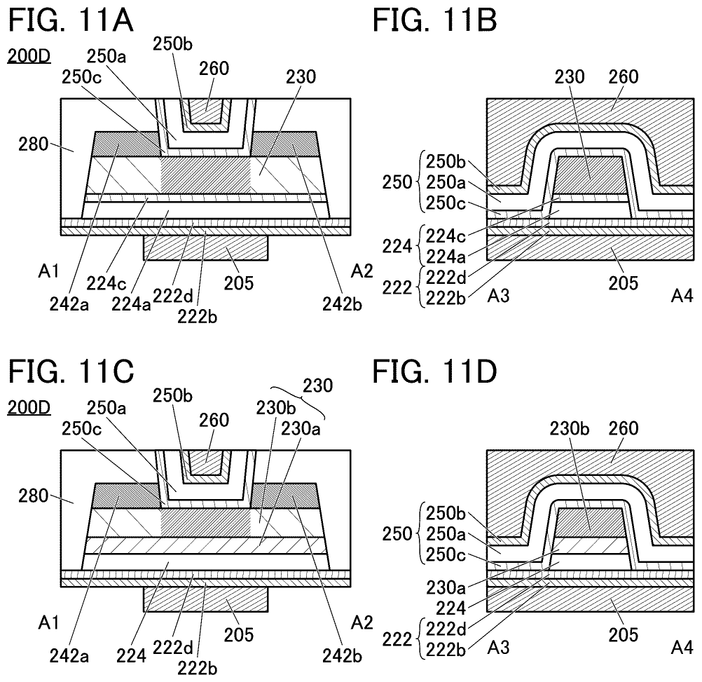

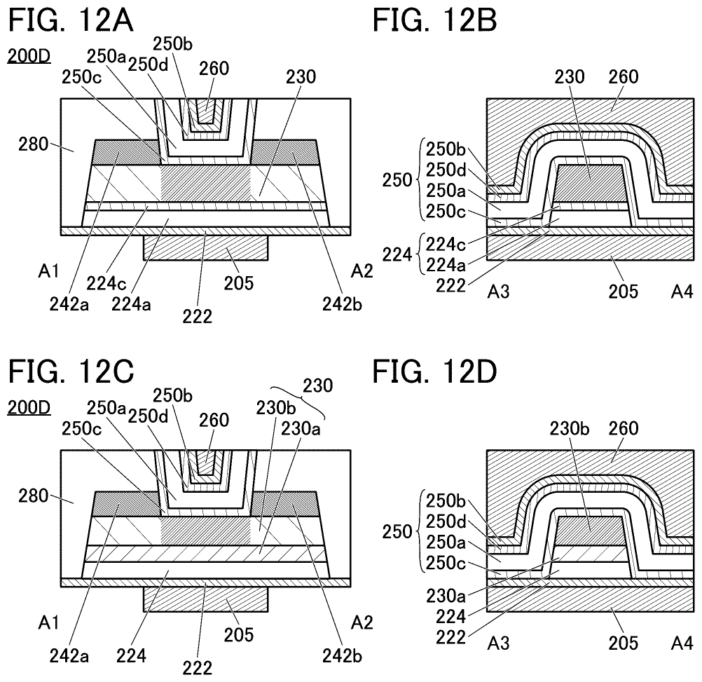

FIG. 11A and FIG. 11B, FIG. 11C and FIG. 11D, FIG. 12A and FIG. 12B, and FIG. 12C and FIG. 12D are cross-sectional views of semiconductor devices including the transistors 200D. Here, FIG. 11A, FIG. 11C, FIG. 12A, and FIG. 12C are cross-sectional views of the transistors 200D in the channel length direction, and FIG. 11B, FIG. 11D, FIG. 12B, and FIG. 12D are cross-sectional views of the transistors 200D in the channel width direction. Note that FIG. 3A can be referred to for the top views of the semiconductor device illustrated in FIG. 11A and FIG. 11B and the semiconductor device illustrated in FIG. 11C and FIG. 11D, and FIG. 8A can be referred to for the top views of the semiconductor device illustrated in FIG. 12A and FIG. 12B and the semiconductor device illustrated in FIG. 12C and FIG. 12D.

For example, the transistor 200D illustrated in FIG. 11A and FIG. 11B and the transistor 200D illustrated in FIG. 11C and FIG. 11D each include the insulator 222d and do not include the insulator 250d.

The transistor 200D illustrated in FIG. 11A and FIG. 11B is different from the transistor 200B illustrated in FIG. 4C and FIG. 4D in that the insulator 222d is included. The transistor 200D illustrated in FIG. 11A and FIG. 11B is different from the transistor 200D illustrated in FIG. 9C and FIG. 9D in that the insulator 250d is not included. Thus, the transistor 200D illustrated in FIG. 11A and FIG. 11B can be regarded as a modification example of the transistor 200B illustrated in FIG. 4C and FIG. 4D or a modification example of the transistor 200D illustrated in FIG. 9C and FIG. 9D.

The transistor 200D illustrated in FIG. 11C and FIG. 11D is different from the transistor 200B illustrated in FIG. 5C and FIG. 5D in that the insulator 222d is included between the insulator 222b and the insulator 224. The transistor 200D illustrated in FIG. 11C and FIG. 11C is different from the transistor 200D illustrated in FIG. 10C and FIG. 10D in that the insulator 250d is not included. Thus, the transistor 200D illustrated in FIG. 11C and FIG. 11D can be regarded as a modification example of the transistor 200B illustrated in FIG. 5C and FIG. 5D or a modification example of the transistor 200D illustrated in FIG. 10C and FIG. 10D. The transistor 200D illustrated in FIG. 10C and FIG. 10D has a structure obtained by providing the insulator 250d between the insulator 250a and the insulator 250b in the transistor 200D illustrated in FIG. 11C and FIG. 11D.

For example, the transistor 200D illustrated in FIG. 12A and FIG. 12B and the transistor 200D illustrated in FIG. 12C and FIG. 12D each include the insulator 250d and do not include the insulator 222d.

The transistor 200D illustrated in FIG. 12A and FIG. 12B is different from the transistor 200B illustrated in FIG. 4C and FIG. 4D in that the insulator 250d is included. The transistor 200D illustrated in FIG. 12A and FIG. 12B is different from the transistor 200D illustrated in FIG. 9C and FIG. 9D in that the insulator 222d is not included. Thus, the transistor 200D illustrated in FIG. 12A and FIG. 12B can be regarded as a modification example of the transistor 200B illustrated in FIG. 4C and FIG. 4D or a modification example of the transistor 200D illustrated in FIG. 9C and FIG. 9D.

The transistor 200D illustrated in FIG. 12C and FIG. 12D is different from the transistor 200B illustrated in FIG. 5C and FIG. 5D in that the insulator 250d is included. In other words, the transistor 200D illustrated in FIG. 12C and FIG. 12D has a structure obtained by adding the insulator 250d to the transistor 200B illustrated in FIG. 5C and FIG. 5D. The transistor 200D illustrated in FIG. 12C and FIG. 12D is different from the transistor 200D illustrated in FIG. 10C and FIG. 10D in that the insulator 222d is not included. Thus, the transistor 200D illustrated in FIG. 12C and FIG. 12D can be regarded as a modification example of the transistor 200B illustrated in FIG. 5C and FIG. 5D or a modification example of the transistor 200D illustrated in FIG. 10C and FIG. 10D.

Note that the insulator 222 of each of the transistor 200D illustrated in FIG. 12A and FIG. 12B and the transistor 200D illustrated in FIG. 12C and FIG. 12D may be formed using any of the above-described materials that can be used for the insulator 222b or any of the above-described materials that can be used for the insulator 222d.

In the case where the insulator 222 of each of the transistor 200D illustrated in FIG. 12A and FIG. 12B and the transistor 200D illustrated in FIG. 12C and FIG. 12D is formed using any of the above-described materials that can be used for the insulator 222d, the insulator 222 preferably has a function of further inhibiting diffusion of hydrogen (e.g., at least one of a hydrogen atom, a hydrogen molecule, and the like). For example, the insulator 222 preferably has a function of inhibiting diffusion of hydrogen more than the insulator 224 (the insulator 224a in the transistor 200D illustrated in FIG. 12A and FIG. 12B). The insulator 222 may also have a function of inhibiting diffusion of oxygen (e.g., at least one of an oxygen atom, an oxygen molecule, and the like). In that case, the insulator 222 preferably has a function of inhibiting diffusion of oxygen more than the insulator 224 (the insulator 224a in the transistor 200D illustrated in FIG. 12A and FIG. 12B).

In the transistor 200D illustrated in FIG. 12A and FIG. 12B and the transistor 200D illustrated in FIG. 12C and FIG. 12D, an oxide of one or both of aluminum and hafnium or an oxide containing hafnium and zirconium is preferably used for the insulator 222. In the case where such an oxide is used for the insulator 222, the insulator 222 functions as a layer that inhibits diffusion of impurities such as hydrogen from the substrate side into the oxide 230 and inhibits release of oxygen from the oxide 230 to the substrate side. Thus, diffusion of impurities such as hydrogen into the transistor 200D can be inhibited, and generation of oxygen vacancies in the oxide 230 can be inhibited. Moreover, the conductor 205 can be inhibited from reacting with oxygen contained in the oxide 230.

Note that aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment.

In the case where an oxide of one or both of aluminum and hafnium, for example, is used for the insulator 222, the thickness of the insulator 222 is preferably increased. For example, the thickness of the insulator 222 is preferably larger than the thickness of the insulator 250d, further preferably larger than the sum of the thickness of the insulator 250d and the thickness of the insulator 250b. When the thickness of the insulator 222 is increased, the insulator 222 sometimes has a function of capturing or fixing hydrogen and a function of inhibiting diffusion of hydrogen (e.g., at least one of a hydrogen atom, a hydrogen molecule, and the like). In that case, the insulator 222 can have both the function of any of the above-described materials that can be used for the insulator 222b and the function of any of the above-described materials that can be used for the insulator 222d. With such a structure, the transistor 200D illustrated in FIG. 12A and FIG. 12B and the transistor 200D illustrated in FIG. 12C and FIG. 12D can each be regarded as having a structure in which the first stack and the second stack are provided symmetrically with respect to the channel formation region.

### Application Example

In the semiconductor device of one embodiment of the present invention, an insulator having a barrier property against hydrogen may be provided either above the first gate electrode or below the second gate electrode or both.

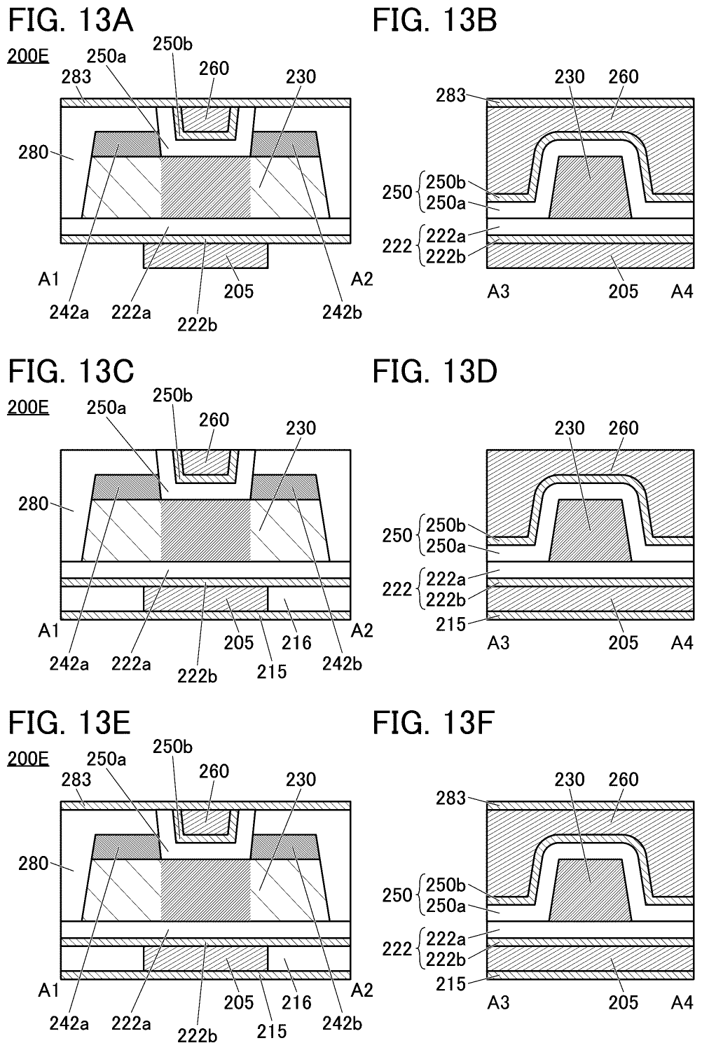

FIG. 13A and FIG. 13B, FIG. 13C and FIG. 13D, and FIG. 13E and FIG. 13F are cross-sectional views of semiconductor devices including transistors 200E. Here, FIG. 13A, FIG. 13C, and FIG. 13E are cross-sectional views of the transistors 200E in the channel length direction, and FIG. 13B, FIG. 13D, and FIG. 13F are cross-sectional views of the transistors 200E in the channel width direction. Note that FIG. 1A can be referred to for the top views of the semiconductor device illustrated in FIG. 13A and FIG. 13B, the semiconductor device illustrated in FIG. 13C and FIG. 13D, and the semiconductor device illustrated in FIG. 13E and FIG. 13F. Differences from the structure example 1 to the structure example 4 described above are mainly described below, and common portions are not described.

In the transistor 200E illustrated in FIG. 13A and FIG. 13B, an insulator 283 is provided above the conductor 260. In the transistor 200E illustrated in FIG. 13C and FIG. 13D, an insulator 215 is provided below the conductor 205. In the transistor 200E illustrated in FIG. 13E and FIG. 13F, the insulator 283 is provided above the conductor 260 and the insulator 215 is provided below the conductor 205.

The insulator 283 preferably has a barrier property against hydrogen, like the insulator 250b. Providing the insulator 283 can inhibit diffusion of impurities such as hydrogen contained in a component provided above the insulator 283 into the region 230i. The insulator 215 preferably has a barrier property against hydrogen, like the insulator 222b. Providing the insulator 215 can inhibit diffusion of impurities such as hydrogen contained in a component provided below the insulator 215 into the region 230i.

Note that in the transistor 200E provided with the insulator 215, an insulator 216 is provided over the insulator 215, and the conductor 205 is provided to fill an opening portion formed in the insulator 216. The top surface of the conductor 205 is level with the top surface of the insulator 216.

The electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, thereby inhibiting diffusion of the impurities into the oxide 230.

The permittivity of the insulator 216 is preferably lower than that of the insulator 215. As the insulator 216, an insulator that can be used for the insulator 280 is used, for example.

Note that the insulator 250b is not necessarily provided in the case where providing the insulator 283 having a function similar to that of the insulator 250b can sufficiently inhibit diffusion of hydrogen into the region 230i from above the transistor 200. The insulator 222b is also not necessarily provided in the case where providing the insulator 215 having a function similar to that of the insulator 222b can sufficiently inhibit diffusion of hydrogen into the region 230i from below the transistor 200.

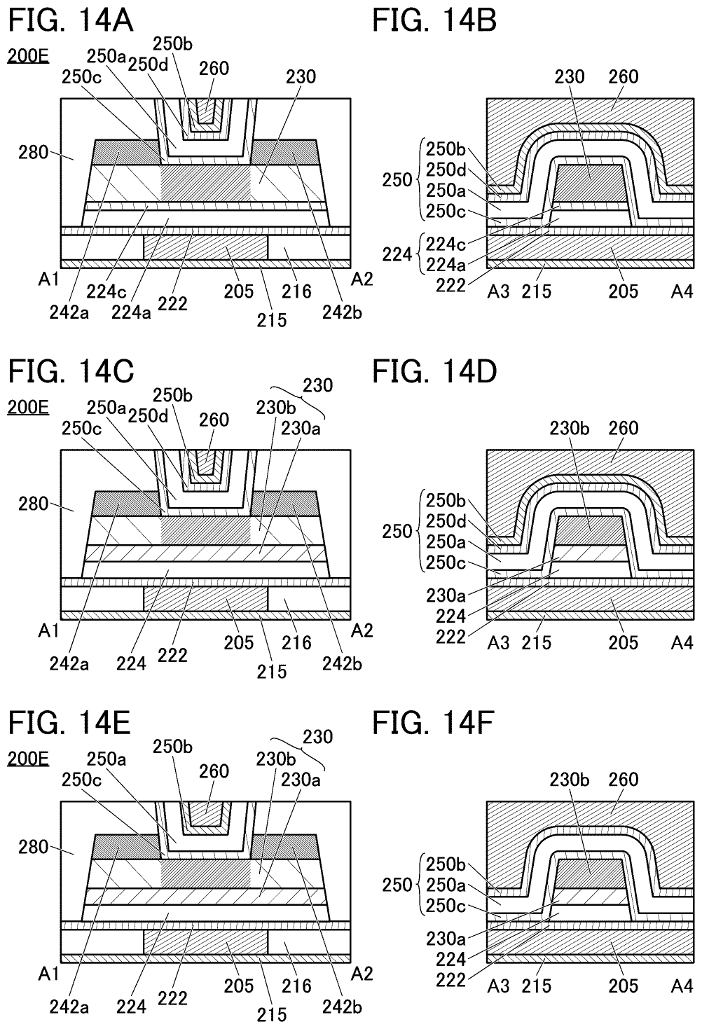

FIG. 14A and FIG. 14B, FIG. 14C and FIG. 14D, and FIG. 14E and FIG. 14F are cross-sectional views of semiconductor devices including the transistors 200E. Here, FIG. 14A, FIG. 14C, and FIG. 14E are cross-sectional views of the transistors 200E in the channel length direction, and FIG. 14B, FIG. 14D, and FIG. 14F are cross-sectional views of the transistors 200E in the channel width direction. Note that FIG. 8A can be referred to for the top views of the semiconductor device illustrated in FIG. 14A and FIG. 14B and the semiconductor device illustrated in FIG. 14C and FIG. 14D. FIG. 3A can be referred to for the top view of the semiconductor device illustrated in FIG. 14E and FIG. 14F.

The transistor 200E illustrated in FIG. 14A and FIG. 14B, the transistor 200E illustrated in FIG. 14C and FIG. 14D, and the transistor 200E illustrated in FIG. 14E and FIG. 14F are different from the transistor 200D illustrated in FIG. 9C and FIG. 9D, the transistor 200D illustrated in FIG. 10C and FIG. 10D, and the transistor 200E illustrated in FIG. 11C and FIG. 11D, respectively, in that the insulator 215 is provided and the insulator 222b is not provided.

Also in the case where the insulator 222b is not provided as illustrated in FIG. 14A to FIG. 14F, providing an insulator having a function of capturing or fixing hydrogen between the oxide 230 and each of the conductor 205 and the insulator 216 can inhibit an increase in the hydrogen concentration in the region 230i.

Note that when the insulator 222 having a large thickness is formed using any of the above-described materials that can be used for the insulator 222b, the transistor 200E illustrated in FIG. 14A and FIG. 14B, the transistor 200E illustrated in FIG. 14C and FIG. 14D, and the transistor 200E illustrated in FIG. 14E and FIG. 14F can each be regarded, like the transistor 200D illustrated in FIG. 12A and FIG. 12B and the transistor 200D illustrated in FIG. 12C and FIG. 12D, as having a structure in which the first stack and the second stack are provided symmetrically with respect to the channel formation region.

### Detailed Structure Example

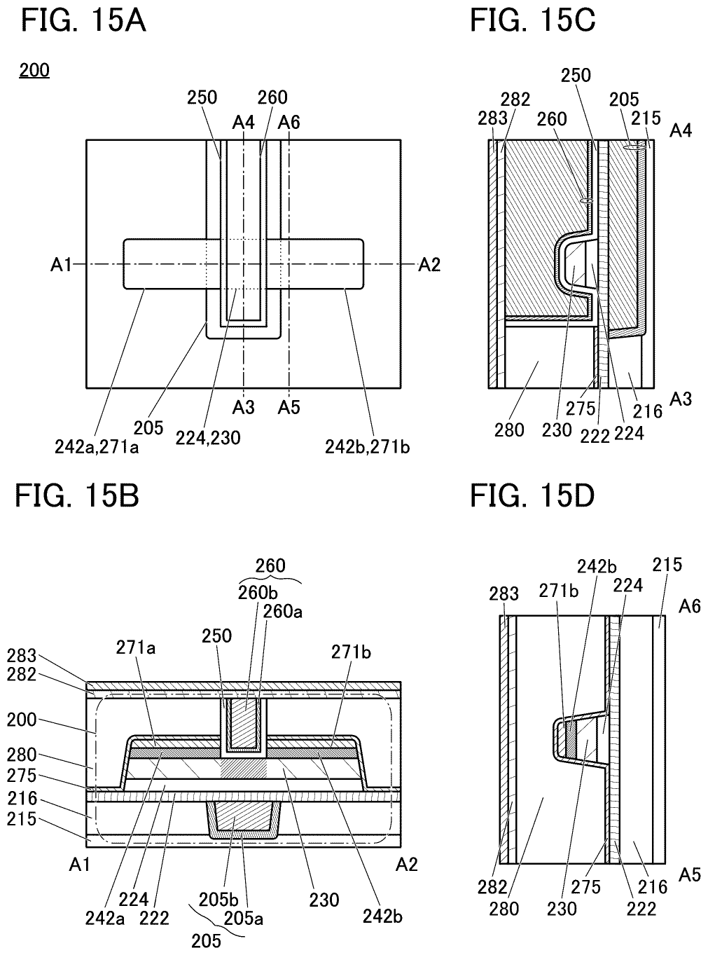

A detailed structure example of a semiconductor device including a transistor will be described with reference to FIG. 15A to FIG. 15D.

FIG. 15A is a top view of a semiconductor device including a transistor 200, and FIG. 15B to FIG. 15D are cross-sectional views of the semiconductor device. Here, FIG. 15B is a cross-sectional view of a portion indicated by the dashed-dotted line A1-A2 in FIG. 15A and is also a cross-sectional view of the transistor 200 in the channel length direction. FIG. 15C is a cross-sectional view of a portion indicated by the dashed-dotted line A3-A4 in FIG. 15A and is also a cross-sectional view of the transistor 200 in the channel width direction. FIG. 15D is a cross-sectional view of a portion indicated by the dashed-dotted line A5-A6 in FIG. 15A and is also a cross-sectional view of the transistor 200 in the channel width direction. Note that some components are omitted in the top view in FIG. 15A for clarity of the drawing. Differences from the above description are mainly described below, and common portions are not described.

The transistor 200 includes the insulator 216 over the insulator 215, the conductor 205 (a conductor 205a and a conductor 205b) provided to be embedded in the insulator 216, the insulator 222 over the insulator 216 and the conductor 205, the insulator 224 over the insulator 222, the oxide 230 over the insulator 224, the conductor 242a and the conductor 242b over the oxide 230, an insulator 271a over the conductor 242a, an insulator 271b over the conductor 242b, the insulator 250 over the oxide 230, and the conductor 260 (a conductor 260a and a conductor 260b) over the insulator 250.

An insulator 275 is provided over the insulator 271a and the insulator 271b, and the insulator 280 is provided over the insulator 275. The insulator 250 and the conductor 260 fill an opening formed in the insulator 280 and the insulator 275. An insulator 282 is provided over the insulator 280, the conductor 260, and the insulator 250. An insulator 283 is provided over the insulator 282.

As illustrated in FIG. 15B, it is preferable that one side end portion of the conductor 242a be aligned with one side end portion of the oxide 230 and one side end portion of the conductor 242b be aligned with the other side end portion of the oxide 230 in the cross-sectional view of the transistor 200. Furthermore, it is preferable that the side end portion of the insulator 224 be aligned with the side end portion of the oxide 230. When the insulator 224, the oxide 230, and a conductive layer to be the conductor 242a and the conductor 242b are collectively processed into an island shape, the semiconductor device can be fabricated with favorable productivity. In that case, the side end portions of the insulator 224, the oxide 230, the conductor 242a, and the conductor 242b are aligned with each other as described above.

The transistor 200 illustrated in FIG. 15A to FIG. 15D preferably has any one of the above-described structures of the transistor 200A to the transistor 200E.

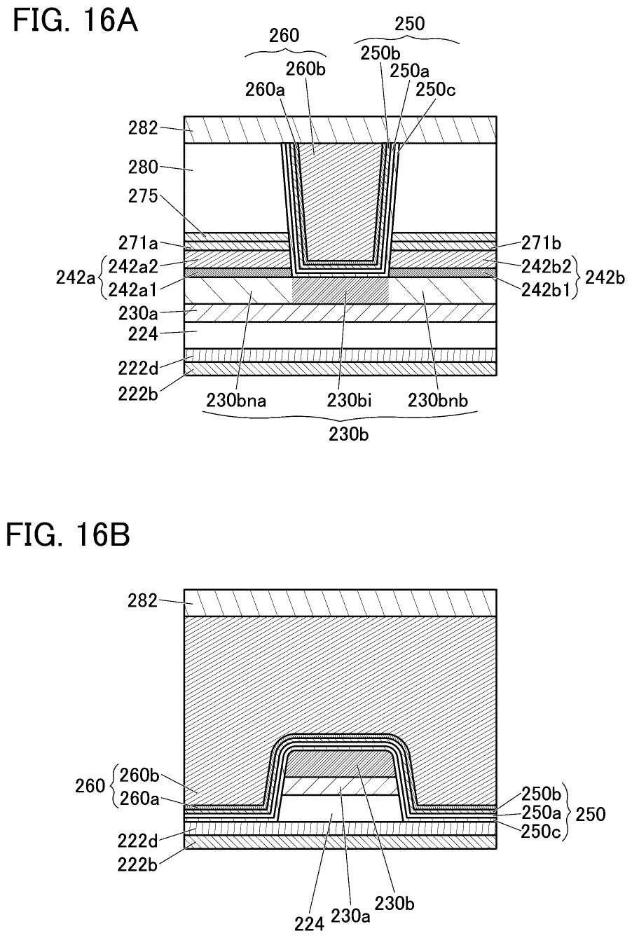

FIG. 16A and FIG. 16B illustrate an example in which the transistor 200 illustrated in FIG. 15A to FIG. 15D has the structure of the transistor 200D illustrated in FIG. 11C and FIG. 11D. FIG. 16A is an enlarged cross-sectional view of the transistor 200 in the channel length direction, and FIG. 16B is an enlarged cross-sectional view of the transistor 200 in the channel width direction.

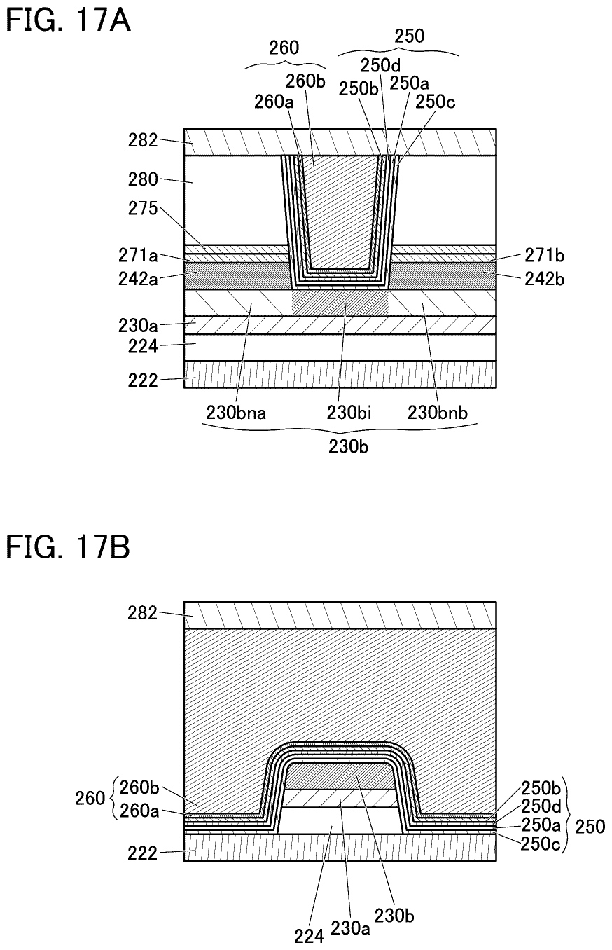

FIG. 17A and FIG. 17B illustrate an example in which the transistor 200 illustrated in FIG. 15A to FIG. 15D has the structure of the transistor 200E illustrated in FIG. 14C and FIG. 14D. FIG. 17A is an enlarged cross-sectional view of the transistor 200 in the channel length direction, and FIG. 17B is an enlarged cross-sectional view of the transistor 200 in the channel width direction.

As illustrated in FIG. 16A to FIG. 17B, the oxide 230 preferably includes the oxide 230a over the insulator 224 and the oxide 230b over the oxide 230a.

The oxide 230a and the oxide 230b preferably have different chemical compositions. When the oxide 230a and the oxide 230b contain a common element as the main component besides oxygen, the density of defect states at an interface between the oxide 230a and the oxide 230b can be decreased. The density of defect states at the interface between the oxide 230a and the oxide 230b can be decreased. Thus, the influence of interface scattering on carrier conduction is reduced, and the transistor 200 can have a high on-state current and high frequency characteristics.

An oxide semiconductor having crystallinity is preferably used for the oxide 230b. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. For the oxide 230b, the CAAC-OS or the nc-OS is preferably used, and the CAAC-OS is particularly preferably used.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as the CAAC-OS, is used as the oxide 230b, oxygen extraction from the oxide 230b by the conductor 242a or the conductor 242b can be inhibited. This can inhibit oxygen extraction from the oxide 230b even when heat treatment is performed; thus, the transistor 200 is stable with respect to high temperatures in a manufacturing process (what is called thermal budget). Furthermore, it is possible to inhibit a reduction in the conductivity of the conductor 242a and the conductor 242b.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal (also referred to as a nanocrystal). Furthermore, there is no regularity of crystal orientation between different nanocrystals in the nc-OS, and thus the orientation in the whole film is not observed. That is, in the case where the nc-OS is used as the oxide 230b, the oxide 230b has uniform film characteristics regardless of the direction of carriers flowing in the oxide 230b; thus, the transistor has stable electrical characteristics.

Note that oxide semiconductors have various structures with different properties. The oxide 230b may include two or more kinds of the CAAC-OS, the nc-OS, an amorphous-like oxide semiconductor (a-like OS), an amorphous oxide semiconductor, a polycrystalline oxide semiconductor, and a CAC-OS (cloud-aligned composite oxide semiconductor).

When a CAAC-OS film is subjected to structural analysis by Out-of-plane XRD measurement with an XRD apparatus using θ/2θ scanning, for example, a peak indicating c-axis alignment is detected at or around 2θ=31°. Note that the position of the peak indicating c-axis alignment (the value of 2θ) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

In some cases, a plurality of spots in a ring-like region with a direct spot as the center are observed in the obtained electron diffraction pattern when an nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

As illustrated in FIG. 16A and FIG. 17A, the oxide 230b includes a region 230bi, and a region 230bna and a region 230bnb provided such that the region 230bi is sandwiched therebetween. Note that the above description of the region 230i, the region 230na, and the region 230nb can be referred to for the region 230bi, the region 230bna, and the region 230bnb.

Although FIG. 16A to FIG. 17B illustrate examples in which the oxide 230 has a two-layer structure of the oxide 230a and the oxide 230b, one embodiment of the present invention is not limited thereto. The oxide 230 may have a single-layer structure as illustrated in FIG. 1, FIG. 1C, and the like, for example. One or both of the oxide 230a and the oxide 230b may have a stacked-layer structure of two or more layers. Note that in the case where the oxide 230 has a single-layer structure, any of the above-described metal oxides that can be used as the oxide 230a may be used as the oxide 230.

As illustrated in FIG. 16A and FIG. 16B, the insulator 250 preferably has a stacked-layer structure of the insulator 250c in contact with the oxide 230, the insulator 250a over the insulator 250c, and the insulator 250b over the insulator 250a. Alternatively, as illustrated in FIG. 17A and FIG. 17B, the insulator 250 preferably has a stacked-layer structure of the insulator 250c in contact with the oxide 230, the insulator 250a over the insulator 250c, the insulator 250d over the insulator 250a, and the insulator 250b over the insulator 250d.

The insulator 250a to the insulator 250d are provided in an opening formed in the insulator 280 and the like, together with the conductor 260. The thicknesses of the insulator 250a to the insulator 250d are preferably small for miniaturization of the transistor 200. The thickness of each of the insulator 250a to the insulator 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that at least part of each of the insulator 250a to the insulator 250d includes a region having the above-described thickness.

To form the insulator 250a to the insulator 250d having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables deposition at a lower temperature.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 250 can be deposited on the side surface of the opening portion formed in the insulator 280 and the insulator 275, the side end portions of the conductor 242a and the conductor 242b, and the like, with a small thickness like the above-described thickness and favorable coverage.

Note that some precursors used in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

Although the structure in which the insulator 250 has the three-layer structure of the insulator 250a to the insulator 250c or the four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the fabrication process of the semiconductor device can be simplified and the productivity can be increased.

As illustrated in FIG. 16A and FIG. 16B, the insulator 222 preferably has a stacked-layer structure of the insulator 222b over the insulator 216 and the conductor 205 and the insulator 222d over the insulator 222b.

The insulator 222b is provided between the insulator 222d and each of the insulator 216 and the conductor 205. The insulator 222b preferably has a function of inhibiting diffusion of hydrogen. This can inhibit diffusion of hydrogen into the transistor 200 from below the insulator 222b. Note that the insulator 222b can also function as the insulator 215. In such a case, the structure without the insulator 215 enables simplification of the fabrication process and the improvement in productivity of the semiconductor device.

For the insulator 222b, silicon nitride deposited by an ALD method (especially a PEALD method) is preferably used, for example. When deposited by an ALD method, the insulator 222b can have favorable coverage even when unevenness is formed by the insulator 216 and the conductor 205. This can inhibit formation of a pinhole, step disconnection, or the like in the insulator 222d deposited over the insulator 222b.

Alternatively, as illustrated in FIG. 17A and FIG. 17B, the insulator 222 preferably has a single-layer structure. Note that the insulator 222 having a large thickness is preferably formed using any of the above-described materials that can be used for the insulator 222b, as in the transistor 200D illustrated in FIG. 12A and FIG. 12B and the transistor 200D illustrated in FIG. 12C and FIG. 12D.

Although the structure in which the insulator 222 has a single-layer structure or a two-layer structure of the insulator 222b and the insulator 222d is described above, the present invention is not limited thereto. The insulator 222 may have a stacked-layer structure of three or more layers.

The insulator 224 is preferably processed into an island shape in the same manner as the oxide 230. Thus, in the case where a plurality of the transistors 200 are provided, the insulator 224 having substantially the same size is provided in each of the transistors 200. Accordingly, among the transistors 200, the amount of oxygen supplied from the insulator 224 to the oxide 230 is substantially the same. This can reduce variations in electrical characteristics of the transistors 200 in the substrate plane.

Note that the insulator 224 may have a stacked-layer structure of two or more layers. In that case, the stacked layers are not necessarily formed of the same material and may be formed of different materials. A structure in which the insulator 224 is not provided as illustrated in FIG. 1B or the like may be employed.

The insulator 275 preferably has a barrier property against oxygen. The insulator 275 is provided between the insulator 280 and the conductor 242a and between the insulator 280 and the conductor 242b. Providing the insulator 275 can inhibit diffusion of oxygen contained in the insulator 280 into the conductor 242a and the conductor 242b. Thus, the conductor 242a and the conductor 242b can be inhibited from being oxidized by oxygen contained in the insulator 280, so that an increase in resistivity and a reduction in on-state current can be inhibited. The insulator 275 is preferably less permeable to oxygen than at least the insulator 280 is. For example, silicon nitride is preferably used for the insulator 275. In that case, the insulator 275 contains at least nitrogen and silicon.

Note that the insulator 275 is provided between the insulator 280 and the region 230bna and between the insulator 280 and the region 230bnb. In other words, the region 230bna and the region 230bnb are surrounded by the insulator 275 and the oxide 230a. Thus, oxygen contained in the insulator 280 can be inhibited from diffusing into the region 230bna and the region 230bnb.

The insulator 275 preferably has a barrier property against hydrogen. The insulator 275 having a barrier property against hydrogen can inhibit a reduction in the hydrogen concentration in the region 230bna and the region 230bnb.

Examples of a barrier insulator against hydrogen include oxides such as aluminum oxide, hafnium oxide, and tantalum oxide and nitrides such as silicon nitride. For example, the insulator 275 preferably has a single-layer structure or a stacked-layer structure of the barrier insulator against hydrogen.

With the above-described structure, the region 230bi can be an i-type or substantially i-type region, and the region 230bna and the region 230bnb can be n-type regions. Thus, a semiconductor device with favorable electrical characteristics can be provided. The semiconductor device can have favorable electrical characteristics even when miniaturized or highly integrated. Miniaturization of the transistor 200 can improve the high frequency characteristics. Specifically, the cutoff frequency can be improved.

The insulator 271a is in contact with the top surface of the conductor 242a and the bottom surface of the insulator 275, and the insulator 271b is in contact with the top surface of the conductor 242b and the bottom surface of the insulator 275.

The insulator 271a and the insulator 271b function as etching stoppers for protecting the conductor 242a and the conductor 242b. Accordingly, as illustrated in FIG. 15B, it is preferable that a side end portion of the insulator 271a be aligned with the side end portion of the conductor 242a and a side end portion of the insulator 271b be aligned with the side end portion of the conductor 242b in the cross-sectional view of the transistor 200.

Since the insulator 271a and the insulator 271b are respectively in contact with the conductor 242a and the conductor 242b, the insulator 271a and the insulator 271b are preferably inorganic insulators that are less likely to oxidize the conductor 242a and the conductor 242b. For example, a nitride insulator that can be used for the insulator 250b is preferably used for the insulator 271a and the insulator 271b.

Although FIG. 15B illustrates each of the insulator 271a and the insulator 271b as a single layer, the present invention is not limited thereto. The insulator 271a and the insulator 271b may each have a stacked-layer structure.

In addition to the above structure, the semiconductor device of this embodiment preferably has a structure that inhibits entry of hydrogen into the transistor 200 and the like. For example, one or both of upper and lower insulators having a function of inhibiting diffusion of hydrogen is/are preferably provided to cover the transistor 200 and the like. In the semiconductor device described in this embodiment, the insulator corresponds to the insulator 215, the insulator 282, and the insulator 283, for example. Note that the insulator 215 provided under the transistor 200 may have a structure similar to the structure of one or both of the insulator 282 and the insulator 283. In such a case, the insulator 215 may have a stacked-layer structure of the insulator 282 and the insulator 283; the insulator 282 may be the lower layer and the insulator 283 may be the upper layer, or the insulator 282 may be the upper layer and the insulator 283 may be the lower layer. Note that in the case where the insulator 215 has a structure in which the insulator 282 is the upper layer and the insulator 283 is the lower layer, the insulator 215 and each of the insulator 282 and the insulator 283 are provided symmetrically with respect to the channel formation region.

One or both of the insulator 282 and the insulator 283 preferably function as a barrier insulator that inhibits diffusion of impurities such as water and hydrogen into the transistor 200 and the like from the substrate side or from above the transistor 200 and the like. Thus, one or both of the insulator 282 and the insulator 283 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom (an insulating material that is less permeable to the impurities). Alternatively, it is preferable to contain an insulating material having a function of inhibiting diffusion of oxygen (e.g., at least one of an oxygen atom, an oxygen molecule, and the like) (an insulating material that is less permeable to oxygen).

The insulator 282 and the insulator 283 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a higher hydrogen barrier property, is preferably used for the insulator 283. For example, the insulator 282 preferably contains aluminum oxide, magnesium oxide, or the like, which has a function of capturing or fixing hydrogen well. Thus, impurities such as water and hydrogen can be inhibited from diffusing into the transistor 200 and the like from an interlayer insulating film and the like that are provided on the outer side of the insulator 283. Moreover, oxygen contained in the insulator 280 and the like can be inhibited from diffusing to above the transistor 200 and the like through the insulator 282 and the like. When the insulator 215 has a structure similar to that of one or both of the insulator 282 and the insulator 283, it is possible to inhibit diffusion of impurities such as water and hydrogen into the transistor 200 and the like from the substrate side through the insulator 215. Moreover, oxygen contained in the insulator 224 and the like can be inhibited from diffusing to the substrate side. In this manner, it is preferable that the transistor 200 and the like be surrounded by upper and lower insulators having a function of inhibiting diffusion of oxygen and impurities such as water and hydrogen.

The conductor 205 may have a single-layer structure or a stacked-layer structure. In FIG. 15B and FIG. 15C, the conductor 205 includes the conductor 205a and the conductor 205b. The conductor 205a is provided in contact with the bottom surface and the sidewall of the opening portion formed in the insulator 216. The conductor 205b is provided to fill a depressed portion that is defined by the conductor 205a and formed along the opening portion.

Here, the conductor 205a preferably contains a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to contain a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from diffusing into the oxide 230 through the insulator 216 and the like. When the conductor 205a is formed using a conductive material having a function of inhibiting diffusion of oxygen, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride.

The conductor 205b is preferably formed using a conductive material containing tungsten, copper, or aluminum as its main component. For example, the conductor 205b preferably contains tungsten.

The conductor 242a and the conductor 242b each include a region in contact with the oxide 230b. The conductor 242a and the conductor 242b may each have a single-layer structure or a stacked-layer structure. For example, as illustrated in FIG. 16A, the conductor 242a and the conductor 242b may each have a two-layer structure. In this case, the conductor 242a is a stack of a conductor 242al and a conductor 242a2 over the conductor 242al, and the conductor 242b is a stack of a conductor 242b1 and a conductor 242b2 over the conductor 242b1. At this time, the layers in contact with the oxide 230b (the conductor 242al and the conductor 242b1) are preferably formed using the above-described conductive material that is less likely to be oxidized or the above-described conductive material having a function of inhibiting diffusion of oxygen. Thus, the conductor 242a and the conductor 242b can be prevented from being oxidized excessively by oxygen contained in the oxide 230b. Furthermore, it is possible to inhibit a reduction in the conductivity of the conductor 242a and the conductor 242b.

The conductor 242a2 and the conductor 242b2 preferably have higher conductivity than the conductor 242al and the conductor 242b1. For example, the thicknesses of the conductor 242a2 and the conductor 242b2 are preferably larger than the thicknesses of the conductor 242al and the conductor 242b1. As the conductor 242a2 and the conductor 242b2, a conductor that can be used for the conductor 205b is used. The above structure can reduce the resistances of the conductor 242a2 and the conductor 242b2. Accordingly, the conductor 242a and the conductor 242b can each function as a wiring or an electrode with high conductivity. This can also increase the operating speed of the transistor 200.

For example, tantalum nitride or titanium nitride can be used for the conductor 242al and the conductor 242b1, and tungsten can be used for the conductor 242a2 and the conductor 242b2.

As illustrated in FIG. 16A to FIG. 17B, the conductor 260 is provided to fill the opening portion formed in the insulator 280 and the insulator 275. The conductor 260 is provided in the opening portion to cover the side surface of the insulator 224, the side surface of the oxide 230a, and the side surface and the top surface of the oxide 230b with the insulator 250 therebetween.

As illustrated in FIG. 16B and FIG. 17B, a curved surface may be provided between the side surface of the oxide 230b and the top surface of the oxide 230b in a cross-sectional view of the transistor 200 in the channel width direction. That is, an end portion of the side surface and an end portion of the top surface may be curved (hereinafter also referred to as rounded). Such a shape can improve the coverage of the oxide 230b with the insulator 250 and the conductor 260.

In the structure provided with the insulator 224 having an island shape, at least part of the bottom surface of the conductor 260 can be provided below the bottom surface of the oxide 230b, as illustrated in FIG. 16B and FIG. 17B. Thus, the conductor 260 can be provided to face the top surface and the side surface of the oxide 230b, so that an electric field of the conductor 260 can be applied to the top surface and the side surface of the oxide 230b. When the insulator 224 having an island shape is provided in this manner, the transistor having the S-channel structure can be easily obtained.

Note that the S-channel structure disclosed in this specification and the like has a structure different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor 200 has the S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure.

Although FIG. 16B and FIG. 17B illustrate a transistor with the S-channel structure as the transistor 200, the semiconductor device of one embodiment of the present invention is not limited thereto. For example, a transistor structure that can be used in one embodiment of the present invention may be one or more selected from the planar structure, the Fin-type structure, and the GAA structure.

FIG. 16A and FIG. 17A illustrate the conductor 260 as having a two-layer structure. Here, the conductor 260 preferably includes the conductor 260a and the conductor 260b placed over the conductor 260a. For example, the conductor 260a is preferably placed to cover the bottom surface and a side surface of the conductor 260b. In this case, the conductor 260a is preferably formed using a conductive material that is less likely to be oxidized or a conductive material having a function of inhibiting diffusion of oxygen.

The conductor 260a is preferably formed using a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 280 or the like. As the conductive material having a function of inhibiting diffusion of oxygen, titanium, titanium nitride, tantalum, tantalum nitride, ruthenium, or ruthenium oxide is preferably used, for example.

As the conductor 260b, a conductor having high conductivity is preferably used. For example, the conductor 260b can be formed using a conductive material containing tungsten, copper, or aluminum as its main component. The conductor 260b may have a stacked-layer structure; for example, a stacked-layer structure of titanium or titanium nitride and the above conductive material may be employed.

In the transistor 200, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment.

Although FIG. 16A illustrate the structure in which the insulator 250c is in contact with the side surfaces of the conductor 242a2 and the conductor 242b2, the present invention is not limited thereto. For example, an insulator 255 may be provided between the insulator 250c and the conductor 242a2 and between the insulator 250c and the conductor 242b2.

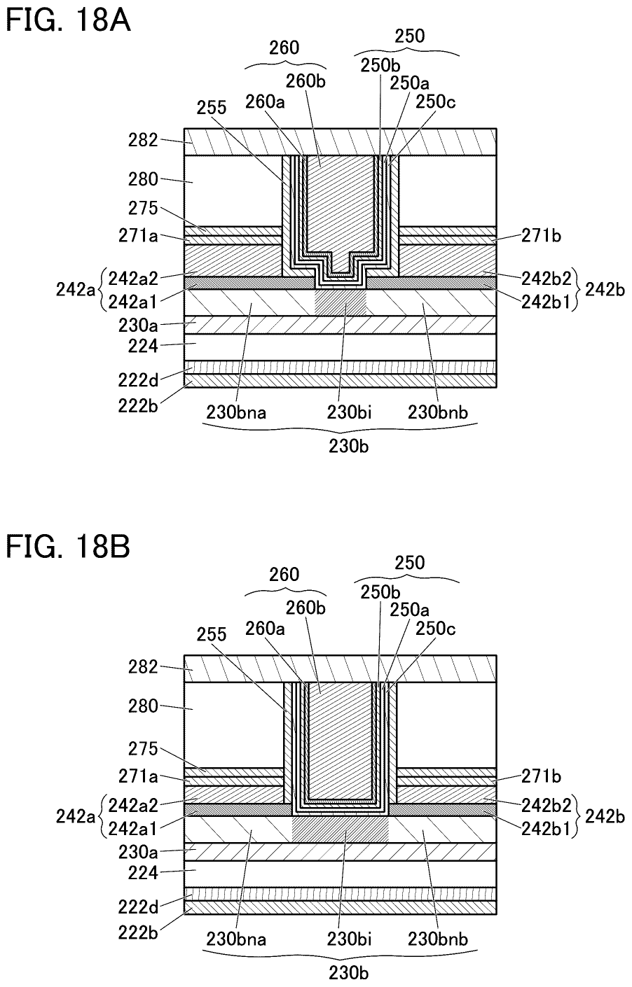

FIG. 18A and FIG. 18B are enlarged cross-sectional views of the transistor 200 in the channel length direction. A semiconductor device illustrated in FIG. 18A and a semiconductor device illustrated in FIG. 18B are modification examples of the semiconductor device illustrated in FIG. 16A. Specifically, the semiconductor device illustrated in FIG. 18A and the semiconductor device illustrated in FIG. 18B are different from the semiconductor device illustrated in FIG. 16A in that the insulator 255 is included between the insulator 250c and the conductor 242a2 and between the insulator 250c and the conductor 242b2.

As illustrated in FIG. 18A, in a cross-sectional view of the transistor 200 in the channel length direction, a distance between the conductor 242al and the conductor 242b1 is smaller than a distance between the conductor 242a2 and the conductor 242b2. With such a structure, the distance between the source and the drain can be shorter and accordingly the channel length can be shortened. Thus, the frequency characteristics of the transistor 200 can be improved. In this manner, miniaturization of the semiconductor device enables the semiconductor device to have a higher operation speed.

The insulator 255 is preferably an insulator that is not easily oxidized, such as a nitride. The insulator 255 is formed in contact with the side surface of the conductor 242a2 and the side surface of the conductor 242b2 and has a function of protecting the conductor 242a2 and the conductor 242b2. The insulator 255 is exposed to an oxidizing atmosphere, and thus is preferably an inorganic insulator that is not easily oxidized. Since the insulator 255 is in contact with the conductor 242a2 and the conductor 542b2, the insulator 255 is preferably an inorganic insulator that is less likely to oxidize the conductor 242a2 and the conductor 242b2. Thus, the insulator 255 is preferably formed using an insulating material having a barrier property against oxygen. The insulator 255 can be formed using silicon oxynitride, for example.

The transistor 200 illustrated in FIG. 18A is formed by forming an opening portion in the insulator 280 and the insulator 275, forming the insulator 255 in contact with a sidewall of the opening portion, and separating the conductor 242al and the conductor 242b1 using a mask. Here, the opening portion overlaps with a region between the conductor 242a2 and the conductor 242b2. Part of the conductor 242a1 and part of the conductor 242b1 are each formed to extend to the opening portion. Thus, in the opening portion, the insulator 255 is in contact with the top surface of the conductor 242a1, the top surface of the conductor 242b1, the side surface of the conductor 242a2, and the side surface of the conductor 242b2. The insulator 250 is in contact with the top surface of the oxide 230 in a region between the conductor 242al and the conductor 242b1.

Heat treatment in an atmosphere containing oxygen is preferably performed after the separation of the conductor 242al and the conductor 242b1 and before the deposition of the insulator 250. Accordingly, oxygen can be supplied to the oxide 230 to reduce oxygen vacancies. Moreover, since the insulator 255 is formed in contact with the side surface of the conductor 242a2 and the side surface of the conductor 242b2, excessive oxidation of the conductor 242a2 and the conductor 242b2 can be prevented. Thus, the electrical characteristics and reliability of the transistor can be improved. In addition, variations in electrical characteristics of transistors formed over the same substrate can be reduced.

Although FIG. 18A illustrates a structure in which the insulator 250 includes the regions overlapping with the conductor 242al and the conductor 242b1 with the insulator 255 therebetween, the present invention is not limited thereto. For example, as illustrated in FIG. 18B, the side surface of the insulator 255 may be aligned with the side surface of the conductor 242al and the side surface of the insulator 255 may be aligned with the side surface of the conductor 242b1 in the opening portion formed in the insulator 280 and the insulator 275. Such a structure can eliminate the above-described step of separating the conductor 242al and the conductor 242b1 using a mask, thereby simplifying the fabrication process of the semiconductor device and improving the productivity.

Although FIG. 18A and FIG. 18B each illustrate an example in which the first stack and the second stack have the structure in the transistor 200D illustrated in FIG. 11C and FIG. 11D, any one of the above-described structures of the transistor 200A to the transistor 200E may be employed.

### <Component Material of Semiconductor Device>

Component materials that can be used for the semiconductor device are described below. Note that each layer included in the semiconductor device may have a single-layer structure or a stacked-layer structure.

### <<Substrate>>

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples of substrates include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided for the substrate include a capacitor, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a low-dielectric-constant material is used for the insulator functioning as an interlayer film, parasitic capacitance generated between wirings can be reduced. Thus, a material is preferably selected depending on the function of the insulator.

Examples of the high-dielectric-constant (high-k) material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the low-dielectric-constant material include inorganic insulating materials such as silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide and resins such as polyester, polyolefin, polyamide (e.g., nylon and aramid), polyimide, polycarbonate, and acrylic. Note that the low-dielectric-constant material is a material with high dielectric strength.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used. Specific examples of the insulator having a function of inhibiting passage of oxygen and impurities such as hydrogen include a metal oxide such as aluminum oxide, magnesium oxide, gallium oxide, germanium oxide, yttrium oxide, zirconium oxide, lanthanum oxide, neodymium oxide, hafnium oxide, or tantalum oxide and a metal nitride such as aluminum nitride, silicon nitride oxide, or silicon nitride.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductor include tantalum nitride, titanium nitride, tungsten, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

In the case of using a conductor having a stacked-layer structure, for example, a stacked-layer structure combining a material containing the above metal element and a conductive material containing oxygen, a stacked-layer structure combining a material containing the above metal element and a conductive material containing nitrogen, or a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

The semiconductor device of this embodiment includes OS transistors. Since the off-state current of the OS transistors is low, a semiconductor device with low power consumption can be obtained. Since the OS transistors have high frequency characteristics, a semiconductor device with a high operation speed can be obtained. With use of the OS transistors, a semiconductor device having favorable electrical characteristics, a semiconductor device with a small variation in electrical characteristics of transistors, a semiconductor device with a high on-state current, or a highly reliable semiconductor device can be obtained.

### <Application Example of Semiconductor Device>

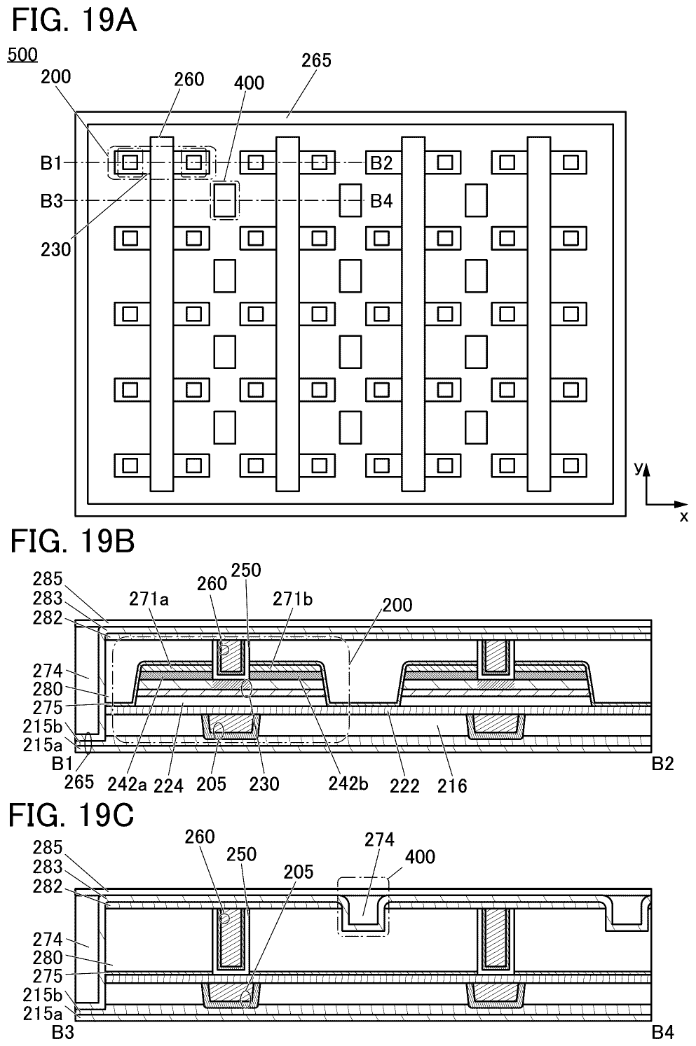

An example of the semiconductor device of one embodiment of the present invention is described below with reference to FIG. 19A to FIG. 19C.

FIG. 19A is a top view of a semiconductor device 500. In FIG. 19A, the x-axis is parallel to the channel length direction of the transistor 200, and the y-axis is perpendicular to the x-axis. FIG. 19B is a cross-sectional view corresponding to a portion indicated by the dashed-dotted line A1-A2 in FIG. 19A and is also a cross-sectional view of the transistor 200 in the channel length direction. FIG. 19C is a cross-sectional view corresponding to a portion indicated by the dashed-dotted line A3-A4 in FIG. 19A and is also a cross-sectional view of an opening region 400 and the vicinity thereof. Note that some components are omitted in the top view in FIG. 19A for clarity of the drawing.

Note that in the semiconductor device illustrated in FIG. 19A to FIG. 19C, components having the same functions as the components included in the semiconductor device described in <Detailed structure example> are denoted by the same reference numerals. Note that the materials described in detail in <Detailed structure example> can be used as component materials of the semiconductor device also in this section.

The semiconductor device 500 illustrated in FIG. 19A to FIG. 19C is a modification example of the semiconductor device illustrated in FIG. 15A to FIG. 15D. The semiconductor device 500 illustrated in FIG. 19A to FIG. 19C differs from the semiconductor device illustrated in FIG. 15A to FIG. 15D in that the opening region 400 is formed in the insulator 282 and the insulator 280. Moreover, a sealing portion 265 is formed to surround a plurality of transistors 200, which is a different point from the semiconductor device illustrated in FIG. 15A to FIG. 15D.

The semiconductor device 500 includes a plurality of transistors 200 and a plurality of opening regions 400 arranged in a matrix. In addition, a plurality of conductors 260 functioning as gate electrodes of the transistors 200 are provided to extend in the y-axis direction. The opening regions 400 are formed in regions not overlapping with the oxide 230 or the conductor 260. The sealing portion 265 is formed so as to surround the plurality of transistors 200, the plurality of conductors 260, and the plurality of opening regions 400. Note that the number, the position, and the size of the transistors 200, the conductors 260, and the opening regions 400 are not limited to those illustrated in FIG. 19A to FIG. 19C and may be set as appropriate in accordance with the design of the semiconductor device 500.

An insulator 285 is provided over the insulator 283. As the insulator 285, an insulator similar to the insulator 280 can be used.

As illustrated in FIG. 19B and FIG. 19C, the sealing portion 265 is provided to surround the plurality of transistors 200, the insulator 216, the insulator 222, the insulator 275, the insulator 280, and the insulator 282. In other words, the insulator 283 is provided to cover the plurality of transistors 200, the insulator 216, the insulator 222, the insulator 275, the insulator 280, and the insulator 282. In the sealing portion 265, the insulator 283 is in contact with the top surface of an insulator 215b. Above the sealing portion 265, an insulator 274 is provided between the insulator 283 and the insulator 285. The top surface of the insulator 274 is level with the uppermost surface of the insulator 283. As the insulator 274, an insulator similar to the insulator 280 can be used.

Such a structure enables the plurality of transistors 200 to be surrounded by the insulator 283, the insulator 215b and an insulator 215a. Here, one or more of the insulator 283, the insulator 215b, and the insulator 215a preferably function as a barrier insulator against hydrogen. Accordingly, entry of hydrogen contained in a region outside the sealing portion 265 into a region inside the sealing portion 265 can be inhibited.

As illustrated in FIG. 19C, the insulator 282 in the opening region 400 has an opening portion. In the opening region 400, the insulator 280 may have a groove portion overlapping with the opening portion in the insulator 282. The depth of the groove portion of the insulator 280 is less than or equal to the depth at which the top surface of the insulator 275 is exposed and is, for example, approximately greater than or equal to ¼ and less than or equal to ½ of the maximum thickness of the insulator 280.

As illustrated in FIG. 19C, the insulator 283 inside the opening region 400 is in contact with the side surface of the insulator 282, the side surface of the insulator 280, and the top surface of the insulator 280. Part of the insulator 274 is formed in the opening region 400 to fill the depressed portion formed in the insulator 283 in some cases. At this time, the top surface of the insulator 274 formed in the opening region 400 is level with the uppermost surface of the insulator 283, in some cases.

When heat treatment is performed in such a state that the opening region 400 is formed and the insulator 280 is exposed in the opening portion of the insulator 282, part of oxygen contained in the insulator 280 can be made to diffuse outwardly from the opening region 400 while oxygen is supplied to the oxide 230. This enables oxygen to be sufficiently supplied to the region functioning as the channel formation region and its vicinity in the oxide semiconductor from the insulator 280 containing oxygen to be released by heating, and also prevents an excess amount of oxygen from being supplied thereto.

At this time, hydrogen contained in the insulator 280 can be bonded to oxygen and released to the outside through the opening region 400. The hydrogen bonded to oxygen is released as water. Thus, the amount of hydrogen contained in the insulator 280 can be reduced, and hydrogen contained in the insulator 280 can be inhibited from entering the oxide 230.

In FIG. 19A, the shape of the opening region 400 in the top view is substantially rectangular; however, the present invention is not limited to the shape. For example, the shape of the opening region 400 in the top view can be a rectangular shape, an elliptical shape, a circular shape, a rhombus shape, or a shape obtained by combining any of the above shapes. The area and arrangement interval of the opening regions 400 can be set as appropriate in accordance with the design of the semiconductor device including the transistors 200. For example, in the region where the density of the transistors 200 is low, the area of the opening region 400 may be increased or the arrangement interval of the opening regions 400 may be narrowed. For example, in the region where the density of the transistors 200 is high, the area of the opening region 400 may be decreased, or the arrangement interval of the opening regions 400 may be increased.

According to one embodiment of the present invention, a novel transistor can be provided. Alternatively, a semiconductor device having favorable electrical characteristics can be provided. Alternatively, a highly reliable semiconductor device can be provided. Alternatively, a semiconductor device with a small variation in transistor characteristics can be provided. Alternatively, a semiconductor device with a high on-state current can be provided. Alternatively, a semiconductor device with a high field-effect mobility can be provided. Alternatively, a semiconductor device with favorable frequency characteristics can be provided. Alternatively, a semiconductor device that can be miniaturized or highly integrated can be provided. Alternatively, a semiconductor device with low power consumption can be provided.

### <Structure Example of Semiconductor Device Including Transistor 200 and Capacitor 100>

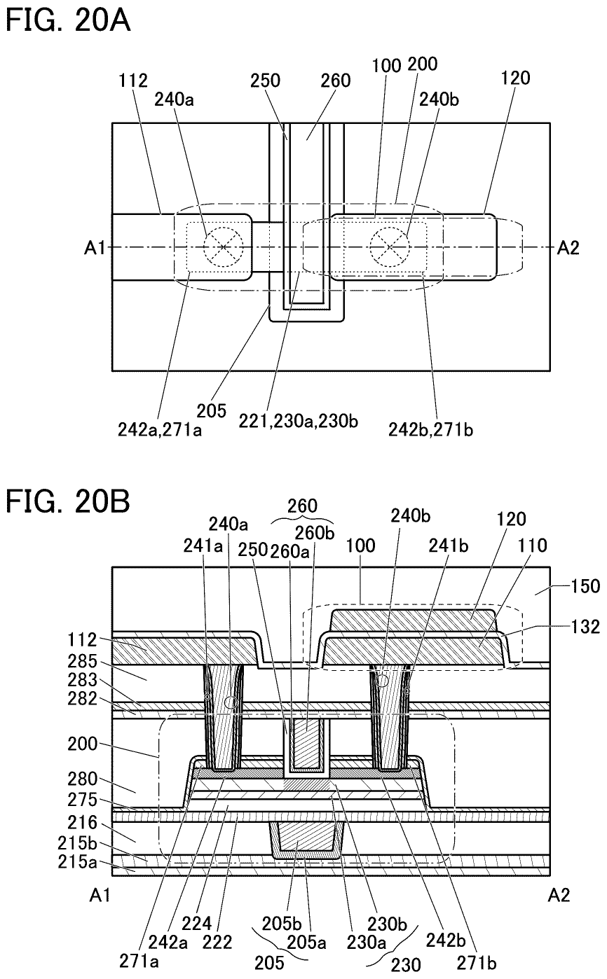

FIG. 20A and FIG. 20B illustrate a semiconductor device including the above transistor 200 and a capacitor 100. FIG. 20A is a top view of the semiconductor device. FIG. 20B is a cross-sectional view of a portion indicated by the dashed-dotted line A1-A2 in FIG. 20A and is also a cross-sectional view of the transistor 200 in the channel length direction. Note that some components are omitted in the top view in FIG. 20A for clarity of the drawing.

In the semiconductor device illustrated in FIG. 20A and FIG. 20B, the capacitor 100 and a conductor 112 are provided over the transistor 200. Here, the area where the capacitor 100 and the transistor 200 overlap with each other is preferably large in the top view. Such a structure can reduce the area occupied by the semiconductor device including the capacitor 100 and the transistor 200. In that case, miniaturization and high integration of the semiconductor device can be achieved.

The semiconductor device includes a conductor 240a and a conductor 240b that function as plugs. The conductor 240a is provided in an opening formed in the insulator 285, the insulator 283, the insulator 282, the insulator 280, the insulator 275, and the insulator 271a, and the conductor 240b is provided in an opening formed in the insulator 285, the insulator 283, the insulator 282, the insulator 280, the insulator 275, and the insulator 271b.

As illustrated in FIG. 20B, the conductor 240a includes a region in contact with the conductor 242a and a region in contact with at least part of the bottom surface of the conductor 112. The conductor 240b includes a region in contact with the conductor 242b and a region in contact with at least part of the bottom surface of a conductor 110 included in the capacitor 100. That is, the conductor 240a is electrically connected to one of the source and the drain of the transistor 200, and the conductor 240b is electrically connected to the other of the source and the drain of the transistor 200.

The conductor 240a and the conductor 240b are preferably formed using a conductive material containing tungsten, copper, or aluminum as its main component, for example. The conductor 240a and the conductor 240b may each have a stacked-layer structure of a first conductor provided along side surfaces and a bottom surface of the opening and a second conductor over the first conductor.

In the case where the conductor 240a and the conductor 240b have a stacked-layer structure, the first conductor placed in the vicinity of the insulator 285 and the insulator 280 is preferably formed using a conductive material having a function of inhibiting passage of impurities such as water and hydrogen. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. With such a structure, impurities such as water and hydrogen contained in a layer above the insulator 283 can be inhibited from entering the oxide 230 through the conductor 240a and the conductor 240b. Note that the second conductor functions also as a wiring and thus is preferably formed using a conductor having high conductivity. The second conductor is formed using the conductive material containing tungsten, copper, or aluminum as its main component, for example.

Although the conductor 240a and the conductor 240b illustrated in FIG. 20B are each illustrated as the stack structure of the first conductor and the second conductor, the present invention is not limited thereto. For example, the conductor 240 may have a single-layer structure or a stacked-layer structure of three or more layers.

An insulator 241a is provided in contact with an inner wall of the opening portion formed in the insulator 285, the insulator 283, the insulator 282, the insulator 280, the insulator 275, and the insulator 271a and the side surface of the conductor 240a. An insulator 241b is provided in contact with an inner wall of the opening portion formed in the insulator 285, the insulator 283, the insulator 282, the insulator 280, the insulator 275, and the insulator 271b and the side surface of the conductor 240b. Note that each of the insulator 241a and the insulator 241b has a structure in which a first insulator is provided in contact with the inner wall of the opening portion and a second insulator is provided on the inner side of the first insulator.

As the insulator 241a and the insulator 241b, a barrier insulator against one or both of hydrogen and oxygen is preferably used. For example, the insulator 241a and the insulator 241b are preferably formed using silicon nitride, silicon nitride oxide, aluminum oxide, hafnium oxide, or the like. Other than that, a metal oxide such as magnesium oxide, gallium oxide, germanium oxide, yttrium oxide, zirconium oxide, lanthanum oxide, neodymium oxide, or tantalum oxide can be used, for example. Since the insulator 241a and the insulator 241b are each provided in contact with the insulator 283, the insulator 282, and the insulator 275, impurities such as water and hydrogen contained in the insulator 280 or the like can be inhibited from entering the oxide 230 through the conductor 240a and the conductor 240b. In particular, silicon nitride is suitable because of having a high barrier property against hydrogen.

The insulator 241a is provided between the insulator 280 and the conductor 240a, and the insulator 241b is provided between the insulator 280 and the conductor 240b. The insulator 280 contains excess oxygen and is provided in the vicinity of an oxide semiconductor. The barrier insulator against oxygen used as the insulator 241a and the insulator 241b can inhibit oxygen contained in the insulator 280 from being absorbed by the conductor 240a and the conductor 240b.

When the insulator 241a and the insulator 241b each have a stacked-layer structure as illustrated in FIG. 20B, the first insulator in contact with the inner wall of the opening portion formed in the insulator 280 and the like and the second insulator on the inner side of the first insulator are preferably formed using a combination of a barrier insulator against oxygen and a barrier insulator against hydrogen.

For example, aluminum oxide deposited by an ALD method is used for the first insulator and silicon nitride deposited by a PEALD method is used for the second insulator. With such a structure, oxidation of the conductor 240a and the conductor 240b can be inhibited, and hydrogen can be inhibited from entering the conductor 240a and the conductor 240b.

### <Capacitor 100>

The capacitor 100 is provided above the transistor 200. The capacitor 100 includes the conductor 110 functioning as a first electrode (also referred to as a lower electrode), a conductor 120 functioning as a second electrode (also referred to as an upper electrode), and an insulator 132 functioning as a dielectric. The first electrode and the second electrode constitute a pair of electrodes of the capacitor 100.

As the conductor 110, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

The conductor 120 is formed using a conductive material that can be used for the conductor 110.

For example, the conductor 112 provided over the conductor 240a and the conductor 110 provided over the conductor 240b can be formed at the same time. In that case, the conductor 112 and the conductor 110 contain the same conductive material. Note that the conductor 112 functions as a plug or a wiring that is electrically connected to the capacitor 100 or the transistor 200.

Although FIG. 20B illustrates the conductor 112 and the conductor 110 as each having a single-layer structure, the present invention is not limited thereto. For example, the conductor 112 and the conductor 110 may each have a stacked-layer structure of two or more layers. For example, between a conductor having a barrier property and a conductor having high conductivity, a conductor that is highly adhesive to the conductor having a barrier property and the conductor having high conductivity may be formed.

The insulator 132 can be provided as stacked layers or a single layer using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like. As the insulator 132, an insulator in which zirconium oxide, aluminum oxide, and zirconium oxide are stacked in this order can be used, for example.

For example, the insulator 132 preferably has a stacked-layer structure of an insulator containing a material with high dielectric strength (a low-dielectric-constant material) and an insulator containing a high-dielectric-constant (high-k) material. In the capacitor 100 having such a structure, a sufficient capacitance can be provided owing to the insulator containing the high-k material, and the dielectric strength can be increased owing to the insulator containing the material with high dielectric strength, so that the electrostatic breakdown of the capacitor 100 can be inhibited.

An insulator 150 is provided over the conductor 120 and the insulator 132. The insulator 150 functions as an interlayer film.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a low-dielectric-constant material is used for the insulator functioning as the interlayer film, parasitic capacitance generated between wirings can be reduced. Thus, a material is preferably selected depending on the function of the insulator.

For example, the insulator 150 preferably contains the low-dielectric-constant material. Alternatively, the insulator 150 preferably has a stacked-layer structure of an insulator containing the above inorganic insulating material and an insulator containing the above resin. When silicon oxide and silicon oxynitride, which are thermally stable, are combined with a resin, the stacked-layer structure can have thermal stability and a low dielectric constant.

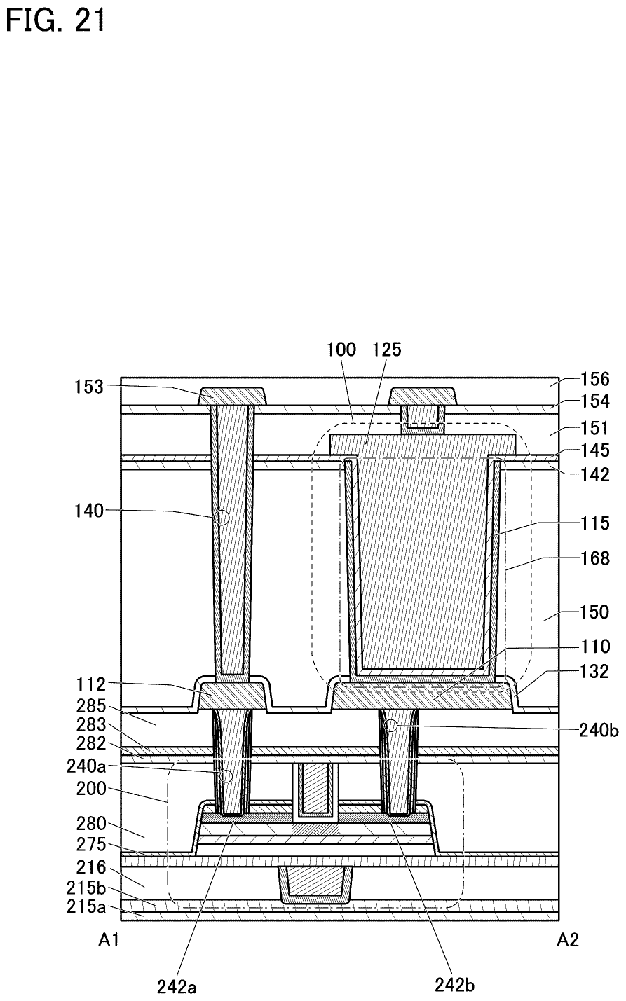

Although the capacitor 100 of the semiconductor device illustrated in FIG. 20A and FIG. 20B has a planar shape, the present invention is not limited thereto. For example, the capacitor 100 may have a cylindrical shape as illustrated in FIG. 21. Note that the structure below and including the insulator 150 of a semiconductor device illustrated in FIG. 21 is similar to that of the semiconductor device illustrated in FIG. 20A and FIG. 20B.

In the semiconductor device illustrated in FIG. 21, the insulator 150 is provided over the insulator 132, and an insulator 142 is provided over the insulator 150. Note that an opening 168 reaching the conductor 110 is formed in the insulator 132, the insulator 150, and the insulator 142.

The capacitor 100 illustrated in FIG. 21 includes a conductor 115, an insulator 145 over the conductor 115 and the insulator 142, and a conductor 125 over the insulator 145. Here, at least parts of the conductor 115, the insulator 145, and the conductor 125 are positioned in the opening 168.

An insulator 151 is provided over the conductor 125 and the insulator 145, an insulator 154 is provided over the insulator 151, and a conductor 153 and an insulator 156 are provided over the insulator 154. A conductor 140 is provided in an opening formed in the insulator 132, the insulator 150, the insulator 142, the insulator 145, the insulator 151, and the insulator 154.

The conductor 115 functions as the first electrode of the capacitor 100, the conductor 125 functions as the second electrode of the capacitor 100, and the insulator 145 functions as the dielectric of the capacitor 100. The capacitor 100 has a structure in which the first electrode and the second electrode face each other with the dielectric therebetween on a side surface as well as a bottom surface in the opening 168; thus, the capacitance per unit area can be increased. Thus, the deeper the opening 168 is, the larger the capacitance of the capacitor 100 can be. Increasing the capacitance per unit area of the capacitor 100 in this manner can promote miniaturization or higher integration of the semiconductor device.

As the insulator 151, an insulator that can be used as the insulator 150 is used. As the insulator 142, an insulator that can be used as the insulator 282 is used.

The shape of the opening 168 when seen from above may be a tetragonal shape, a polygonal shape other than a tetragonal shape, a polygonal shape with rounded corners, or a circular shape including an elliptical shape. Here, the area where the opening 168 and the transistor 200 overlap with each other is preferably large in the top view. Such a structure can reduce the area occupied by the semiconductor device including the capacitor 100 and the transistor 200.

The conductor 115 is provided in contact with the side surfaces of the insulator 150 and the insulator 142 in the opening 168. The top surface of the conductor 115 is preferably level with the top surface of the insulator 142. Furthermore, the bottom surface of the conductor 115 is in contact with the conductor 110 through the opening 168. The conductor 115 is preferably deposited by an ALD method, a CVD method, or the like; for example, a conductor that can be used as the conductor 205 is used.

The insulator 145 is placed to cover the conductor 115 and the insulator 142. The insulator 145 is preferably deposited by an ALD method, a CVD method, or the like. As the insulator 145, an insulator that can be used as the insulator 132 can be used.

The conductor 125 is provided to fill the opening 168. The conductor 125 is preferably deposited by an ALD method, a CVD method, or the like; for example, a conductor that can be used as the conductor 205 is used.

The conductor 153 is provided over the insulator 154 and is covered with the insulator 156. As the conductor 153, a conductor that can be used as the conductor 112 is used. As the insulator 156, an insulator that can be used as the insulator 150 is used. Here, the conductor 153 is in contact with the top surface of the conductor 140 and functions as a terminal of the capacitor 100 or the transistor 200.

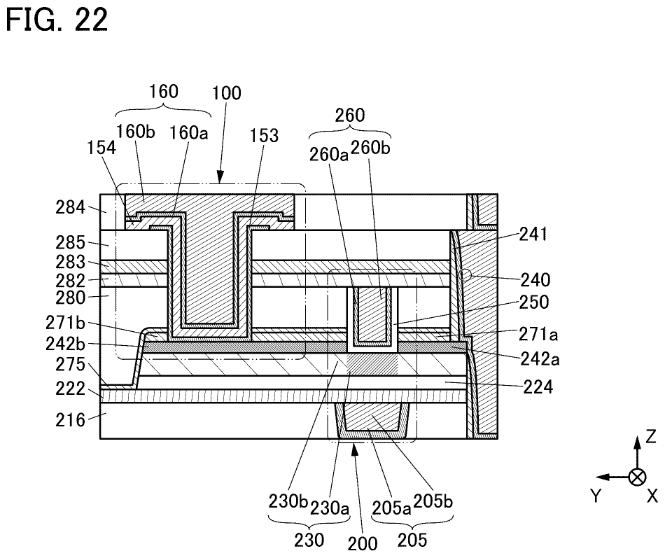

Although FIG. 21 illustrates a structure in which the lower electrode of the capacitor 100 having a cylindrical shape is electrically connected to the other of the source electrode and the drain electrode of the transistor 200 through the conductor 240b, the present invention is not limited thereto. For example, as illustrated in FIG. 22, the lower electrode of the capacitor having a cylindrical shape may be in contact with the other of the source electrode and the drain electrode of the transistor 200.

FIG. 22 illustrates a semiconductor device including the transistor 200 and the capacitor 100 having a cylindrical shape. Note that in FIG. 22, the X direction is parallel to the channel length direction of the transistor illustrated in the drawing, the Y direction is perpendicular to the X direction, and the Z direction is perpendicular to the X direction and the Y direction. Differences from the semiconductor device illustrated in FIG. 21 are mainly described below, and common portions are not described.

An insulator 284 is provided over the insulator 285. As the insulator 284, an insulator that can be used as the insulator 216 is used.

The capacitor 100 includes the conductor 153 over the conductor 242b, the insulator 154 over the conductor 153, and a conductor 160 (a conductor 160a and a conductor 160b) over the insulator 154.

At least parts of the conductor 153, the insulator 154, and the conductor 160 are positioned in an opening formed in the insulator 271b, the insulator 275, the insulator 280, the insulator 282, the insulator 283, and the insulator 285. End portions of the conductor 153, the insulator 154, and the conductor 160 are positioned at least over the insulator 282, and preferably positioned over the insulator 285. The insulator 154 is provided to cover the end portion of the conductor 153. This enables the conductor 153 and the conductor 160 to be electrically insulated from each other.

The conductor 153 includes a region functioning as the first electrode (the lower electrode) of the capacitor 100. The insulator 154 includes a region functioning as the dielectric of the capacitor 100. The conductor 160 includes a region functioning as the second electrode (the upper electrode) of the capacitor 100. The capacitor 100 forms a MIM (Metal-Insulator-Metal) capacitor.

The conductor 242b provided over the oxide 230 to overlap with the oxide 230 functions as a wiring electrically connected to the conductor 153 of the capacitor 100.

Each of the conductor 153 and the conductor 160 included in the capacitor 100 can be formed using a conductor that can be used as the conductor 205, the conductor 242a, the conductor 242b, or the conductor 260. The conductor 153 and the conductor 160 are each preferably deposited by a deposition method that offers excellent coverage, such as an ALD method or a CVD method. For example, titanium nitride or tantalum nitride deposited by an ALD method or a CVD method can be used for the conductor 153.

The top surface of the conductor 242b is in contact with the bottom surface of the conductor 153. Here, the use of a conductive material with favorable conductivity for the conductor 242b can reduce the contact resistance between the conductor 153 and the conductor 242b.

Titanium nitride deposited by an ALD method or a CVD method can be used for the conductor 160a, and tungsten deposited by a CVD method can be used for the conductor 160b. Note that in the case where the adhesion of tungsten to the insulator 154 is sufficiently high, a single-layer structure of tungsten deposited by a CVD method may be used for the conductor 160.

The insulator 154 included in the capacitor 100 is preferably formed using a high-dielectric-constant (high-k) material. The insulator 154 is preferably deposited by a deposition method that offers excellent coverage, such as an ALD method or a CVD method.

The insulator 154 preferably has a stacked-layer structure of a high-dielectric-constant (high-k) material and a material with high dielectric strength. As the insulator 154, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. As another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 100.

Alternatively, a material that can have ferroelectricity as described later may be used for the insulator 154.

The deeper the opening portion formed in the insulator 271b, the insulator 275, the insulator 280, the insulator 282, the insulator 283, and the insulator 285 is (i.e., the larger the thickness of one or more of the insulator 271b, the insulator 275, the insulator 280, the insulator 282, the insulator 283, and the insulator 285 is), the larger the capacitance of the capacitor 100 can be. Increasing the capacitance per unit area of the capacitor 100 can achieve miniaturization or higher integration of the semiconductor device.

Here, since the insulator 271b, the insulator 275, the insulator 282, and the insulator 283 function as barrier insulators, their thicknesses are preferably set in accordance with a barrier property required for the semiconductor device. The thickness of the conductor 260 functioning as a gate electrode depends on the thickness of the insulator 280; thus, the thickness of the insulator 280 is preferably set in accordance with the thickness of the conductor 260 required for the semiconductor device.

Accordingly, the capacitance of the capacitor 100 is preferably set by adjusting the thickness of the insulator 285. For example, the thickness of the insulator 285 is set within the range from 50 nm to 250 nm inclusive, and the depth of the opening portion is approximately greater than or equal to 150 nm and less than or equal to 350 nm. When the capacitor 100 is formed within the above range, the capacitor 100 can have adequate capacitance, and the height of one layer can be prevented from being excessively large in a semiconductor device in which a plurality of layers each including the capacitor 100 are stacked. Note that the capacitance of the capacitor may differ between the plurality of layers. In this structure, the thickness of the insulator 285 may differ between the layers, for example.

Note that the sidewall of the opening portion in which the capacitor 100 is positioned and which is provided in the insulator 285 and the like may be substantially perpendicular to the top surface of the insulator 222 or may be tapered. The tapered shape of the sidewall can improve the coverage with the conductor 153 and the like provided in the opening portion, so that defects such as voids can be reduced.

The conductor 240 is provided in an opening portion formed in the insulator 216, the insulator 222, the insulator 275, the insulator 280, the insulator 282, the insulator 283, the insulator 285, and the insulator 284. The conductor 240 is provided in contact with one of the source electrode and the drain electrode (the conductor 242a) of the transistor 200. The conductor 240 is provided to extend in the Z direction.

The conductor 242a provided over the oxide 230 includes a region functioning as a wiring electrically connected to the conductor 240. In FIG. 22, for example, the top surface and a side end portion of the conductor 242a are electrically connected to the conductor 240 extending in the Z direction. When the conductor 240 is in direct contact with at least one of the top surface and the side end portion of the conductor 242a, an electrode for connection does not need to be provided additionally, so that the area occupied by the semiconductor device can be reduced. Note that the conductor 240 is preferably in contact with the side end portion and part of the top surface of the conductor 242a. When the conductor 240 is in contact with a plurality of surfaces of the conductor 242a, the contact resistance between the conductor 240 and the conductor 242a can be reduced.

The conductor 240 preferably has a stacked-layer structure of a first conductor and a second conductor. For example, as illustrated in FIG. 22, a structure can be employed in which the first conductor of the conductor 240 is provided in contact with an inner wall of the opening portion and the second conductor is provided on the inner side. That is, the first conductor is positioned closer to the insulator 216, the insulator 222, the insulator 275, the insulator 280, the insulator 282, the insulator 283, the insulator 285, and the insulator 284 than the second conductor is. The first conductor is in contact with the top surface and the side end portion of the conductor 242a.

The first conductor of the conductor 240 is formed using any of the above-described conductive materials that can be used for the first conductor of the conductor 240a or the conductor 240b, and the second conductor of the conductor 240 is formed using any of the above-described conductive materials that can be used for the second conductor of the conductor 240a or the conductor 240b.

For example, it is preferable to use titanium nitride for the first conductor of the conductor 240 and tungsten for the second conductor of the conductor 240. In that case, the first conductor of the conductor 240 contains titanium and nitrogen, and the second conductor of the conductor 240 contains tungsten.

Note that the conductor 240 may have a single-layer structure or a stacked-layer structure of three or more layers.

As illustrated in FIG. 22, an insulator 241 is preferably provided in contact with a side surface of the conductor 240. Specifically, the insulator 241 is provided in contact with the inner wall of an opening portion provided in the insulator 216, the insulator 222, the insulator 275, the insulator 280, the insulator 282, the insulator 283, the insulator 285, and the insulator 284. The insulator 241 is formed also on side surfaces of the insulator 224, the oxide 230, and the conductor 242a that are formed to protrude in the opening portion. Here, at least part of the conductor 242a is exposed from the insulator 241 and is in contact with the conductor 240. That is, the conductor 240 is provided to fill the opening with the insulator 241 therebetween.

As illustrated in FIG. 22, the uppermost portion of the insulator 241 formed below the conductor 242a is preferably positioned below the top surface of the conductor 242a. With such a structure, the conductor 240 can be in contact with at least part of the side end portion of the conductor 242a. Note that the insulator 241 formed under the conductor 242a preferably includes a region in contact with a side surface of the oxide 230. With such a structure, impurities such as water and hydrogen contained in the insulator 280 and the like can be inhibited from entering the oxide 230 through the conductor 240.

As the insulator 241, any of the above-described barrier insulators that can be used as the insulator 241a and the insulator 241b is used.

Although FIG. 22 illustrates the structure in which the insulator 241 is a single layer, the present invention is not limited thereto. The insulator 241 may have a stacked-layer structure of two or more layers.

In the case where the insulator 241 has a stacked-layer structure of two layers, a barrier insulating film against oxygen is used for a first layer in contact with the inner wall of the opening in the insulator 280 and the like, and a barrier insulating film against hydrogen is used for a second layer positioned inward from the first layer. For example, aluminum oxide deposited by an ALD method is used for the first layer, and silicon nitride deposited by a PEALD method is used for the second layer. With this structure, oxidation of the conductor 240 can be inhibited, and hydrogen can be inhibited from entering the oxide 230 and the like from the conductor 240. Thus, the electrical characteristics and reliability of the transistor 200 can be improved.

Note that the sidewall of the opening portion in which the conductor 240 and the insulator 241 are positioned may be substantially perpendicular to the top surface of the insulator 222 or may be tapered. The tapered shape of the sidewall can improve the coverage with the insulator 241 and the like provided in the opening portion.

The semiconductor device which includes the transistor 200 and the capacitor 100 and in which one of the source and the drain of the transistor 200 is electrically connected to one of the pair of electrodes of the capacitor 100 can function as a memory cell of a storage device, for example.

### <Structure Example of Semiconductor Device Including Transistor 200 and Capacitor 100A>

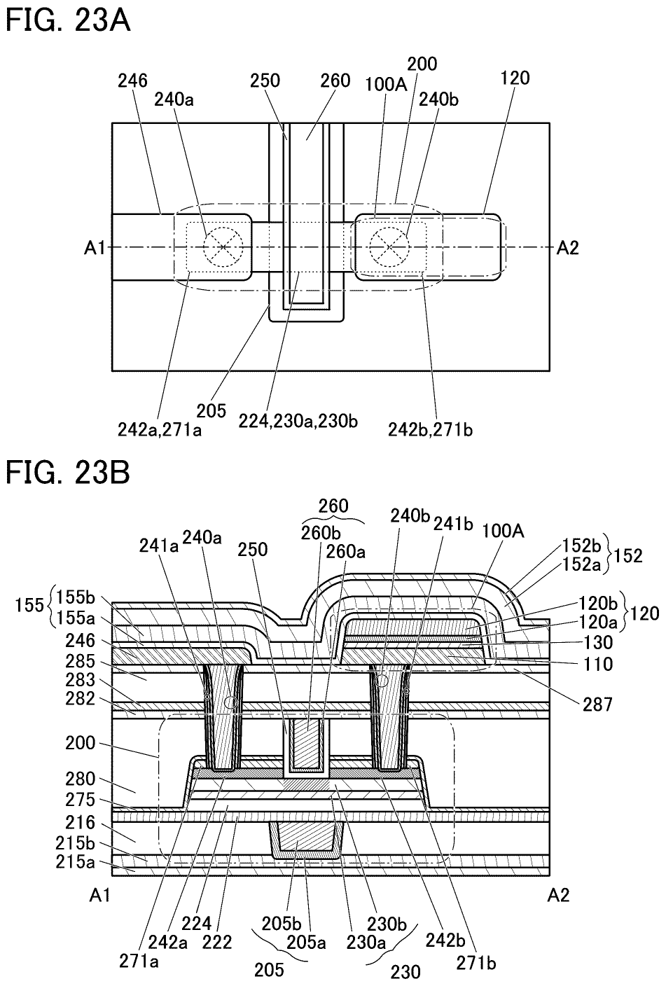

FIG. 23A and FIG. 23B illustrate a semiconductor device including the above transistor 200 and a capacitor 100A. FIG. 23A is a top view of the semiconductor device. FIG. 23B is a cross-sectional view of a portion indicated by the dashed-dotted line A1-A2 in FIG. 23A and is also a cross-sectional view of the transistor 200 in the channel length direction. Note that some components are omitted in the top view in FIG. 23A for clarity of the drawing.

In the semiconductor device illustrated in FIG. 23A and FIG. 23B, the capacitor 100A and a conductor 246 are provided over the transistor 200. The conductor 246 functions as a wiring. Here, the area where the capacitor 100A and the transistor 200 overlap with each other is preferably large in the top view. Such a structure can reduce the area occupied by the semiconductor device including the capacitor 100A and the transistor 200. In that case, miniaturization and high integration of the semiconductor device can be achieved.

Note that the structure below and including the insulator 285 of the semiconductor device illustrated in FIG. 23A and FIG. 23B is similar to that of the semiconductor device illustrated in FIG. 20A and FIG. 20B. Differences from the semiconductor device illustrated in FIG. 20A and FIG. 20B are mainly described below, and common portions are not described.

The semiconductor device illustrated in FIG. 23A and FIG. 23B includes an insulator 287 over the insulator 285.

The conductor 240a is provided in an opening formed in the insulator 287, the insulator 285, the insulator 283, the insulator 282, the insulator 280, the insulator 275, and the insulator 271a, and the conductor 240b is provided in an opening formed in the insulator 287, the insulator 285, the insulator 283, the insulator 282, the insulator 280, the insulator 275, and the insulator 271b. As illustrated in FIG. 23B, the conductor 240a includes a region in contact with the conductor 242a and a region in contact with at least part of the bottom surface of the conductor 246. The conductor 240b includes a region in contact with the conductor 242b and a region in contact with at least part of the bottom surface of the conductor 110 included in the capacitor 100A.

The conductor 246 may be placed in contact with the top surface of the conductor 240a. The conductor 246 is preferably formed using a conductive material containing tungsten, copper, or aluminum as its main component. The conductor 246 may have a stacked-layer structure; for example, stacked layers of titanium or titanium nitride and the above-described conductive material may be employed. The conductor 246 is preferably formed using the same material in the same layer as that for/in the conductor 110.

### <Capacitor 100A>

The capacitor 100A includes the conductor 110, the conductor 120, and an insulator 130 interposed between the conductor 110 and the conductor 120. For example, the conductor 110 is placed over the insulator 287 and the conductor 240b, the insulator 130 is placed over the conductor 110, and the conductor 120 is placed over the insulator 130. Here, the conductor 110 functions as the first electrode of the capacitor 100A, the conductor 120 functions as the second electrode of the capacitor 100A, and the insulator 130 functions as the dielectric of the capacitor 100A. Note that the capacitor 100A is a capacitor in which a material that can have ferroelectricity is used as a dielectric, which will be described in detail later.

As the conductor 110, a conductor that can be used as the conductor 110 of the capacitor 100 is used. As the conductor 120, an insulator that can be used as the conductor 120 of the capacitor 100 is used.

The conductor 110 may have a single-layer structure or a stacked-layer structure. As the conductor 110, any of the above-described conductors that can be used as the conductor 110 of the capacitor 100 is used.

In FIG. 23B, the conductor 120 has a stacked-layer structure of a conductor 120a and a conductor 120b provided over and in contact with the conductor 120a.

As the conductor 120a, any of the above-described conductors that can be used as the conductor 120 is deposited by a sputtering method, an ALD method, a CVD method, or the like. For example, titanium nitride is deposited for the conductor 120a by a sputtering method.

Alternatively, titanium nitride may be deposited for the conductor 120a by a thermal ALD method. Here, the conductor 120a is preferably deposited by a method in which deposition is performed while the substrate is heated, such as a thermal ALD method. For example, deposition is performed at a substrate temperature of higher than or equal to room temperature, preferably higher than or equal to 300° C., further preferably higher than or equal to 325° C., still further preferably higher than or equal to 350° C. Furthermore, for example, deposition is performed at a substrate temperature of lower than or equal to 500° C., preferably lower than or equal to 450° C. For example, the substrate temperature is approximately 400° C.

When the conductor 120a is deposited within the above temperature range, the insulator 130 can have ferroelectricity even without a baking treatment at a high temperature (e.g., baking treatment at a heat treatment temperature of higher than or equal to 400° C. or higher than or equal to 500° C.) after the formation of the conductor 120a. When the conductor 120a is deposited by an ALD method, which causes relatively little damage to a base, as described above, the crystal structure of the insulator 130 can be inhibited from being broken excessively, which enhances the ferroelectricity of the insulator 130. Note that increasing the crystallinity or ferroelectricity of the insulator 130 by utilizing the temperature during the deposition of the conductor 120 without performing annealing after the deposition of the conductor 120a is referred to as self-annealing in some cases.

As the conductor 120b, any of the above-described conductors that can be used for the conductor 120 is deposited by a sputtering method, an ALD method, a CVD method, or the like. For example, tungsten is deposited by a sputtering method.

Without being limited to the above, the conductor 120 may have a single-layer structure or a structure of three or more layers.

The insulator 130 is preferably formed using a material that can have ferroelectricity. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can have ferroelectricity also include a material in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide. The atomic ratio of zirconium to the element J2 can be set as appropriate; the atomic ratio of zirconium to the element J2 is, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include metal nitrides such as scandium aluminum nitride (Al₁₋ₐScₐN_{b} (a is a real number greater than 0 and less than 0.5, and b is 1 or an approximate value thereof)), an Al—Ga—Sc nitride, and a Ga—Sc nitride. Examples of the material that can have ferroelectricity also include a metal nitride containing an element M1, an element M2, and nitrogen. Here, the element M1 is one or more selected from aluminum (Al), gallium (Ga), indium (In), and the like. The element M2 is one or more selected from boron (B), scandium (Sc), yttrium (Y), lanthanum (La), cerium (Ce), neodymium (Nd), europium (Eu), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium (Mg), calcium (Ca), strontium (Sr), zinc (Zn), cadmium (Cd), and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a x-alumina-type structure, and the like.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the deposition conditions; thus, a material that exhibits ferroelectricity is referred to not only as a ferroelectric but also as a material that can have ferroelectricity in this specification and the like.

Among the materials that can have ferroelectricity, a material containing hafnium oxide or hafnium oxide and zirconium oxide is preferable because the material can have ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm. For example, the thickness is preferably greater than or equal to 5 nm and less than or equal to 15 nm, further preferably greater than or equal to 8 nm and less than or equal to 12 nm. When a ferroelectric layer that can be thin is used, the capacitor 100A can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

The material containing hafnium oxide or hafnium oxide and zirconium oxide is preferable because it can have ferroelectricity even with a minute area. For example, a ferroelectric layer can have ferroelectricity even with an area (occupying area) less than or equal to 10000 μm², less than or equal to 1000 μm², less than or equal to 100 μm², less than or equal to 10 μm², less than or equal to 1 μm², or less than or equal to 0.1 μm² in a top view. With a small-area ferroelectric layer, the area occupied by the capacitor 100A can be reduced.

The material that can have ferroelectricity is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile storage element can be formed. A nonvolatile storage element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, the capacitor 100A described in this embodiment is a ferroelectric capacitor, and the semiconductor device including the capacitor 100A and the above transistor 200 can function as a ferroelectric memory.

Note that ferroelectricity is exhibited by displacement of oxygen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable that the insulator 130 include a crystal having an orthorhombic crystal structure to exhibit ferroelectricity. Note that a crystal included in the insulator 130 may have one or more selected from tetragonal, orthorhombic, and monoclinic crystal structures. Alternatively, the insulator 130 may have an amorphous structure. In that case, the insulator 130 may have a composite structure including an amorphous structure and a crystal structure.

In order to form the insulator 130 including a crystal, an impurity such as hydrogen or chlorine in the insulator 130 is preferably reduced. Here, the impurity does not indicate only atoms of a single element. It is preferable that a substance bonded with the above impurity be reduced in the insulator 130. For example, it is also preferable to reduce a substance bonded with hydrogen (e.g., OH⁻) or the like in the insulator 130. Such impurities form oxygen vacancies in crystals in the insulator 130 in some cases. Furthermore, an impurity such as hydrogen is bonded to the oxygen vacancy part to reduce crystallinity of the insulator 130 in some cases. Accordingly, when the impurities are contained in the insulator 130, crystallization of the insulator 130 is inhibited in some cases. Thus, in order to improve the ferroelectricity of the insulator 130, an impurity such as hydrogen or chlorine is preferably reduced.

Thus, as illustrated in FIG. 23B, it is preferable that an insulator 152 be provided to cover the capacitor 100A and an insulator 155 be provided between the insulator 152 and the insulator 130. In that case, the insulator 155 in a region not overlapping with the conductor 110 is preferably in contact with the insulator 287.

The insulator 152 and the insulator 155 each function as a barrier insulator against hydrogen. The insulator 152 has a function of inhibiting diffusion of at least one of hydrogen and a substance bonded with hydrogen (for example, OH⁻). Thus, the insulator 152 preferably has higher capability of inhibiting diffusion of at least one of hydrogen and a substance bonded with hydrogen (for example, OH⁻) than the insulator 130. The insulator 155 has a function of capturing or fixing at least one of hydrogen and a substance bonded with hydrogen. Thus, the insulator 155 preferably has higher capability of capturing or fixing at least one of hydrogen and a substance bonded with hydrogen than the insulator 130.

Each of the insulator 152 and the insulator 155 can be formed using aluminum oxide, magnesium oxide, hafnium oxide, gallium oxide, indium gallium zinc oxide, silicon nitride, or silicon nitride oxide, for example. The insulator 152 having high capability of inhibiting diffusion of impurities such as hydrogen is preferably formed using silicon nitride, for example. In that case, the insulator 152 contains at least nitrogen and silicon.

The insulator 155 having high capability of capturing or fixing impurities such as hydrogen is preferably formed using an oxide having an amorphous structure. For example, a metal oxide such as aluminum oxide or magnesium oxide is preferably used. In the case where aluminum oxide is used for the insulator 155, the insulator 155 contains at least oxygen and aluminum. As described above, a metal oxide having an amorphous structure sometimes has a property of capturing or fixing hydrogen. When such a metal oxide having an amorphous structure is used as a component of the capacitor 100A or provided around the capacitor 100A, hydrogen contained in the capacitor 100A or hydrogen existing around the capacitor 100A can be captured or fixed. It is particularly preferable to capture or fix hydrogen contained in the insulator 130.

Note that the insulator 155 preferably has an amorphous structure, but a crystal region may be partly formed. Alternatively, the insulator 155 may have a multilayer structure in which a layer with an amorphous structure and a layer including a crystal region are stacked. For example, the insulator 155 can have a stacked-layer structure where a layer with a crystal region, typically, a layer with a polycrystalline structure, is formed over a layer with an amorphous structure.

With the insulator 152, diffusion of impurities such as hydrogen into the insulator 130 from outside the insulator 152 can be inhibited. Furthermore, with the insulator 155, impurities such as hydrogen existing in a region surrounded by the insulator 152 can be captured or fixed, whereby the concentration of impurities such as hydrogen contained in the insulator 130 can be reduced. When the insulator 130 does not contain impurities such as hydrogen or the amount of impurities such as hydrogen contained in the insulator 130 is made extremely small as described above, the insulator 130 can have higher crystallinity and thus can have a structure with higher ferroelectricity.

In FIG. 23B, the insulator 155 has a stacked-layer structure of an insulator 155a and an insulator 155b provided over and in contact with the insulator 155a. The insulator 152 has a stacked-layer structure of an insulator 152a and an insulator 152b provided over and in contact with the insulator 152a. Without being limited to the above, one or both of the insulator 155 and the insulator 152 may have a single-layer structure or a structure of three or more layers.

As the insulator 155a, any of the above-described insulators that can be used as the insulator 155 is preferably deposited by an ALD method, particularly a thermal ALD method. For example, aluminum oxide deposited by an ALD method can be used for the insulator 155a. The insulator 155a can thus be deposited to have excellent coverage; hence, even when a pinhole, step disconnection, or the like is formed in the insulator 155b deposited by a sputtering method, diffusion of impurities from the outside of the insulator 155b into the insulator 130 through the pinhole, the step disconnection, or the like can be inhibited.

As the insulator 155b, an insulator that can be used as the insulator 155 described above is deposited by a sputtering method. For example, aluminum oxide deposited by a sputtering method can be used for the insulator 155b. Since a sputtering method does not need to use a molecule containing hydrogen as a deposition gas, the hydrogen concentration in the insulator 155b can be reduced. Accordingly, a larger amount of impurities such as hydrogen contained in the insulator 130 can be captured or fixed.

As the insulator 152a, any of the above-described insulators that can be used as the insulator 152 is deposited by a sputtering method. For example, silicon nitride deposited by a sputtering method can be used for the insulator 152a. Since a sputtering method does not need to use a molecule containing hydrogen as a deposition gas, the hydrogen concentration in the insulator 152a can be reduced.

As the insulator 152b, any of the above-described insulators that can be used as the insulator 152 is preferably deposited by an ALD method, particularly a PEALD method. For example, silicon nitride deposited by a PEALD method can be used for the insulator 152b. Thus, even when a pinhole, step disconnection, or the like is formed in the insulator 152a deposited by a sputtering method, a portion overlapping with such a defect can be filled with silicon nitride deposited by an ALD method with excellent coverage. Covering the pinhole, the step disconnection, or the like with the insulator 152b can inhibit diffusion of impurities from the outside of the insulator 152b into the insulator 130.

Moreover, as illustrated in FIG. 23B, the insulator 155 and the insulator 152 are provided to cover not only the capacitor 100A but also the conductor 246. Accordingly, in the heat treatment, impurities such as hydrogen can be inhibited from diffusing into the oxide 230 through the capacitor 100A, the conductor 246, and the conductor 240. The highly purified intrinsic capacitor with ferroelectricity in which the amount of impurities such as hydrogen is reduced and a highly purified intrinsic oxide semiconductor in which the amount of impurities such as hydrogen is reduced are highly compatible with each other in the manufacturing process. Thus, a method for fabricating the semiconductor device with high productivity can be provided.

The insulator 287 is preferably formed using an insulator having high capability of inhibiting diffusion of impurities such as hydrogen, like the insulator 152. When a structure is employed in which the insulator 155 and the insulator 287 are in contact with each other in a region not overlapping with the capacitor 100A, the capacitor 100A is sealed by the insulator 287 and each of the insulator 155 and the insulator 152. Accordingly, diffusion of hydrogen into the capacitor 100A from the outside of the insulator 152 and the insulator 287 can be inhibited, and hydrogen in the region surrounded by the insulator 152 and the insulator 287 can be captured or fixed, so that the hydrogen concentration in the insulator 130 of the capacitor 100A can be reduced. As a result, the ferroelectricity of the insulator 130 can be enhanced.

Although FIG. 23B illustrates a structure in which the insulator 287 in a region not overlapping with the conductor 110 is in contact with the insulator 155, the present invention is not limited thereto. A structure may be employed in which the insulator 287 is omitted and the top surface of the insulator 285 is in contact with the bottom surface of the conductor 246, the bottom surface of the insulator 155a, and the bottom surface of the conductor 110.

Furthermore, a layer increasing the crystallinity of the insulator 130 may be provided between the insulator 130 and the conductor 110 and/or between the insulator 130 and the conductor 120. As the layer increasing the crystallinity, a layer containing at least one of the elements contained in the insulator 130 is preferably used, for example. Note that the composition of the layer increasing the crystallinity and the composition of the insulator 130 are preferably different from each other. When HfZrO_{X} is used for the insulator 130, specifically, it is preferable to use a metal oxide such as hafnium oxide or zirconium oxide or a metal such as hafnium or zirconium for the layer increasing the crystallinity.

Note that the composition of the layer increasing the crystallinity does not necessarily include an element contained in the insulator 130. In that case, silicon, yttrium, aluminum, scandium, or the like can be used as the element. With the layer increasing the crystallinity, the crystallinity of the insulator 130 can be improved and the ferroelectricity of the insulator 130 can be enhanced. Since the increase in the crystallinity of the insulator 130 is followed by the enhancement of the ferroelectricity of the insulator 130, the layer increasing the crystallinity can be also referred to as a layer increasing the remanent polarization of the insulator 130.

### <Modification Example of Capacitor 100A>

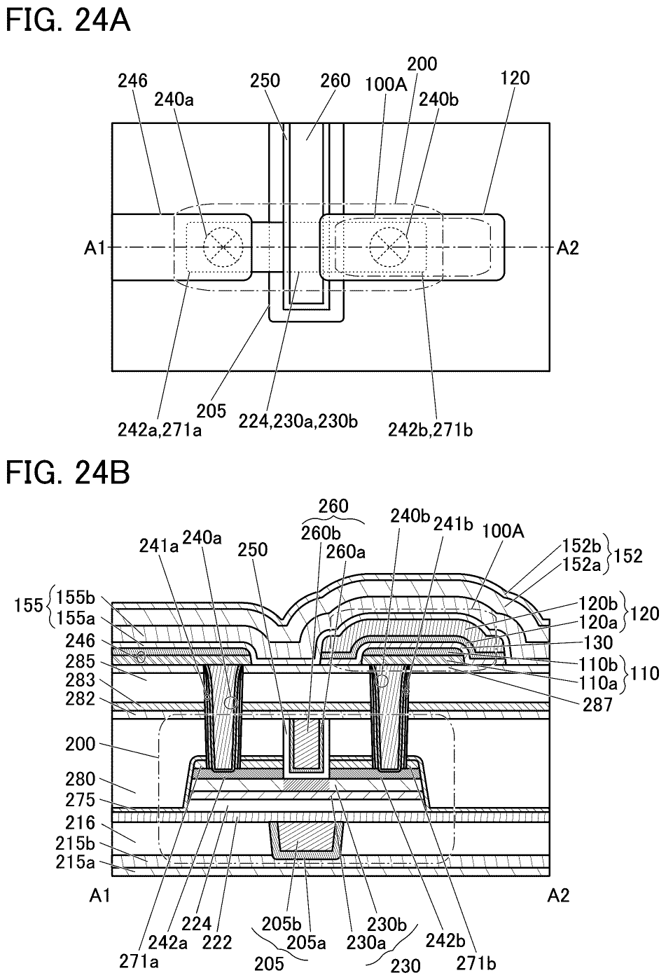

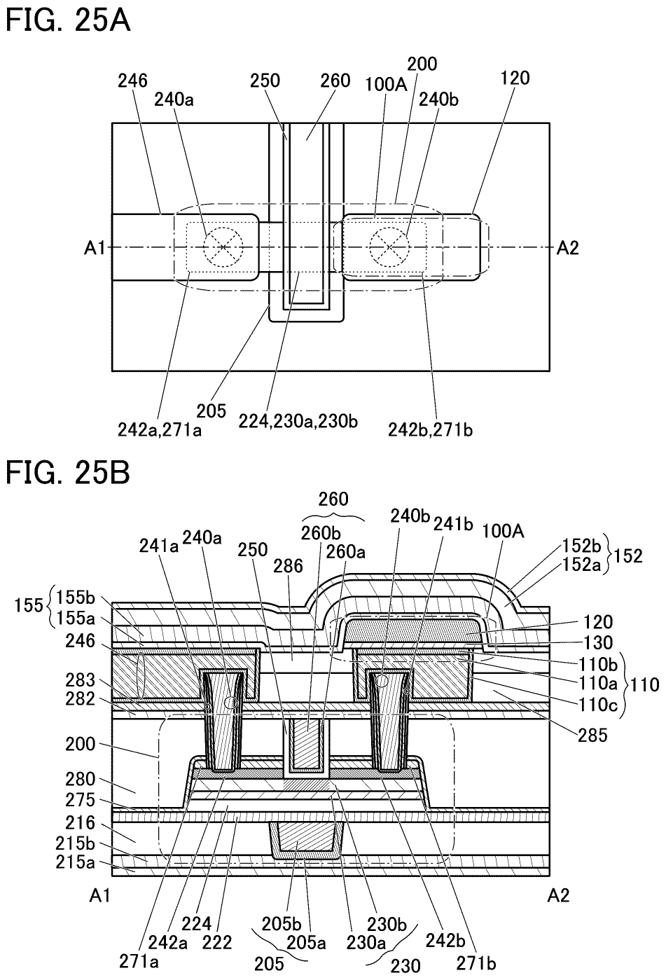

Although the side surface of the conductor 110, the side surface of the insulator 130, and the side surface of the conductor 120 are aligned with each other in the capacitor 100A illustrated in FIG. 23A and FIG. 23B, the present invention is not limited thereto. Modification examples of the capacitor 100A illustrated in FIG. 23A and FIG. 23B will be described below with reference to FIG. 24A to FIG. 25B. Differences from the semiconductor device illustrated in FIG. 23A and FIG. 23B are mainly described below, and common portions are not described.

FIG. 24A is a top view of a semiconductor device. FIG. 24B is a cross-sectional view of a portion indicated by the dashed-dotted line A1-A2 in FIG. 24A and is also a cross-sectional view of the transistor 200 in the channel length direction. Note that some components are omitted in the top view in FIG. 24A for clarity of the drawing.

As illustrated in FIG. 24B, a structure where the side surface of the conductor 110 is located inward from the side surfaces of the insulator 130 and the conductor 120 may be employed. The insulator 130 is formed to cover the top surface and the side surface of the conductor 110, and a region of the insulator 130 not overlapping with the conductor 110 is in contact with the insulator 287. In this case, the periphery of the conductor 110 is located inward from the peripheries of the insulator 130 and the conductor 120 in the top view. In such a structure, the conductor 110 and the conductor 120 can be sufficiently apart from each other with the insulator 130.

Increasing the area of the conductor 120 in a top view enables an adequate design margin to be provided in the case where a conductor (not illustrated) that is connected to the conductor 120 and functions as a plug or a wiring is provided.

Although FIG. 23B illustrates a structure in which the conductor 110 is a single layer, the present invention is not limited to this structure, and the conductor 110 may have a stacked-layer structure of two or more layers. For example, as illustrated in FIG. 24B, the conductor 110 may have a stacked-layer structure of two layers of a conductor 110a and a conductor 110b over the conductor 110a.

As the conductor 110a, any of the above-described conductors that can be used as the conductor 110 is deposited by a sputtering method, an ALD method, a CVD method, or the like. For example, tungsten is deposited by a sputtering method or a CVD method.

As the conductor 110b in contact with at least part of the bottom surface of the insulator 130, any of the above-described conductors that can be used as the conductor 110 is deposited by an ALD method, a CVD method, or the like. For example, titanium nitride is deposited by a thermal ALD method. The top surface of the conductor 110b preferably has high planarity. Making the planarity of the top surface of the conductor 110b high can improve the crystallinity of the insulator 130 and enhance the ferroelectricity of the insulator 130.

FIG. 25A is a top view of a semiconductor device. FIG. 25B is a cross-sectional view of a portion indicated by the dashed-dotted line A1-A2 in FIG. 25A and is also a cross-sectional view of the transistor 200 in the channel length direction. Note that some components are omitted in the top view in FIG. 25A for clarity of the drawing.

As illustrated in FIG. 25A and FIG. 25B, an insulator 286 may be provided instead of the insulator 287 illustrated in FIG. 23B and the conductor 110 may be provided to fill an opening formed in the insulator 286 and the insulator 285.

The insulator 286 is formed using any of the above-described insulating materials that can be used for the insulator 285.

The conductor 110 fills the opening formed in the insulator 286 and the insulator 285. In the opening formed in the insulator 286 and the insulator 285, the conductor 110 includes a region in contact with the conductor 240b. When the conductor 110 fills the opening formed in the insulator 286 and the insulator 285, the conductor 110 and the conductor 120 can be adequately apart from each other. This can reduce the leakage current of the capacitor 100A.

The conductor 110 illustrated in FIG. 25B can be formed by forming an opening in the insulator 286 and the insulator 285, forming a conductive film to be the conductor 110, and performing planarization treatment using a chemical mechanical polishing (CMP) method or the like until the insulator 286 is exposed. That is, the conductor 110 illustrated in FIG. 25B can be formed by a single damascene method. Such a step of forming the conductor 110 doubles as a step of enhancing the planarity of the top surface of the conductor 110. Thus, the insulator 130 is provided over the conductor 110 with high planarity, so that the planarity of the insulator 130 can also be high. Accordingly, the leakage current of the capacitor 100A can be reduced even when the insulator 130 is formed using a thin ferroelectric layer. Such a step of forming the conductor 110 is suitable also in the case where part of the insulator 130 is provided over the insulator 286 because the planarity of the top surface of the insulator 286 is also high.

As illustrated in FIG. 25B, the conductor 110 may have a stacked-layer structure of a conductor 110c, the conductor 110a over the conductor 110c, and the conductor 110b over the conductor 110a. In the opening formed in the insulator 286 and the insulator 285, the conductor 110c is provided in contact with the side surface of the insulator 286, the side surface of the insulator 285, the top surface of the insulator 283, the side surface of the insulator 241b, and the top surface of the conductor 240b. The conductor 110a is provided to fill part of a depressed portion that is defined by the conductor 110c. Here, the level of the top surface of the conductor 110a is lower than the levels of the top surface of the conductor 110c and the top surface of the insulator 286. The conductor 110b is provided in contact with the top surface of the conductor 110a and the side surface of the conductor 110c. Here, the top surface of the conductor 110b is level with the top surface of the conductor 110c and the top surface of the insulator 286. That is, the conductor 110a is surrounded by the conductor 110c and the conductor 110b.

In the case where the conductor 110 has the three-layer structure of the conductor 110c, the conductor 110a, and the conductor 110b, the conductor 110 can be formed by forming an opening in the insulator 286 and the insulator 285, depositing a conductive film to be the conductor 110c and a conductive film to be the conductor 110a, performing CMP treatment so that the insulator 286 is exposed to form the conductor 110c and the conductor 110a, etching back part of the conductor 110a, and embedding the conductor 110b.

As the conductor 110c, any of the above-described conductors that can be used as the conductor 205a is deposited by a sputtering method, an ALD method, a CVD method, or the like. When the conductor 110c is formed using a conductive material having a function of inhibiting diffusion of oxygen, the conductivity of the conductor 110a can be inhibited from being lowered because of oxidation. For example, titanium nitride is deposited for the conductor 110c by a CVD method.

As the conductor 110b, any of the above-described conductors that can be used as the conductor 110 is deposited by an ALD method, a CVD method, or the like. In the case where the conductor 110c is formed through the planarization treatment as described above, the conductor 110c may be formed by a sputtering method, a CVD method, or a PECVD method that provides a high deposition rate. Thus, the semiconductor device can be fabricated with high productivity. For example, titanium nitride is deposited for the conductor 110b by a CVD method.

In FIG. 25B, the side surface of the conductor 110 is positioned inward from the side surface of the insulator 130. In this case, the periphery of the conductor 110 is positioned inward from the peripheries of the insulator 130 and the conductor 120 in the top view. For example, the shortest distance from the side surface of the conductor 110 to the side surface of the insulator 130 is preferably greater than or equal to the thickness of the insulator 130, further preferably greater than or equal to twice the thickness of the insulator 130. In such a structure, the conductor 110 and the conductor 120 can be sufficiently apart from each other with the insulator 130. In that case, as illustrated in FIG. 25B, part of the insulator 286 in a region not overlapping with the conductor 120 is sometimes removed.

Although FIG. 25B illustrates a structure in which the side surface of the conductor 110 is positioned inward from the side surface of the insulator 130, the present invention is not limited thereto. For example, the side surface of the conductor 110 may be positioned outward from the side surface of the insulator 130. With such a structure, the insulator 130 is surrounded by the conductor 110c and each of the insulator 155 and the insulator 152. When the conductor 110c is formed using a conductive material having a function of inhibiting diffusion of hydrogen, diffusion of hydrogen into the insulator 130 from the outside of the insulator 152 and the conductor 110c is inhibited and hydrogen in the insulator 130 is captured or fixed, so that the hydrogen concentration in the insulator 130 can be reduced. As a result, the ferroelectricity of the insulator 130 can be enhanced. Note that the side surface of the conductor 110 may be aligned with the side surface of the insulator 130.

In the opening formed in the insulator 286 and the insulator 285, the conductor 246 includes a region in contact with the conductor 240a. The conductor 246 functions as a wiring or a terminal. The conductor 246 is preferably formed using the same material in the same layer as that for/in the conductor 110. In the case where the conductor 110 has the above-described stacked-layer structure of three layers as illustrated in FIG. 25B, the conductor 246 and the conductor 110 are formed using the same material in the same layer so that the conductor 246 can have the stacked-layer structure of three layers.

FIG. 25B illustrates the conductor 120 as having a single-layer structure. Note that the conductor 120 may have the stacked-layer structure of two layers illustrated in FIG. 23B or a stacked-layer structure of three or more layers. In the case where the conductor 120 has a single-layer structure, any of the above-described conductors that can be used as the conductor 120a or the conductor 120b is used as the conductor 120. The conductor 120 is deposited by any of the above-described methods that can be used for the conductor 120a or the conductor 120b.

This embodiment can be combined with the other embodiments as appropriate. In this specification, in the case where a plurality of structure examples are shown in one embodiment, the structure examples can be combined as appropriate.

### Embodiment 2

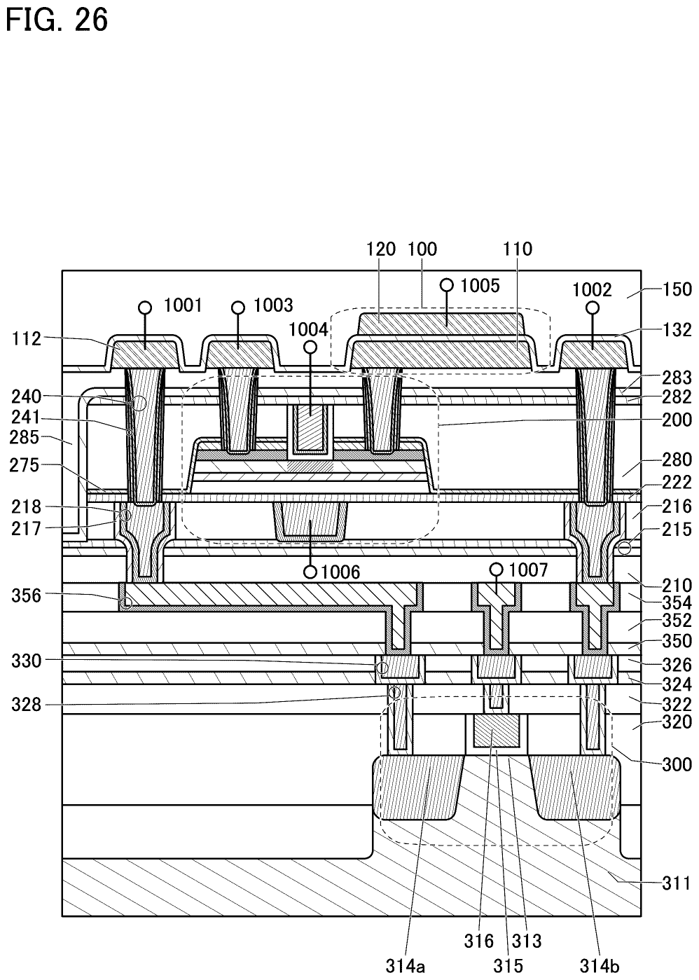

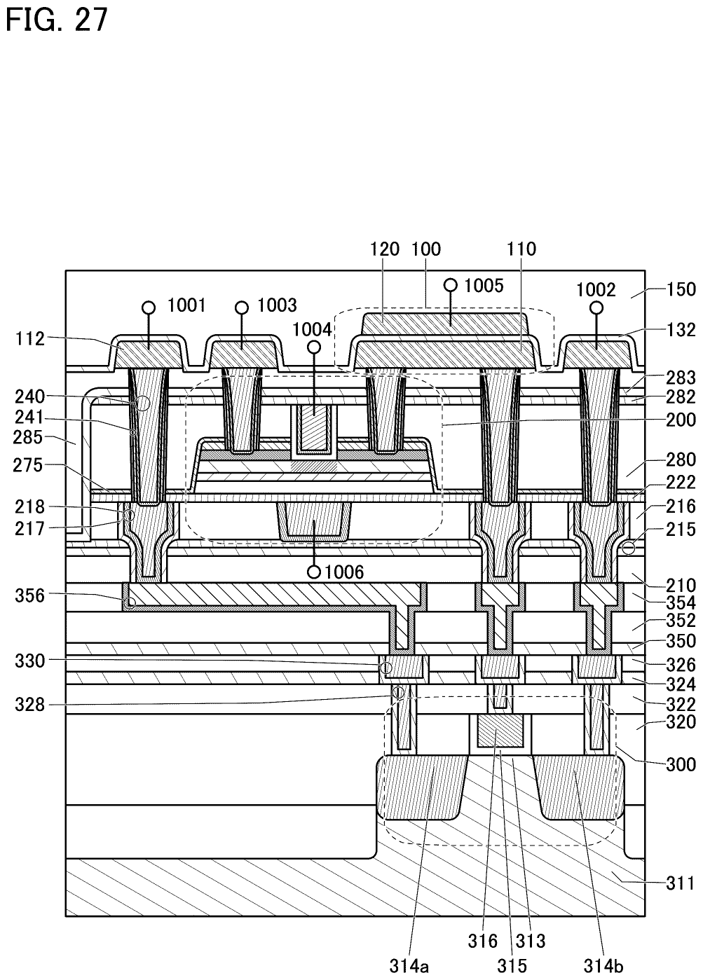

In this embodiment, a storage device which is one embodiment of a semiconductor device will be described with reference to FIG. 26 and FIG. 27.

### [Storage Device 1]

FIG. 26 illustrates an example of a storage device which is one embodiment of the present invention. In the storage device of one embodiment of the present invention, a transistor 200 is provided above a transistor 300, and a capacitor 100 is provided above the transistor 300 and the transistor 200. Note that the transistor 200 described in the above embodiment can be used as the transistor 200.

The transistor 200 is a transistor in which a channel is formed in a semiconductor layer including an oxide semiconductor. Since the transistor 200 has low off-state current, a storage device that uses the transistor can retain stored data for a long time. In other words, such a storage device does not require refresh operation or has extremely low frequency of the refresh operation, which leads to a sufficient reduction in power consumption of the storage device.

In the storage device illustrated in FIG. 26, a wiring 1001 is electrically connected to a source of the transistor 300, a wiring 1002 is electrically connected to a drain of the transistor 300, and a wiring 1007 is electrically connected to a gate of the transistor 300. In addition, a wiring 1003 is electrically connected to one of the source and the drain of the transistor 200, a wiring 1004 is electrically connected to the first gate of the transistor 200, and a wiring 1006 is electrically connected to the second gate of the transistor 200. The other of the source and the drain of the transistor 200 is electrically connected to one electrode of the capacitor 100, and a wiring 1005 is electrically connected to the other electrode of the capacitor 100.

When the storage devices each of which is illustrated in FIG. 26 are arranged in a matrix, a memory cell array can be formed.

The capacitor 100 described in the above embodiment can be used as the capacitor 100. Note that the capacitor 100A described in the above embodiment can also be used as the capacitor 100. In the case where the capacitor 100A is used as the capacitor 100, the storage device illustrated in FIG. 26 includes a ferroelectric memory.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 26, the semiconductor region 313 (part of the substrate 311) where a channel is formed has a protruding shape. In addition, the conductor 316 is provided to cover the side surface and the top surface of the semiconductor region 313 with the insulator 315 therebetween. Note that the conductor 316 may be formed using a material for adjusting the work function. Such a transistor 300 is also referred to as a FIN-type transistor because it utilizes the protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 300 illustrated in FIG. 26 is an example and the structure is not limited thereto; an appropriate transistor is used in accordance with a circuit structure or a driving method.

### <Wiring Layer>

A wiring layer provided with an interlayer film, a wiring, a plug, and the like may be provided between components. A plurality of wiring layers can be provided in accordance with the design. Here, a plurality of conductors functioning as a plug or a wiring are collectively denoted by the same reference numeral in some cases. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 is embedded in the insulator 320 and the insulator 322, and a conductor 330 is embedded in the insulator 324 and the insulator 326. Note that the conductor 328 and the conductor 330 function as a plug or a wiring.

The insulator functioning as an interlayer film may function as a planarization film that covers an uneven shape thereunder. For example, the top surface of the insulator 322 may be planarized through planarization treatment using a CMP method or the like to increase the level of planarity.

A wiring layer may be provided over the insulator 326 and the conductor 330. For example, in FIG. 26, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

Similarly, a conductor 218 and a conductor (a conductor 205) included in the transistor 200 are embedded in an insulator 210, an insulator 215, and an insulator 216. Note that the conductor 218 functions as a plug or a wiring that is electrically connected to the transistor 300.

Here, like the insulator 241a and the insulator 241b described in the above embodiment, an insulator 217 is provided in contact with the side surface of the conductor 218. The insulator 217 is provided in contact with an inner wall of an opening portion formed in the insulator 210, the insulator 215, and the insulator 216. That is, the insulator 217 is provided between the conductor 218 and each of the insulator 210, the insulator 215, and the insulator 216. Note that the conductor 205 and the conductor 218 can be formed in parallel; thus, the insulator 217 is sometimes formed in contact with the side surface of the conductor 205.

As the insulator 217, any of the above-described insulators that can be used as the insulator 241a and the insulator 241b is used, for example. Since the insulator 217 is provided in contact with the insulator 215 and the insulator 222, impurities such as water and hydrogen contained in the insulator 210, the insulator 216, or the like can be inhibited from entering the oxide 230 through the conductor 218. In particular, silicon nitride is suitable because of its high blocking property against hydrogen. Moreover, oxygen contained in the insulator 210 or the insulator 216 can be prevented from being absorbed by the conductor 218.

The insulator 217 can be formed in a manner similar to that of the insulator 241a and the insulator 241b described above. For example, silicon nitride is deposited by a PEALD method and an opening reaching the conductor 356 is formed by anisotropic etching.

An insulator that can be used as the insulator 150 is used as the insulator 210, the insulator 352, and the insulator 354 that function as interlayer films, for example.

When a transistor including an oxide semiconductor is surrounded by an insulator having a function of inhibiting passage of oxygen and impurities such as hydrogen, the transistor can have stable electrical characteristics. Thus, the insulator having a function of inhibiting the passage of oxygen and impurities such as hydrogen is used as the insulator 215, the insulator 350, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, the conductor 328, the conductor 330, the conductor 356, the conductor 218, the conductor 112, and the like can be provided as a single layer or stacked layers using a conductive material such as a metal material, an alloy material, a metal nitride material, or a metal oxide material that is formed using the above materials. It is preferable to use a high-melting-point material that has both heat resistance and conductivity, such as tungsten or molybdenum, and it is preferable to use tungsten. Alternatively, it is preferable to form the conductors with a low-resistance conductive material such as aluminum or copper. The use of a low-resistance conductive material can reduce wiring resistance.

<Wiring or Plug in Layer Provided with Oxide Semiconductor>

As described in the above embodiment, the transistor 200 may be sealed with the insulator 215 and the insulator 283. Such a structure can inhibit entry of hydrogen contained in the insulator 274, the insulator 150, or the like into the insulator 280 or the like.

Note that the conductor 240 penetrates the insulator 283, and the conductor 218 penetrates the insulator 215; however, as illustrated in FIG. 26, the insulator 241 is provided in contact with the conductor 240, and the insulator 217 is provided in contact with the conductor 218. The use of a barrier insulator against hydrogen as each of the insulator 241 and the insulator 217 can inhibit entry of hydrogen into the insulator 215 and the insulator 283 through the conductor 240 and the conductor 218. In this manner, the transistor 200 is sealed with the insulator 215, the insulator 283, the insulator 241, and the insulator 217, so that impurities such as hydrogen contained in the insulator 274 or the like can be inhibited from entering from the outside.

### <Dicing Line>

A dicing line (sometimes referred to as a scribe line, a dividing line, or a cutting line) which is provided when a large-sized substrate is divided into semiconductor elements so that a plurality of semiconductor devices are each taken as a chip is described below. Examples of a dividing method include the case where a groove (a dicing line) for dividing the semiconductor elements is formed on the substrate, and then the substrate is cut along the dicing line to divide (split) it into a plurality of semiconductor devices.

Here, for example, as illustrated in FIG. 26, a region in which the insulator 283 and the insulator 215 are in contact with each other is preferably designed to overlap with the dicing line. That is, an opening is provided in the insulator 282, the insulator 280, the insulator 275, the insulator 222, and the insulator 216 in the vicinity of a region to be the dicing line that is provided on an outer edge of a memory cell including the plurality of transistors 200.

That is, in the opening provided in the insulator 282, the insulator 280, the insulator 275, the insulator 222, and the insulator 216, the insulator 215 is in contact with the insulator 283.

For example, an opening may be provided in the insulator 282, the insulator 280, the insulator 275, the insulator 222, the insulator 216, and the upper layer of the insulator 215. With such a structure, in the opening provided in the insulator 282, the insulator 280, the insulator 275, the insulator 222, and the insulator 216, the insulator 215 is in contact with the insulator 283. In that case, the lower layer of the insulator 215 and the insulator 283 may be formed using the same material and the same method. When the lower layer of the insulator 215 and the insulator 283 are formed using the same material and the same method, the adhesion therebetween can be increased. For example, silicon nitride is preferably used.

With the structure, the transistors 200 can be surrounded by the insulator 215 and the insulator 283. Since at least one of the insulator 215 and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of impurities such as hydrogen and water from the side surface direction of the divided substrate into the transistor 200 can be prevented.

With the structure, oxygen in the insulator 280 can be prevented from diffusing to the outside. Accordingly, oxygen in the insulator 280 is efficiently supplied to the channel formation region of the transistor 200. The oxygen can reduce oxygen vacancies in the channel formation region in the transistor 200. Thus, the oxide semiconductor including the channel formation region in the transistor 200 can be an oxide semiconductor with a low density of defect states and stable characteristics. That is, a change in electrical characteristics of the transistor 200 can be inhibited, and the reliability can be improved.

### [Storage Device 2]

FIG. 27 illustrates a structure example different from that of the storage device in FIG. 26. Note that in the storage device described below, components having the same functions as the components included in the storage device described above are denoted by the same reference numerals. Differences from the storage device described above are mainly described below, and common portions are not described.

FIG. 27 is a cross-sectional view of a storage device. The storage device illustrated in FIG. 27 is different from the storage device illustrated in FIG. 26 in that the wiring 1007 is not provided and the gate of the transistor 300 is electrically connected to the other of the source and the drain of the transistor 200 and the one electrode of the capacitor 100.

In the storage device illustrated in FIG. 27, the wiring 1001 is electrically connected to the source of the transistor 300, and the wiring 1002 is electrically connected to the drain of the transistor 300. In addition, the wiring 1003 is electrically connected to one of the source and the drain of the transistor 200, the wiring 1004 is electrically connected to the first gate of the transistor 200, and the wiring 1006 is electrically connected to the second gate of the transistor 200. The gate of the transistor 300 and the other of the source and the drain of the transistor 200 are electrically connected to one electrode of the capacitor 100, and the wiring 1005 is electrically connected to the other electrode of the capacitor 100.

The conductor 316 is electrically connected to the capacitor 100 or the transistor 200 through the conductor 328, the conductor 330, the conductor 356, the conductor 218, and the conductor 240.

In the storage device described in this embodiment, a memory cell array can be formed when memory cells are arranged in a matrix on the xy plane like the plurality of transistors 200 illustrated in FIG. 19A. The storage device described in this embodiment may have a structure in which memory cell arrays are stacked. When a plurality of memory cell arrays are stacked, memory cells can be integrally positioned without increasing the area occupied by the memory cell arrays. In other words, a 3D cell array can be formed.

This embodiment can be combined with the other embodiments as appropriate. In this specification, in the case where a plurality of structure examples are shown in one embodiment, the structure examples can be combined as appropriate.

### Embodiment 3

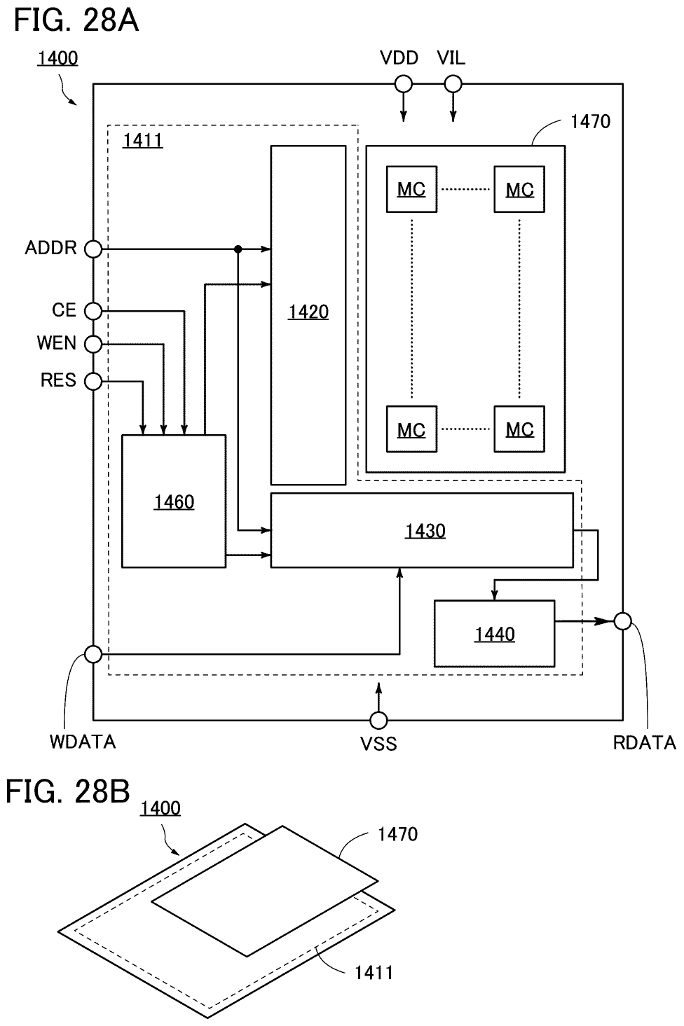

In this embodiment, a storage device including a transistor in which an oxide is used as a semiconductor (hereinafter referred to as an OS transistor in some cases) and a capacitor (hereinafter the storage device is referred to as an OS memory device in some cases) of one embodiment of the present invention will be described with reference to FIG. 28A to FIG. 31C. The OS memory device is a storage device that includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Storage Device>

FIG. 28A illustrates a structure example of the OS memory device. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder, a word line driver circuit, and the like, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WEN, and RES), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WEN, and RES) input from the outside, and generates control signals for the row decoder and the column decoder. The control signal CE is a chip enable signal, the control signal WEN is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 28A illustrates an example in which the peripheral circuit 1411 and the memory cell array 1470 are formed on the same plane; however, this embodiment is not limited thereto. For example, as illustrated in FIG. 28B, the memory cell array 1470 may be provided to overlap with part of the peripheral circuit 1411. For example, the sense amplifier may be provided below the memory cell array 1470 so that they overlap with each other. The OS transistor can be formed in a BEOL (Back end of line) process forming a wiring of a storage device. Thus, in the case where an OS transistor is used for the memory cell array 1470 and a Si transistor is used for the peripheral circuit 1411 that is provided below the memory cell array 1470 so that they overlap with each other, a technique with which the OS transistor is directly formed above the Si transistor (referred to as a BEOL-Tr technique) can be employed.

Furthermore, the memory cell array 1470 may have a stacked-layer structure. When a plurality of memory cell arrays 1470 are stacked, memory cells can be integrally positioned without increasing the area occupied by the memory cell arrays 1470. In other words, a 3D cell array can be formed. A high integration of memory cells is thus possible and a semiconductor device having a large storage capacity can be provided. Note that layers including the OS transistors can be monolithically stacked and are thus suitable.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed. The storage device of one embodiment of the present invention operates fast and can retain data for a long time.

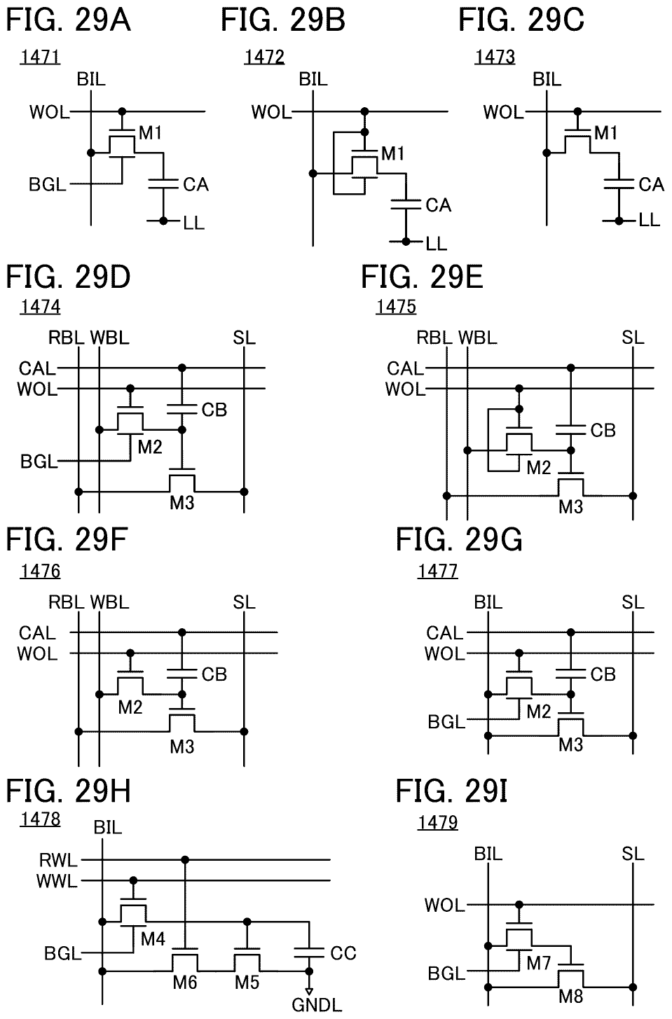

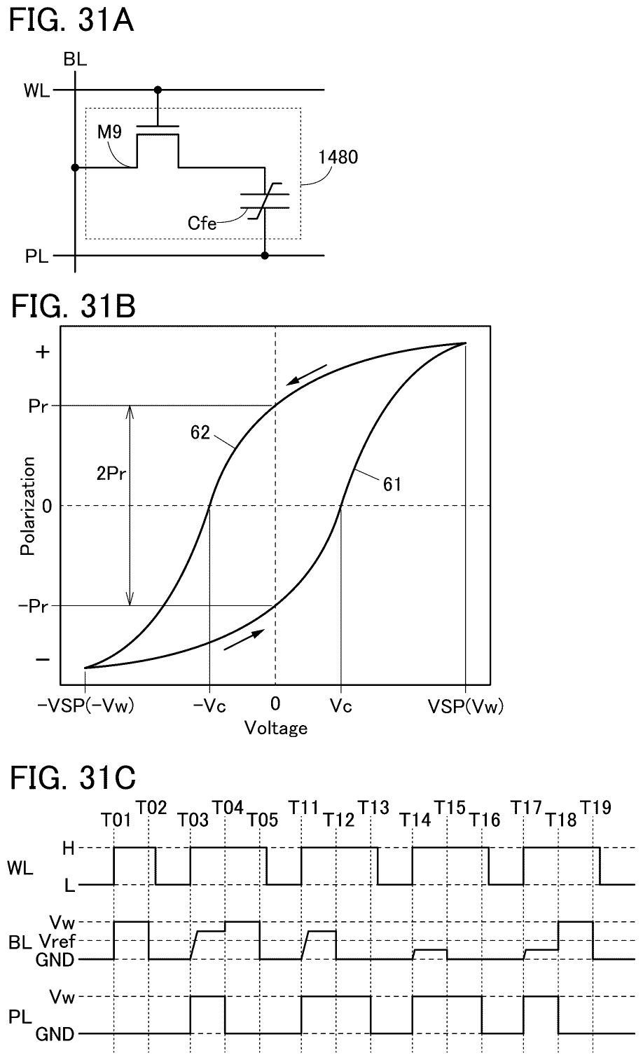

FIG. 29A to FIG. 29I and FIG. 31A illustrate structure examples of a memory cell that can be used as the memory cell MC.

### [DOSRAM]

FIG. 29A to FIG. 29C illustrate circuit structure examples of DRAM memory cells. In this specification and the like, a DRAM using a memory cell including one OS transistor and one capacitor is referred to as a DOSRAM (Dynamic Oxide Semiconductor Random Access Memory) in some cases. A memory cell 1471 illustrated in FIG. 29A includes a transistor M1 and a capacitor CA. Note that the transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. At the time of data writing and data reading, the wiring LL may be at a ground potential or a low-level potential. The wiring BGL functions as a wiring for applying a potential to the back gate of the transistor M1. When a given potential is applied to the wiring BGL, the threshold voltage of the transistor M1 can be increased or decreased.

Here, the memory cell 1471 illustrated in FIG. 29A corresponds to the storage device illustrated in FIG. 26. That is, the transistor M1 and the capacitor CA correspond to the transistor 200 and the capacitor 100, respectively.

The circuit structure of the memory cell MC is not limited to that of the memory cell 1471 and can be changed. For example, as in a memory cell 1472 illustrated in FIG. 29B, the back gate of the transistor M1 may be connected not to the wiring BGL but to the wiring WOL in the memory cell MC. Alternatively, for example, the transistor M1 may be a single-gate transistor, that is, a transistor without a back gate in the memory cell MC as in a memory cell 1473 illustrated in FIG. 29C.

In the case where the semiconductor device described in any of the above embodiments is used in the memory cell 1471 and the like, the transistor 200 can be used as the transistor M1, and the capacitor 100 can be used as the capacitor CA. When an OS transistor is used as the transistor M1, the leakage current of the transistor M1 can be extremely low. That is, with the use of the transistor M1, written data can be retained for a long time, and thus the frequency of the refresh operation for the memory cell can be reduced. Alternatively, refresh operation for the memory cell can be unnecessary. In addition, since the transistor M1 has an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. This reduces bit line capacitance, which can reduce the storage capacitance of the memory cell.

### [NOSRAM]

FIG. 29D to FIG. 29G each illustrate a circuit structure example of a gain memory cell including two transistors and one capacitor. A memory cell 1474 illustrated in FIG. 29D includes a transistor M2, a transistor M3, and a capacitor CB. Note that the transistor M2 includes a top gate (simply referred to as a gate in some cases) and a back gate. In this specification and the like, a storage device including a gain memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing and data reading, a high-level potential is preferably applied to the wiring CAL. During data retaining, a low-level potential is preferably applied to the wiring CAL. The wiring BGL functions as a wiring for applying a potential to the back gate of the transistor M2. The threshold voltage of the transistor M2 can be increased or decreased by applying a given potential to the wiring BGL.

Here, the memory cell 1474 illustrated in FIG. 29D corresponds to the storage device illustrated in FIG. 27. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 1003, the wiring 1004, the wiring 1006, the wiring 1005, the wiring 1002, and the wiring 1001, respectively.

The circuit structure of the memory cell MC is not limited to that of the memory cell 1474 and can be changed as appropriate. For example, as in a memory cell 1475 illustrated in FIG. 29E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 29F. For example, the memory cell MC may have a structure in which the wiring WBL and the wiring RBL are combined into one wiring BIL as in a memory cell 1477 illustrated in FIG. 29G.

In the case where the semiconductor device described in any of the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. Consequently, with the use of the transistor M2, written data can be retained for a long time, and thus the frequency of the refresh operation for the memory cell can be reduced. Alternatively, refresh operation for the memory cell can be unnecessary. In addition, since the transistor M2 has an extremely low leakage current, multi-level data or analog data can be retained in the memory cell 1474. The same applies to the memory cell 1475 to the memory cell 1477.

Note that the transistor M3 may be a transistor containing silicon in a channel formation region (hereinafter sometimes referred to as a Si transistor). The Si transistor may be either an n-channel transistor or a p-channel transistor. A Si transistor has higher field-effect mobility than an OS transistor in some cases. Therefore, a Si transistor may be used as the transistor M3 functioning as a reading transistor. Furthermore, the transistor M2 can be stacked over the transistor M3 when a Si transistor is used as the transistor M3, in which case the area occupied by the memory cell can be reduced, leading to high integration of the storage device.

Alternatively, the transistor M3 may be an OS transistor. When OS transistors are used as the transistor M2 and the transistor M3, the circuit of the memory cell array 1470 can be formed using only n-channel transistors.

FIG. 29H illustrates an example of a gain memory cell including three transistors and one capacitor. A memory cell 1478 illustrated in FIG. 29H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for applying a low-level potential. Note that the memory cell 1478 may be electrically connected to the wiring RBL and the wiring WBL instead of the wiring BIL.

The transistor M4 is an OS transistor with a back gate, and the back gate is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In that case, the circuit of the memory cell array 1470 can be formed using only n-channel transistors.

In the case where the semiconductor device described in any of the above embodiments is used in the memory cell 1478, the transistor 200 can be used as the transistor M4, the transistor 300 can be used as each of the transistor M5 and the transistor M6, and the capacitor 100 can be used as the capacitor CC. When an OS transistor is used as the transistor M4, the leakage current of the transistor M4 can be extremely low.

FIG. 29I illustrates an example of a gain memory cell including two transistors. A memory cell 1479 illustrated in FIG. 29I includes a transistor M7 and a transistor M8. The memory cell 1479 is electrically connected to the wiring BIL, the wiring WWL, the wiring BGL, and the wiring SL.

The transistor M7 is an OS transistor with a back gate, and the back gate is electrically connected to the wiring BGL. Note that the back gate and the gate of the transistor M7 may be electrically connected to each other. Alternatively, the transistor M7 does not necessarily include the back gate.

In the memory cell 1479 illustrated in FIG. 29I, the gate capacitance of the transistor M8 is used as storage capacitance. That is, the memory cell 1479 can be regarded as a capacitor-less memory cell. The memory cell 1479 can be regarded as the memory cell 1477 illustrated in FIG. 29G from which the capacitor CB is omitted, and can be regarded as a gain memory cell with two transistors and no capacitor.

When the OS transistor is used as the transistor M7 and the transistor M7 is turned off, charge at a node where one of a source electrode and a drain electrode of the transistor M7 is electrically connected to a gate electrode of the transistor M8 can be retained for an extremely long time. Accordingly, a nonvolatile memory cell can be obtained.

The transistor M8 may be an n-channel Si transistor or a p-channel Si transistor.

In the case where the semiconductor device described in any of the above embodiments is used in the memory cell 1479, the transistor 200 can be used as the transistor M7, and the transistor 300 can be used as the transistor M8. When an OS transistor is used as the transistor M7, the leakage current of the transistor M7 can be extremely low.

Alternatively, the transistor M8 may be an OS transistor. In that case, the circuit of the memory cell array 1470 can be formed using only n-channel transistors.

In the case where the semiconductor device described in any of the above embodiments is used in the memory cell 1479, the transistor 200 can be used as each of the transistor M7 and the transistor M8. With this structure, the transistor M7 and the transistor M8 can be formed in the same layer. Accordingly, a fabrication process at the time of stacking layers each including the memory cell 1479 can be simple and the productivity can be high as compared with the case where the transistor M7 and the transistor M8 are formed in different layers.

In the case where the transistor 200 is used as each of the transistor M7 and the transistor M8, the components (including a channel length, a channel width, a cross-sectional shape, and the like) of the transistor is determined as appropriate in accordance with the characteristics required for the transistor M7 and the transistor M8.

Note that there is no particular limitation on the structure of the transistor M8 regardless of the semiconductor material used for the transistor M8. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer where a channel is formed.

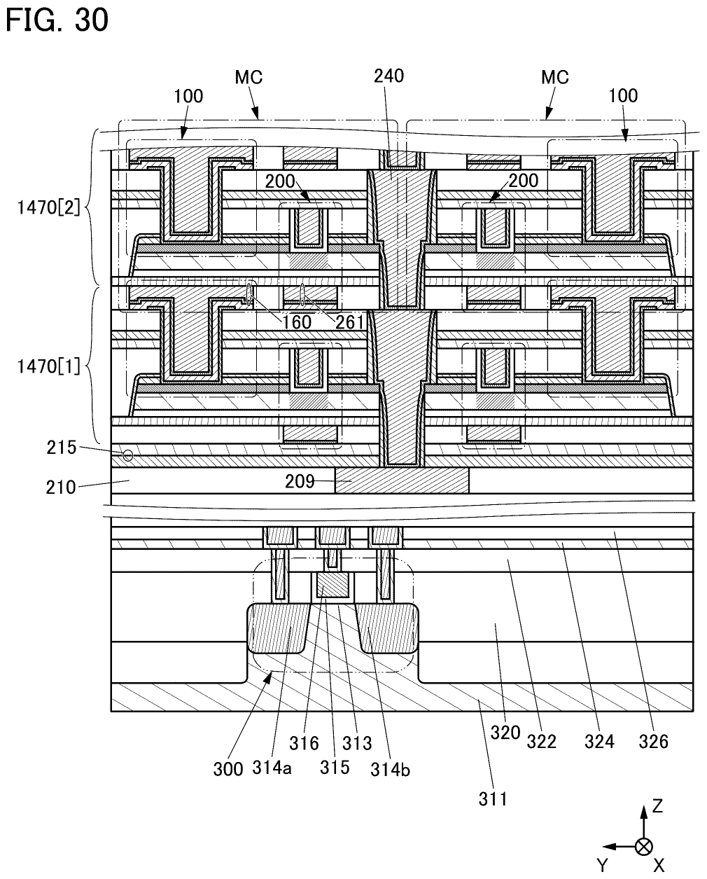

As described above, the memory cell array 1470 may have a stacked-layer structure. When a plurality of memory cell arrays 1470 are stacked, memory cells can be integrally positioned without increasing the area occupied by the memory cell arrays 1470. In other words, a 3D cell array can be formed. FIG. 30 illustrates an example of a storage device having a structure in which a plurality of memory cell arrays 1470 are stacked.

The storage device illustrated in FIG. 30 includes a first layer including the transistor 300 and a memory cell array 1470[1] to a memory cell array 1470[m] (only the memory cell array 1470[1] and the memory cell array 1470[2] are illustrated in FIG. 30) over the first layer. Note that the structure below and including the insulator 326 of the storage device illustrated in FIG. 30 is similar to that of the storage device illustrated in FIG. 26.

The memory cell array 1470[1] to the memory cell array 1470[m] each include a plurality of memory cells MC. The plurality of memory cells MC each include the transistor 200 and the capacitor 100. Here, the transistor 200 corresponds to the transistor 200 described in any of the above embodiments, and the capacitor 100 corresponds to the capacitor 100 or the capacitor 100A described in any of the above embodiments. Note that FIG. 30 illustrates an example in which the transistor 200 and the capacitor 100 illustrated in FIG. 22 are used as the transistor 200 and the capacitor 100.

A wiring layer provided with an interlayer film, a wiring, a plug, and the like may be provided between the first layer and the memory cell array 1470 or between the two memory cell arrays 1470. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

The insulator 210 is provided above the insulator 326, and a conductor 209 is provided in an opening portion formed in the insulator 210. Furthermore, the insulator 215 is provided over the insulator 210. Part of the conductor 240 provided in the memory cell array 1470[1] fills an opening portion formed in the insulator 215. Here, an insulator that can be used as the insulator 216 can be used as the insulator 210.

A conductor (not illustrated) is provided in contact with the bottom surface of the conductor 209. The top surface of the conductor 209 is provided in contact with the bottom surface of the conductor 240 provided in the memory cell array 1470[1]. With such a structure, the conductor 240 functioning as the wiring BL can be electrically connected to a circuit element such as a switch, a transistor, a capacitor, an inductor, a resistor, or a diode, a wiring, an electrode, or a terminal, which is provided below the memory cell array 1470.

The memory cell array 1470[1] to the memory cell array 1470[m] each include the plurality of memory cells MC. The conductor 240 included in each memory cell MC is electrically connected to the conductor 240 in an upper layer and the conductor 240 in a lower layer.

As illustrated in FIG. 30, the conductor 240 is shared between the adjacent memory cells MC. In the adjacent memory cells MC, the components in the right memory cell and the components in the left memory cell are arranged symmetrically about the conductor 240.

Here, the conductor 160 that functions as the upper electrode of the capacitor 100 in a lower layer (e.g., the layer of the memory cell array 1470[1]) and a conductor 261 that functions as the second gate electrode of the transistor 200 in an upper layer (e.g., the layer of the memory cell array 1470[2]) can be formed in the same layer. In other words, the conductor 160 of the capacitor 100 in the lower layer and the conductor 261 of the transistor 200 in the upper layer can be formed to fill respective openings formed in the same insulator 216. When the conductor 160 of the capacitor 100 in the lower layer and the conductor 261 of the transistor 200 in the upper layer are formed by processing one conductive film, the above-described structure is obtained. In this case, the conductor 160 of the capacitor 100 in the lower layer includes the same material as the conductor 261 of the transistor 200 in the upper layer.

When the conductor 160 of the capacitor 100 in the lower layer and the conductor 261 of the transistor 200 in the upper layer are formed at the same time in the above manner, the number of steps for fabricating the storage device of this embodiment can be reduced and the productivity of the storage device can be increased.

In the memory cell array 1470, the plurality of memory cell arrays (the memory cell array 1470[1] to the memory cell array 1470[m]) can be stacked. When the memory cell array 1470[1] to the memory cell array 1470[m] in the memory cell array 1470 are arranged in a direction perpendicular to the substrate surface, the memory density of the memory cells can be increased. The memory cell array 1470 can be fabricated by repeating the same manufacturing process in the perpendicular direction. The manufacturing cost of the memory cell array 1470 of the storage device illustrated in FIG. 30 can be reduced.

### [Ferroelectric Memory]

FIG. 31A illustrates a circuit structure example of a memory cell including a ferroelectric capacitor. A memory cell 1480 includes a transistor M9 and a capacitor Cfe. Here, as the memory cell 1480, the semiconductor device including the transistor 200 and the capacitor 100A illustrated in FIG. 23A to FIG. 25B can be used. In this case, the transistor M9 and the capacitor Cfe correspond to the transistor 200 and the capacitor 100A, respectively. Note that the transistor M9 may have a back gate or may have no back gate.

The OS transistor described in the above embodiment is preferably used as the transistor M9. The OS transistor has a characteristic of a high dielectric breakdown voltage between its source and drain. That is, the OS transistor can be referred to as a minute device with a high breakdown voltage. Thus, with use of the OS transistor as the transistor M9, a high voltage can be applied to the transistor M9 even when the transistor M9 is miniaturized. The miniaturization of the transistor M9 can reduce the area occupied by the semiconductor device. Accordingly, the semiconductor devices can be arranged at high density. Thus, a storage device having a large storage capacity can be achieved.

One of a source and a drain of the transistor M9 is electrically connected to a wiring BL. The other of the source and the drain of the transistor M9 is electrically connected to one electrode of the capacitor Cfe. A gate of the transistor M9 is electrically connected to a wiring WL. The other electrode of the capacitor Cfe is electrically connected to a wiring PL.

The wiring WL has a function of a word line, and the potential of the wiring WL is controlled so that the on/off states of the transistor M9 can be controlled. For example, setting the potential of the wiring WL to a high potential (H) can bring the transistor M9 into an on state; setting the potential of the wiring WL to a low potential (L) can bring the transistor M9 into an off state. The wiring WL is electrically connected to the word line driver circuit included in the row circuit 1420, and the potential of the wiring WL can be controlled by the word line driver circuit.

The wiring BL has a function of a bit line, and a potential corresponding to the potential of the wiring BL is supplied to one electrode of the capacitor Cfe when the transistor M9 is in an on state. The wiring BL is electrically connected to the bit line driver circuit of the column circuit 1430. The bit line driver circuit has a function of generating data to be written to the memory cell MC. Furthermore, the bit line driver circuit has a function of reading data output from the memory cell MC. Specifically, the sense amplifier is provided in the bit line driver circuit, and data output from the memory cell MC can be read using the sense amplifier.

The wiring PL functions as a plate line. A potential is supplied to the other electrode of the capacitor Cfe through the wiring PL.

The capacitor Cfe includes a material that can have ferroelectricity as a dielectric layer between the two electrodes. As the material that can have ferroelectricity, any of the above-described materials that can be used for the insulator 130 is used. With the ferroelectric layer that can be thin, the storage device combined with a miniaturized transistor can be obtained. The dielectric layer included in the capacitor Cfe is referred to as a ferroelectric layer in the following description.

A ferroelectric layer included in the capacitor Cfe has hysteresis characteristics. FIG. 31B is a graph showing an example of the hysteresis characteristics. The horizontal axis in FIG. 31B represents the voltage applied to the ferroelectric layer. The voltage can be a difference between the potential of one electrode of the capacitor Cfe and the potential of the other electrode of the capacitor Cfe, for example.

In FIG. 31B, the vertical axis represents polarization of the ferroelectric layer; a positive value indicates that positive charges are concentrated on one electrode side of the capacitor Cfe and negative charges are concentrated on the other electrode side of the capacitor Cfe. On the other hand, a negative value of the polarization indicates that positive charges are concentrated on the other electrode side of the capacitor Cfe and negative charges are concentrated on the one electrode side of the capacitor Cfe.

Note that the voltage represented by the horizontal axis of the graph in FIG. 31B may be a difference between the potential of the other electrode of the capacitor Cfe and the potential of the one electrode of the capacitor Cfe. Furthermore, the polarization represented by the vertical axis of the graph in FIG. 31B may be a positive value in the case where positive charges are concentrated on the other electrode side of the capacitor Cfe and negative charges are concentrated on the one electrode side of the capacitor Cfe, and may be a negative value in the case where positive charges are concentrated on the one electrode side of the capacitor Cfe and negative charges are concentrated on the other electrode side of the capacitor Cfe.

As shown in FIG. 31B, the hysteresis characteristics of the ferroelectric layer can be represented by a curve 61 and a curve 62. The voltages at the intersecting points between the curve 61 and the curve 62 are VSP and −VSP. The polarities of VSP and −VSP can be said to be different.

When a voltage lower than or equal to −VSP is applied to the ferroelectric layer and then the voltage applied to the ferroelectric layer is increased, the polarization of the ferroelectric layer is increased along the curve 61. On the other hand, when a voltage higher than or equal to VSP is applied to the ferroelectric layer and then the voltage applied to the ferroelectric layer is decreased, the polarization of the ferroelectric layer is decreased along the curve 62. Thus, VSP and −VSP can each be referred to as a saturation polarization voltage. Incidentally, VSP is referred to as a first saturation polarization voltage and −VSP is referred to as a second saturation polarization voltage in some cases. In addition, the absolute values of the first saturation polarization voltage and the second saturation polarization voltage are equal to each other in FIG. 31B, but may be different from each other.

Here, Vc represents a voltage applied to the ferroelectric layer in the case where the polarization of the ferroelectric layer is 0 in the change of the polarization of the ferroelectric layer along the curve 61. In addition, −Vc represents a voltage applied to the ferroelectric layer in the case where the polarization of the ferroelectric layer is 0 in the change of the polarization of the ferroelectric layer along the curve 62. Vc and −Vc can each be referred to as coercive voltage. The value of Vc and the value of −Vc can be said to be values between −VSP and VSP. For example, Vc is referred to as a first coercive voltage and −Vc is referred to as a second coercive voltage in some cases. The absolute values of the first coercive voltage and the second coercive voltage are equal to each other in FIG. 31B, but may be different from each other.

The maximum value and the minimum value of polarization when a voltage is not applied to the ferroelectric layer are referred to as “remanent polarization Pr” and “remanent polarization −Pr”, respectively. A difference between the remanent polarization Pr and the remanent polarization −Pr is referred to as “remanent polarization 2Pr”.

As described above, a voltage applied to the ferroelectric layer included in the capacitor Cfe can be expressed by a difference between the potential of one electrode of the capacitor Cfe and the potential of the other electrode of the capacitor Cfe. As described above, the other electrode of the capacitor Cfe is electrically connected to the wiring PL. Thus, by controlling the potential of the wiring PL, the voltage applied to the ferroelectric layer included in the capacitor Cfe can be controlled.

An example of a method for driving the memory cell 1480 illustrated in FIG. 31A is described below. In the following description, the voltage applied to the ferroelectric layer of the capacitor Cfe indicates a difference (potential difference) between the potential of one electrode of the capacitor Cfe and the potential of the other electrode of the capacitor Cfe (the wiring PL). In addition, the transistor M9 is an n-channel transistor.

FIG. 31C is a timing chart showing an example of a method for driving the memory cell 1480. FIG. 31C shows an example in which binary digital data is written to and read from the memory cell 1480. Specifically, in the example shown in FIG. 31C, data “1” is written to the memory cell 1480 in a period from Time T01 to Time T02, reading and rewriting are performed in a period from Time T03 to Time T05, reading and writing of data “0” to the memory cell 1480 are performed in a period from Time T11 to Time T13, reading and rewriting are performed in a period from Tim T14 to Time T16, and reading and writing of data “1” to the memory cell 1480 are performed in a period from Time T17 to Time T19.

The sense amplifier electrically connected to the wiring BL is supplied with Vref as a reference potential. In the reading operation illustrated in FIG. 31C or the like, when the potential of the wiring BL is higher than Vref, data “1” is read by the bit line driver circuit. In contrast, when the potential of the wiring BL is lower than Vref, data “0” is read by the bit line driver circuit.

In the period from Time T01 to Time T02, the potential of the wiring WL is set to a high potential. Thus, the transistor M9 is turned on. In addition, the potential of the wiring BL is set to Vw. Since the transistor M9 is in an on state, the potential of one electrode of the capacitor Cfe becomes Vw. In addition, the potential of the wiring PL is set to GND. Accordingly, the voltage applied to the ferroelectric layer of the capacitor Cfe becomes “Vw-GND”. As a result, data “1” can be written to the memory cell 1480. Consequently, the period from Time T01 to Time T02 can be referred to as a write operation period.

Here, Vw is preferably higher than or equal to VSP, and is preferably equal to VSP, for example. In this specification and the like, GND is set to a ground potential, but is not necessarily a ground potential as long as the memory cell 1480 can be driven so as to achieve an object of one embodiment of the present invention. For example, when the absolute value of the first saturation polarization voltage is different from the absolute value of the second saturation polarization voltage, and the absolute value of the first coercive voltage is different from the absolute value of the second coercive voltage, GND can be a potential other than a ground.

In the period from Time T02 to Time T03, the potential of the wiring BL and the potential of the wiring PL are set to GND. Accordingly, the voltage applied to the ferroelectric layer of the capacitor Cfe becomes 0 V. The voltage “Vw-GND” applied to the ferroelectric layer of the capacitor Cfe in the period from Time T01 to Time T02 can be higher than or equal to VSP, and thus the polarization quantity of the ferroelectric layer of the capacitor Cfe is changed along the curve 62 in FIG. 31B in the period from Time T02 to Time T03. From the above, in the period from Time T02 to Time T03, polarization reversal does not occur in the ferroelectric layer of the capacitor Cfe.

After the potential of the wiring BL and the potential of the wiring PL are set to GND, the potential of the wiring WL is set to a low potential. Thus, the transistor M9 is turned off. Accordingly, the write operation is completed, and the data “1” is retained in the memory cell 1480. Note that the potentials of the wiring BL and the wiring PL can be any potentials as long as polarization reversal does not occur in the ferroelectric layer of the capacitor Cfe, i.e., the voltage applied to the ferroelectric layer of the capacitor Cfe is higher than or equal to −Vc as the second coercive voltage.

In the period from Time T03 to Time T04, the potential of the wiring WL is set to the high potential. Thus, the transistor M9 is turned on. The potential of the wiring PL is set to Vw. By setting the potential of the wiring PL to Vw, the voltage applied to the ferroelectric layer of the capacitor Cfe becomes “GND-Vw”. As described above, in the period from Time T01 to Time T02, the voltage applied to the ferroelectric layer of the capacitor Cfe is “Vw-GND”. Thus, polarization reversal occurs in the ferroelectric layer of the capacitor Cfe. At the time of the polarization reversal, a current flows through the wiring BL, and the potential of the wiring BL becomes higher than Vref. Thus, the bit line driver circuit can read the data “1” retained in the memory cell 1480. Accordingly, the period from Time T03 to Time T04 can be referred to as a read operation period. Note that Vref is higher than GND and lower than Vw but may be higher than Vw, for example.

Since the above reading is destructive reading, the data “1” retained in the memory cell 1480 is lost. Thus, in the period from Time T04 to Time T05, the potential of the wiring BL is set to Vw and the potential of the wiring PL is set to GND. Thus, data “1” is rewritten to the memory cell 1480. Consequently, the period from Time T04 to Time T05 can be referred to as a rewrite operation period.

In the period from Time T05 to Time T11, the potential of the wiring BL and the potential of the wiring PL are set to GND. After that, the potential of the wiring WL is set to the low potential. Accordingly, the rewrite operation is completed, and the data “1” is retained in the memory cell 1480.

In the period from Time T11 to Time T12, the potential of the wiring WL is set to the high potential and the potential of the wiring PL is set to Vw. Since the data “1” is retained in the memory cell 1480, the potential of the wiring BL becomes higher than Vref, and the data “1” retained in the memory cell 1480 is read. Consequently, the period from Time T11 to Time T12 can be referred to as a read operation period.

In the period from Time T12 to Time T13, the potential of the wiring BL is set to GND. Since the transistor M9 is in an on state, the potential of one electrode of the capacitor Cfe becomes GND. The potential of the wiring PL is set to Vw. In the above manner, the voltage applied to the ferroelectric layer of the capacitor Cfe becomes “GND-Vw”. As a result, data “0” can be written to the memory cell 1480. Consequently, the period from Time T12 to Time T13 can be referred to as a write operation period.

In the period from Time T13 to Time T14, the potential of the wiring BL and the potential of the wiring PL are set to GND. Accordingly, the voltage applied to the ferroelectric layer of the capacitor Cfe becomes 0 V. The voltage “GND-Vw” applied to the ferroelectric layer of the capacitor Cfe in the period from Time T12 to Time T13 can be set to be −VSP or lower; thus, the polarization quantity of the ferroelectric layer of the capacitor Cfe is changed along the curve 61 in FIG. 31B in the period from Time T13 to Time T14. From the above, in the period from Time T13 to Time T14, polarization reversal does not occur in the ferroelectric layer of the capacitor Cfe.

After the potential of the wiring BL and the potential of the wiring PL are set to GND, the potential of the wiring WL is set to the low potential. Thus, the transistor M9 is turned off. Accordingly, the write operation is completed, and the data “0” is retained in the memory cell 1480. Note that the potentials of the wiring BL and the wiring PL can be any potentials as long as polarization reversal does not occur in the ferroelectric layer of the capacitor Cfe, i.e., the voltage applied to the ferroelectric layer of the capacitor Cfe is lower than or equal to Vc as the first coercive voltage.

In the period from Time T14 to Time T15, the potential of the wiring WL is set to the high potential. Thus, the transistor M9 is turned on. The potential of the wiring PL is set to Vw. By setting the potential of the wiring PL to Vw, the voltage applied to the ferroelectric layer of the capacitor Cfe becomes “GND-Vw”. As described above, the voltage applied to the ferroelectric layer of the capacitor Cfe in the period from Time T12 to Time T13 is “GND-Vw”. Thus, polarization reversal does not occur in the ferroelectric layer of the capacitor Cfe. Consequently, the amount of current flowing through the wiring BL is smaller than that in the case where the polarization reversal occurs in the ferroelectric layer of the capacitor Cfe. Accordingly, the increase amount in the potential of the wiring BL is smaller than that in the case where the polarization reversal occurs in the ferroelectric layer of the capacitor Cfe; specifically, the potential of the wiring BL becomes lower than or equal to Vref. Thus, the bit line driver circuit can read the data “0” retained in the memory cell 1480. Accordingly, the period from Time T14 to Time T15 can be referred to as a read operation period.

In the period from Time T15 to Time T16, the potential of the wiring BL is set to GND and the potential of the wiring PL is set to Vw. Thus, data “0” is rewritten to the memory cell 1480. Consequently, the period from Time T15 to Time T16 can be referred to as a rewrite operation period.

In the period from Time T16 to Time T17, the potential of the wiring BL and the potential of the wiring PL are set to GND. After that, the potential of the wiring WL is set to the low potential. Accordingly, the rewrite operation is completed, and the data “0” is retained in the memory cell 1480.

In the period from Time T17 to Time T18, the potential of the wiring WL is set to the high potential and the potential of the wiring PL is set to Vw. Since the data “0” is retained in the memory cell 1480, the potential of the wiring BL becomes lower than Vref, and the data “0” retained in the memory cell 1480 is read. Consequently, the period from Time T17 to Time T18 can be referred to as a read operation period.

The potential of the wiring BL is set to Vw in the period from Time T18 to Time T19. Since the transistor M9 is in an on state, the potential of one electrode of the capacitor Cfe becomes Vw. The potential of the wiring PL is set to GND. Accordingly, the voltage applied to the ferroelectric layer of the capacitor Cfe becomes “Vw-GND”. As a result, data “1” can be written to the memory cell 1480. Consequently, the period from Time T18 to Time T19 can be referred to as a write operation period.

After Time T19, the potential of the wiring BL and the potential of the wiring PL are set to GND. After that, the potential of the wiring WL is set to the low potential. Accordingly, the write operation is completed, and the data “1” is retained in the memory cell 1480.

The semiconductor device including the ferroelectric layer in the capacitor Cfe functions as a nonvolatile storage element that can retain information written thereto even when power supply is stopped.

A DRAM requires regular refresh operation and thus increases power consumption. The semiconductor device including the ferroelectric layer in the capacitor Cfe does not require refresh operation and thus can have low power consumption.

In this specification and the like, a storage element or a storage circuit including a ferroelectric layer is referred to as a “ferroelectric memory” or an “FE memory” in some cases. Thus, the semiconductor device of one embodiment of the present invention is a ferroelectric memory and is also an FE memory. The FE memory can be expected to achieve the number of rewrite cycles of 1×10¹⁰ or more, preferably 1×10¹² or more, further preferably 1×10¹⁵ or more. The FE memory can be expected to achieve an operation frequency of greater than or equal to 10 MHz, preferably greater than or equal to 1 GHz.

In the FE memory, the remanent polarization 2Pr and data retention capability have a correlation, and as the remanent polarization 2Pr becomes smaller, the data retention capability declines. In this specification and the like, a period over which the remanent polarization 2Pr is reduced by 5% (the data retention capability declines by 5%) is referred to as a “memory retention period”. The FE memory can be expected to have a memory retention period of 10 days or longer, preferably one year or longer, further preferably 10 years or longer in an environment at a temperature of 150° C. or 200° C.

The FE memory can also be applied to a cache memory and a register in a CPU, a GPU (Graphics Processing Unit), and the like. A normally-off CPU (NoffCPU (registered trademark)) can be obtained by a combination of the FE memory with a cache memory, a register, and the like in a CPU. A normally-off GPU (NoffGPU (registered trademark)) can be obtained by a combination of the FE memory with a cache memory, a register, and the like in a GPU.

The structure, method, and the like described in this embodiment can be used in an appropriate combination with any of other structures, methods, and the like described in this embodiment or any of structures, methods, and the like described in the other embodiments.

### Embodiment 4

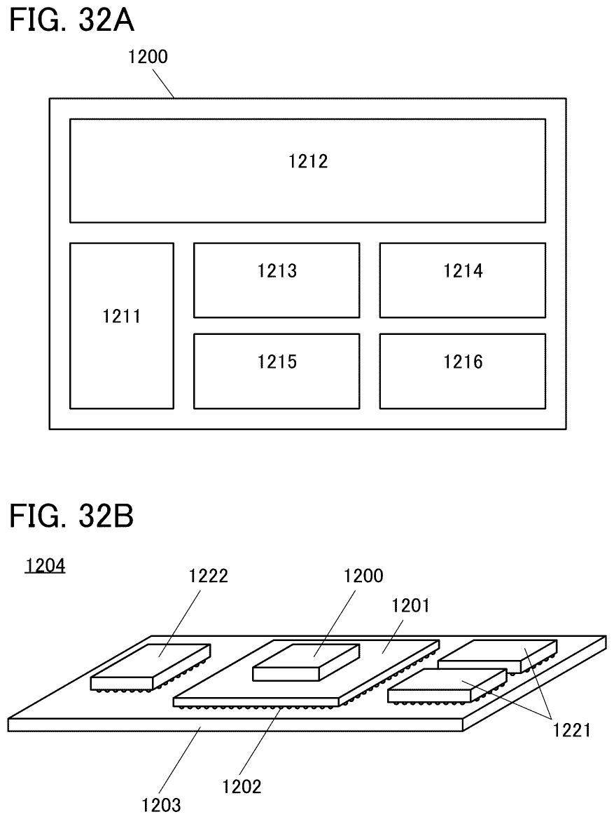

In this embodiment, an example of a chip 1200 on which the semiconductor device of the present invention is mounted is described with reference to FIG. 32A and FIG. 32B. A plurality of circuits (systems) are mounted on the chip 1200. A technique for integrating a plurality of circuits (systems) into one chip is referred to as system on chip (SoC) in some cases.

As illustrated in FIG. 32A, the chip 1200 includes a CPU 1211, a GPU 1212, one or more analog arithmetic units 1213, one or more memory controllers 1214, one or more interfaces 1215, one or more network circuits 1216, and the like.

The chip 1200 is provided with a bump (not illustrated) and is connected to a first surface of a package substrate 1201 as illustrated in FIG. 32B. In addition, a plurality of bumps 1202 are provided on a rear side of the first surface of the package substrate 1201, and the package substrate 1201 is connected to a motherboard 1203.

Storage devices such as a DRAM 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit and a product-sum operation circuit using an oxide semiconductor of the present invention are provided in the GPU 1212, image processing and product-sum operation can be performed with low power consumption.

In addition, since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit for a LAN (Local Area Network) or the like. The network circuit may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be fabricated at low cost.

The motherboard 1203 provided with the package substrate 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in an appropriate combination with any of those in the other embodiments, the other examples, and the like described in this specification.

### Embodiment 5

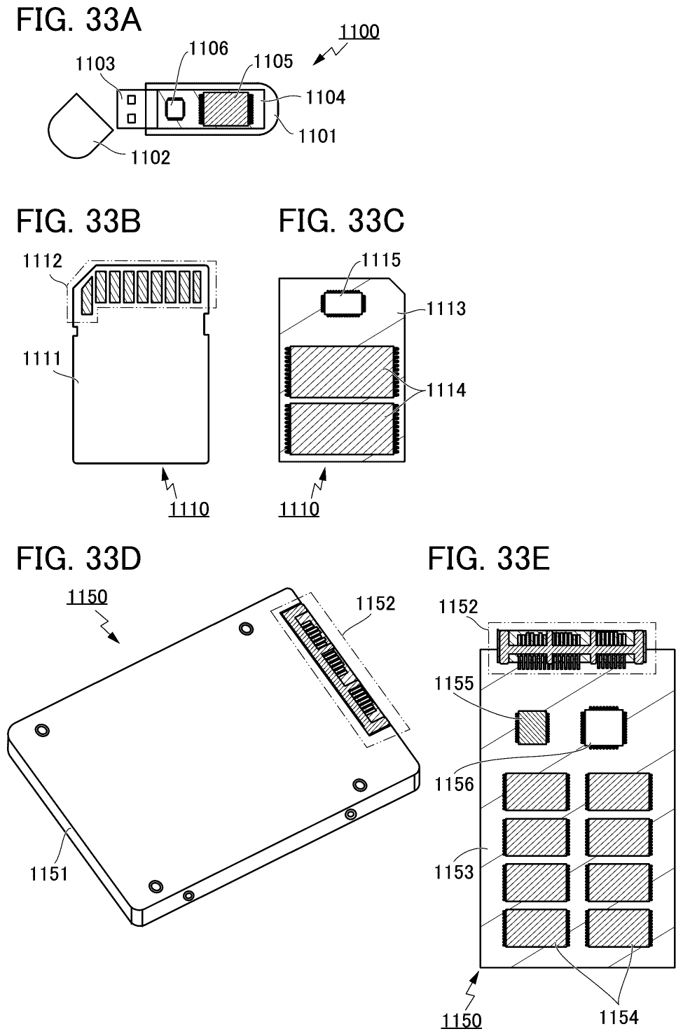

In this embodiment, application examples of the semiconductor device using the storage device described in the above embodiment will be described. The storage device described in the above embodiment can be used for a variety of removable storage devices such as memory cards (e.g., SD cards), USB memories, and SSDs (solid state drives). FIG. 33A to FIG. 33E schematically illustrate some structure examples of removable storage devices. The semiconductor device described in the above embodiment is processed into a packaged memory chip and used in a variety of storage devices and removable memories, for example.

FIG. 33A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device or the semiconductor device described in the above embodiment can be incorporated in the memory chip 1105 or the like.

FIG. 33B is a schematic external view of an SD card, and FIG. 33C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. With this, data can be read from and written to the memory chip 1114 by radio communication between a host device and the SD card 1110. The storage device or the semiconductor device described in the above embodiment can be incorporated in the memory chip 1114 or the like.

FIG. 33D is a schematic external view of an SSD, and FIG. 33E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip is used, for example. When the memory chip 1154 is also provided on the back side of the substrate 1153, the capacity of the SSD 1150 can be increased. The storage device or the semiconductor device described in the above embodiment can be incorporated in the memory chip 1154 or the like.

This embodiment can be implemented in an appropriate combination with the structures described in the other embodiments and the like.

### Embodiment 6

In this embodiment, a transistor whose channel formation region includes an oxide semiconductor (OS transistor) is described. In the description of the OS transistor, comparison with a transistor whose channel formation region includes silicon (also referred to as Si transistor) is also described briefly.

### [OS Transistor]

An oxide semiconductor having a low carrier concentration is preferably used for the OS transistor. For example, the carrier concentration in the channel formation region of the oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and thus has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen and nitrogen. Note that an impurity in an oxide semiconductor refers to, for example, an element other than the main components of the oxide semiconductor. For example, an element with a concentration lower than 0.1 atomic % can be regarded as an impurity.

An OS transistor is likely to have its electrical characteristics changed by impurities and oxygen vacancies in a channel formation region in the oxide semiconductor, which might adversely affect the reliability. In the OS transistor, a defect that is an oxygen vacancy in the oxide semiconductor into which hydrogen has entered (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region is an n⁻-type region and the source region and the drain region are n⁺-type regions.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

The configuration, structure, method, or the like described in this embodiment can be used in an appropriate combination with the configuration, structure, method, or the like described in the other embodiments and the like.

### Embodiment 7

In this embodiment, an electronic component, an electronic appliance, a large computer, a device for space, and a data center (also referred to as DC) for which the semiconductor device described in the above embodiments can be used will be described. An electronic component, an electronic appliance, a large computer, a device for space, and a data center each employing the semiconductor device of one embodiment of the present invention are effective in improving performance, for example, reducing power consumption.

### [Electronic Component]

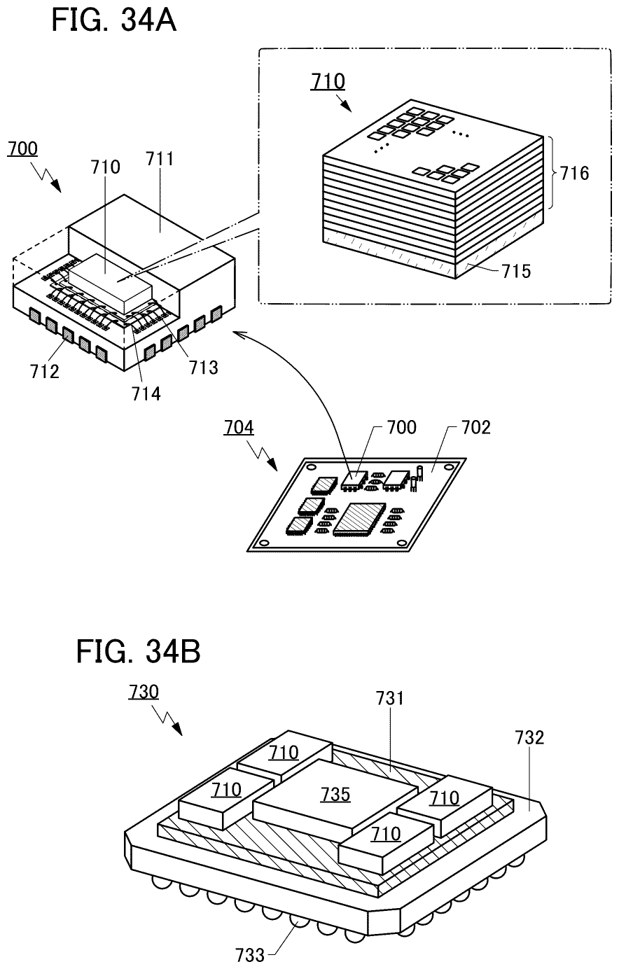

FIG. 34A is a perspective view of a substrate (a mounting board 704) on which an electronic component 700 is mounted. The electronic component 700 illustrated in FIG. 34A includes a semiconductor device 710 in a mold 711. FIG. 34A omits illustrations of some parts to show the inside of the electronic component 700. The electronic component 700 includes a land 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected to each other on the printed circuit board 702, whereby the mounting board 704 is completed.

The semiconductor device 710 includes a driver circuit layer 715 and a storage layer 716. Note that the storage layer 716 has a structure in which a plurality of memory cell arrays are stacked. Note that the storage layer 716 may have a structure in which one layer including a memory cell array is provided. A stacked-layer structure of the driver circuit layer 715 and the storage layer 716 can be a monolithic stacked-layer structure. In the monolithic stacked-layer structure, layers can be connected to each other without using a through electrode technique such as a TSV (Through Silicon Via) and a bonding technique such as Cu-to-Cu direct bonding. The monolithic stacked-layer structure of the driver circuit layer 715 and the storage layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the storage layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to a period of time from access to start of data transmission. In the case where the storage layer 716 is formed using Si transistors, it is difficult to obtain the monolithic stacked-layer structure as compared with the case where the storage layer 716 is formed using OS transistors. Thus, the OS transistor is superior to the Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

Next, FIG. 34B illustrates a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, a TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the heights of the semiconductor device 710 and the semiconductor device 735 are preferably equal to each other, for example.

An electrode 733 may be provided on the bottom portion of the package substrate 732 to mount the electronic component 730 on another substrate. FIG. 34B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Appliance]

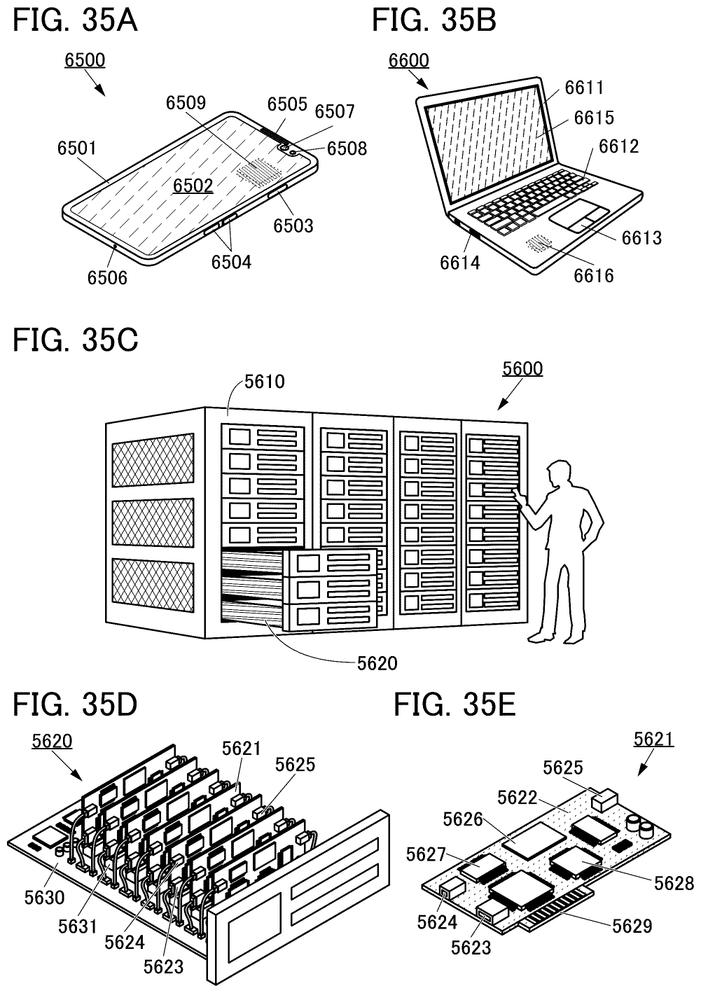

Next, FIG. 35A illustrates a perspective view of an electronic appliance 6500. The electronic appliance 6500 illustrated in FIG. 35A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a storage device are included. The semiconductor device of one embodiment of the present invention can be used for the display portion 6502, the control device 6509, and the like.

An electronic appliance 6600 illustrated in FIG. 35B is an information terminal that can be used as a laptop computer. The electronic appliance 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a storage device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 35C illustrates a perspective view of a large computer 5600. In the large computer 5600 illustrated in FIG. 35C, a plurality of rack mount computers 5620 are stored in a rack 5610. Note that the large computer 5600 may be referred to as a supercomputer.

The computer 5620 can have a structure in a perspective view illustrated in FIG. 35D, for example. In FIG. 35D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 35E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 35E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark) or the like.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used for a device for space, such as devices processing and storing information.

The semiconductor device of one embodiment of the present invention can include an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

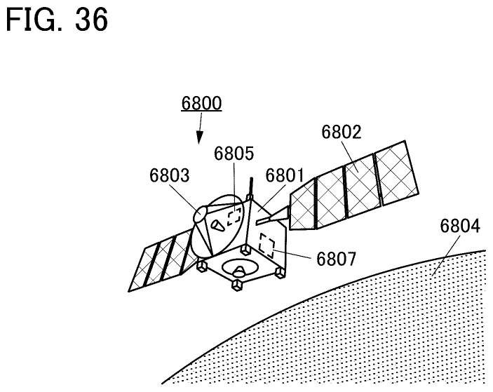

FIG. 36 illustrates an artificial satellite 6800 as an example of a device for space. The artificial satellite 6800 includes a body 6801, a solar panel 6802, an antenna 6803, a secondary battery 6805, and a control device 6807. Note that FIG. 36 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 36, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device including the OS transistor, which is one embodiment of the present invention, is suitably used for the control device 6807. A change in electrical characteristics due to exposure to radiation is smaller in the OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

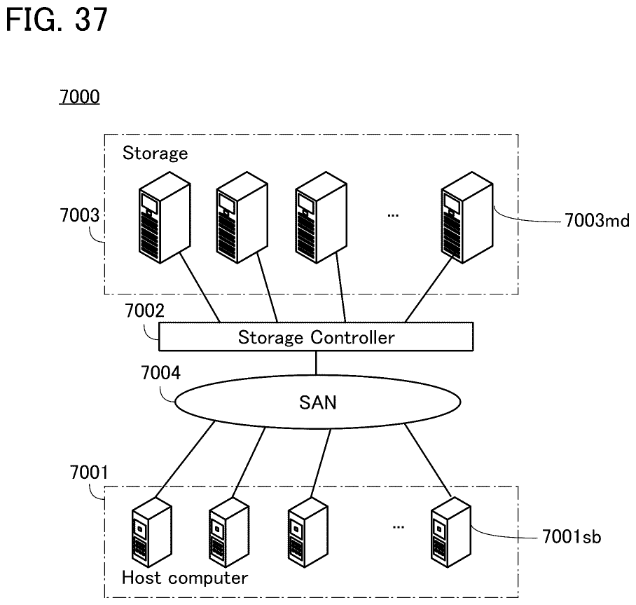

FIG. 37 illustrates a storage system that can be used in a data center. A storage system 7000 illustrated in FIG. 37 includes a plurality of servers 7001sb as a host 7001 (indicated as “Host Computer” in the diagram). The storage system 7000 includes a plurality of storage devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer which accesses data stored in the storage 7003. The host 7001 may be connected to another host 7001 through a network.

The data access speed, i.e., the time taken for storing and outputting data, of the storage 7003 is shortened by using a flash memory, but is still considerably longer than the time required for a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic appliance, a large computer, a device for space, and a data center can be expected to produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configuration, structure, method, or the like described in this embodiment can be used in an appropriate combination with the configuration, structure, method, or the like described in the other embodiments and the like.

### Example 1

In this example, hafnium zirconium oxide (HfZrO_{X}) was fabricated as an insulator exhibiting ferroelectricity, and evaluation results of the crystallinity of the insulator and measurement results of the voltage-polarization characteristics, the endurance characteristics, and the like of the insulator are described. In this example, a memory cell including a ferroelectric capacitor was fabricated, and measurement results of the memory cell are described.

<Crystal structure of HfZrO_{X} Film>

In this section, HfZrO_{X} was evaluated. Specifically, a sample containing HfZrO_{X} was fabricated, and the crystal state was examined by a grazing incident X-ray diffraction (GIXRD) method, which is a kind of XRD analysis method.

A method for fabricating the sample used for GIXRD measurement is described below.

First, a 100-nm-thick silicon oxide film was formed on a silicon substrate by thermal oxidation treatment, and a 35-nm-thick first titanium nitride film was deposited over the silicon oxide film by a sputtering method. After the first titanium nitride film was deposited, CMP treatment was performed.

Next, the first titanium nitride film was processed to form an island-shaped first titanium nitride layer, and a HfZrO_{X} film with Hf:Zr=1:1 [atomic ratio] was deposited over the island-shaped first titanium nitride layer by an ALD method. Tetrakis(ethylmethylamide)zirconium (TEMAZr) and tetrakis(ethylmethylamide)hafnium (TEMAHf) were used as precursors, and ozone (O₃) was used as an oxidizer. The deposition temperature was set to 250° C. Note that the thickness of the HfZrO_{X} film was set to 10 nm.

Next, a 30-nm-thick second titanium nitride film was deposited over the HfZrO_{X} film by a sputtering method. After the second titanium nitride film was deposited, heat treatment was performed. The heat treatment was performed at 450° C. for one minute in a nitrogen atmosphere using an RTA (Rapid Thermal Anneal) apparatus.

Next, the second titanium nitride film was processed to form an island-shaped second titanium nitride layer.

Through the above steps, the sample used for GIXRD measurement was fabricated.

The sample was subjected to GIXRD measurement. The GIXRD measurement was performed using a multifunction thin film material evaluation X-ray diffractometer D8 DISCOVER Hybrid/TXS (produced by Bruker Corporation). Note that as measurement conditions in the case of using this apparatus, the X-ray output was set to 50 kV and 100 mA, the incident angle θ was set to 0.5°, and the scan range 2θ was set to 27° to 33°.

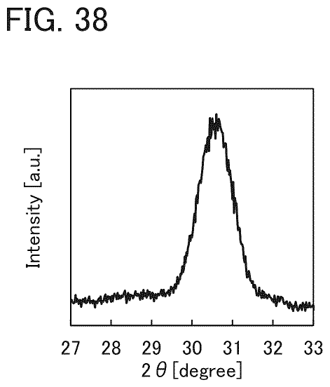

FIG. 38 shows a GIXRD measurement result. FIG. 38 shows the relationship between the X-ray diffraction angle (2θ) and the detected signal intensity. In FIG. 38, the vertical axis represents the intensity, and the horizontal axis represents the diffraction angle (2θ).

According to FIG. 38, a peak was observed around 2θ=30.4°. The peak is derived from an orthorhombic crystal exhibiting ferroelectricity, which indicates that the HfZrO_{X} film deposited by the above method exhibits ferroelectricity.

### <Size of Crystal Grain Included in Ferroelectric Layer>

In this section, the size of crystal grains included in a ferroelectric layer was evaluated.

In this section, two samples (Sample 700A and Sample 700B) were fabricated. The two samples differ in ferroelectric layer thickness.

First, a method for fabricating the samples is described.

First, a 100-nm-thick silicon oxide film was formed on a silicon substrate by thermal oxidation treatment, a 60-nm-thick silicon nitride film was deposited over the silicon oxide film by a sputtering method, and a 40-nm-thick aluminum oxide film was deposited over the silicon nitride film by a sputtering method.

Next, a 30-nm-thick tungsten film was deposited over the aluminum oxide film by a sputtering method, and a 10-nm-thick titanium nitride film was deposited over the tungsten film by a sputtering method. After the titanium nitride film was deposited, CMP treatment was performed.

Next, the stack of the tungsten film and the titanium nitride film was processed into an island shape, and a HfZrO_{X} film with Hf:Zr=1:1 [atomic ratio] was deposited over the island-shaped stack by an ALD method. Tris(dimethylamino)cyclopentadienyl zirconium (ZyALD (registered trademark)) and TEMAHf were used as precursors, and H₂O was used as an oxidizer. The deposition temperature was set to 250° C. Note that the thickness of the HfZrO_{X} film was set to 10 nm for Sample 700A and 20 nm for Sample 700B.

Through the above steps, the two samples were fabricated.

Each of the two fabricated samples was subjected to measurement of average surface roughness of the HfZrO_{X} film. Note that the average surface roughness was measured with an atomic force microscope (AFM). As the AFM, SPA-500 produced by SII Nano Technology Inc. was used. As measurement conditions, the scan rate was set to 1.0 Hz, and the measurement area was set to 1 μm×1 μm.

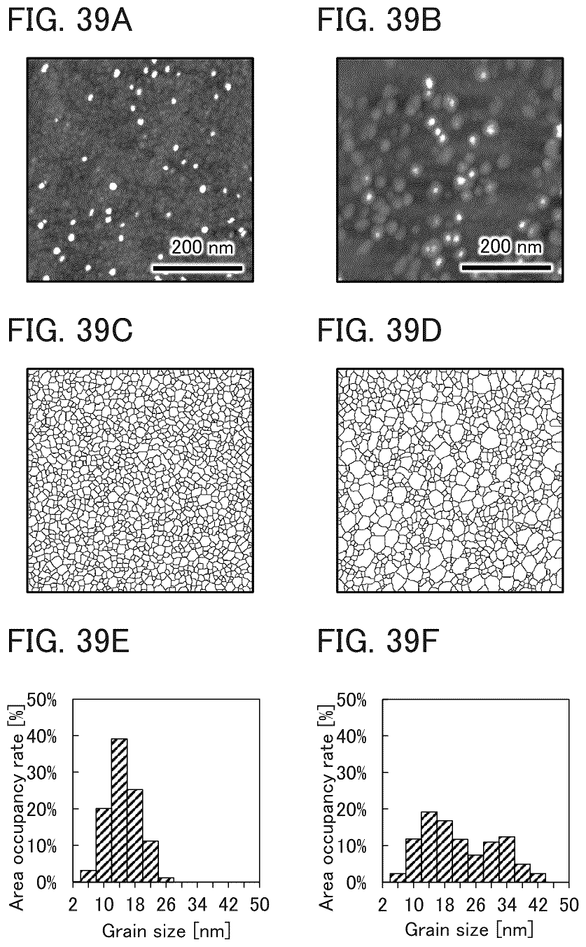

FIG. 39A and FIG. 39B show the results of surface observation using the AFM. FIG. 39A shows AFM data obtained by measurement of Sample 700A, and FIG. 39B shows AFM data obtained by measurement of Sample 700B.

Next, the AFM data obtained by the measurements was subjected to image analysis. Specifically, in the AFM data, grains were identified and separated using image analysis software that had undergone machine learning so as to detect grain boundaries, and images in which grains were separated were subjected to Voronoi analysis to generate data in which grain boundaries were constructed.

FIG. 39C and FIG. 39D show the results of image analysis. FIG. 39C shows data obtained by image analysis of the AFM data shown in FIG. 39A, and FIG. 39D shows data obtained by image analysis of the AFM data shown in FIG. 39B. That is, FIG. 39C shows data on Sample 700A, and FIG. 39D shows data on Sample 700B.

Next, grain size distribution was evaluated using the data shown in FIG. 39C and FIG. 39D. FIG. 39E and FIG. 39F show the results of grain size distribution evaluation.

FIG. 39E and FIG. 39F are diagrams each showing the area occupancy rate with respect to the grain size. In each of FIG. 39E and FIG. 39F, the vertical axis represents the area occupancy rate, and the horizontal axis represents the grain size. FIG. 39E shows the result of grain size distribution evaluation using the data shown in FIG. 39C, and FIG. 39F shows the result of grain size distribution evaluation using the data shown in FIG. 39D. That is, FIG. 39E shows the result of Sample 700A, and FIG. 39F shows the result of Sample 700B.

According to FIG. 39A to FIG. 39F, the tendency of increasing variation in grain size with increasing thickness of the HfZrO_{X} film was observed. A large variation in grain size might affect variation in characteristics. Thus, the thickness of the HfZrO_{X} film is preferably less than or equal to 15 nm, further preferably less than or equal to 12 nm.

### [Sample Fabrication]

Samples used for measuring the voltage-polarization characteristics, endurance characteristics, and the like of insulators are described below. First, four samples (Sample 800A to Sample 800D) were fabricated. Sample 800A to Sample 800D each include a capacitor. Note that FIG. 25B can be referred to for a cross-sectional view of the capacitor included in each of Sample 800A to Sample 800D. Sample 800A to Sample 800D differ in capacitor's dielectric thickness.

A method for fabricating the four samples is described below. Note that Sample 800A to Sample 800D have the same structure except for the difference in dielectric thickness.

The conductor 110 was formed using a titanium nitride film deposited by a CVD method.

The insulator 130 functioning as the dielectric of the capacitor was formed using a HfZrO_{X} film with Hf:Zr=1:1 [atomic ratio] deposited by an ALD method. TEMAZr and TEMAHf were used as precursors, and ozone (O₃) was used as an oxidizer. The deposition temperature was set to 250° C. Note that the thickness of the insulator 130 was set to 6 nm for Sample 800A, 8 nm for Sample 800B, 10 nm for Sample 800C, and 12 nm for Sample 800D.

The conductor 120 was formed using a tantalum nitride film deposited by a sputtering method.

After the conductor 120 was formed, heat treatment was performed at 450° C. for 60 seconds using an RTA apparatus.

Through the above steps, Sample 800A to Sample 800D each including the capacitor were fabricated. Note that 1024 capacitors each having a design area of 0.016 μm² are connected in parallel in each sample. Thus, the total area of the capacitors is 16.384 μm². The area of the capacitor can be rephrased as the area where the two electrodes of the capacitor overlap with each other.

In addition, three samples (Sample 801C, Sample 802C, and Sample 803C) were fabricated. The three samples each include a capacitor. Note that FIG. 25B can be referred to for a cross-sectional view of the capacitor included in each of Sample 801C to Sample 803C. Sample 801C to Sample 803C are the same as Sample 800C except for a difference in capacitor area. Thus, the above-described structure of Sample 800C can be referred to for the structures of Sample 801C to Sample 803C except for the area of the capacitor. The above-described method for fabricating Sample 800C can be referred to for a method for fabricating Sample 801C to Sample 803C.

Sample 801C includes one capacitor having a design area of 94.97 μm². In Sample 802C, 1024 capacitors each having a design area of 0.06 μm² are connected in parallel. Thus, the total area of the capacitors in Sample 802C is 61.44 μm². Sample 803C includes one capacitor having a design area of 10 μm².

### <P-E Characteristics>

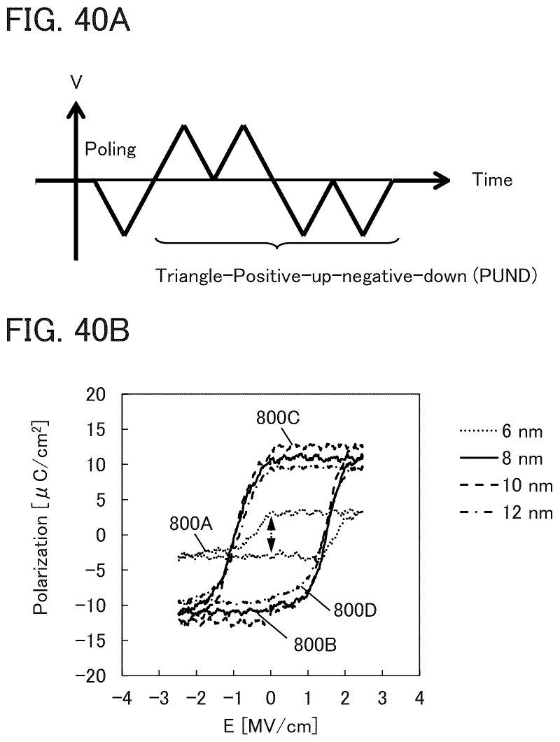

A triangular wave was applied between the conductor 120 and the conductor 110, and a change in spontaneous polarization (P-E characteristics) of the insulator 130 was measured. FIG. 40A shows an input voltage waveform. As shown in FIG. 40A, the P-E characteristics were evaluated by a triangular wave double pulse method. Note that the triangular wave double pulse method is a method in which two positive triangular wave pulses are applied, then two negative triangular wave pulses are applied, and the corresponding response charges are measured. The triangular wave to be applied had a frequency of 1 kHz and an electric field intensity fixed at 2.5 MV/cm. Note that the frequency of the triangular wave to be applied is referred to as a measurement frequency in some cases. Before the positive triangular wave pulses are applied, a negative triangular wave pulse (“Poling” in FIG. 40A) is applied. In this specification and the like, the triangular wave double pulse method is referred to as a Triangle-PUND (Positive-up-negative-down) method in some cases.

As described above, the thickness of the insulator 130 differs between the samples. Thus, the voltage of the triangular wave pulses was varied between the samples to fix the electric field intensity at 2.5 MV/cm. Specifically, the voltage was set to 1.5 V for Sample 800A, 2.0 V for Sample 800B, 2.5 V for Sample 800C, and 3.0 V for Sample 800D.

FIG. 40B shows the results. In FIG. 40B, the vertical axis represents the remanent polarization amount per unit area (“Polarization”), and the horizontal axis represents the electric field intensity E. Note that the remanent polarization amount per unit area is hereinafter simply referred to as polarization in some cases.

In FIG. 40B, a P-E curve indicated by the dotted line is the result of Sample 800A, a P-E curve indicated by the solid line is the result of Sample 800B, a P-E curve indicated by the dashed line is the result of Sample 800C, and a P-E curve indicated by the dashed-dotted line is the result of Sample 800D. Note that the double-headed arrow in FIG. 40B indicates a difference 2Pr between the minimum polarization and the maximum polarization at an electric field intensity E of 0 MV/cm.

According to FIG. 40B, all the samples exhibited hysteresis characteristics. Although Sample 800A showed small 2Pr, Sample 800B to Sample 800D each showed large 2Pr. That is, 2Pr was large when the thickness of the insulator 130 was greater than or equal to 8 nm. Sample 800C showed the largest 2Pr.

The P-E characteristics of Sample 801C and Sample 802C were also measured by the above-described method. For Sample 801C and Sample 802C, the voltage was set to 2.5 V to fix the electric field intensity at 2.5 MV/cm. That is, since the voltage is the same for Sample 800C to Sample 802C, the P-E characteristics can be rephrased as the P-V characteristics in the case of comparing Sample 800C to Sample 802C.

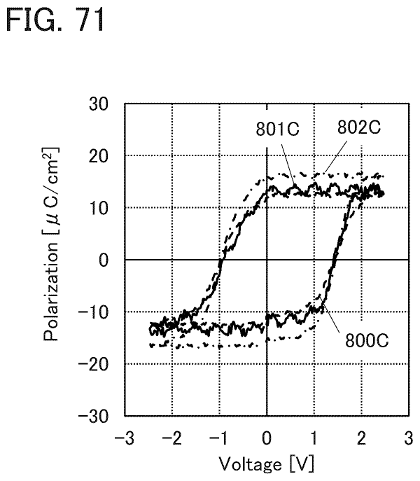

FIG. 71 shows the measurement results of the P-V characteristics. In FIG. 71, the vertical axis represents the remanent polarization amount per unit area (“Polarization”), and the horizontal axis represents the voltage (“Voltage”). The solid line in FIG. 71 represents the P-V curve of Sample 801C, the dashed-dotted line in FIG. 71 represents the P-V curve of Sample 802C, and the dashed line in FIG. 71 represents the P-V curve of Sample 800C.

According to FIG. 71, all the samples exhibited hysteresis characteristics regardless of the area of the capacitor. This reveals that the capacitor can be miniaturized while maintaining its ferroelectricity.

### <Endurance Characteristics>

The measurement results of endurance characteristics of Sample 800A to Sample 800D described above are described below.

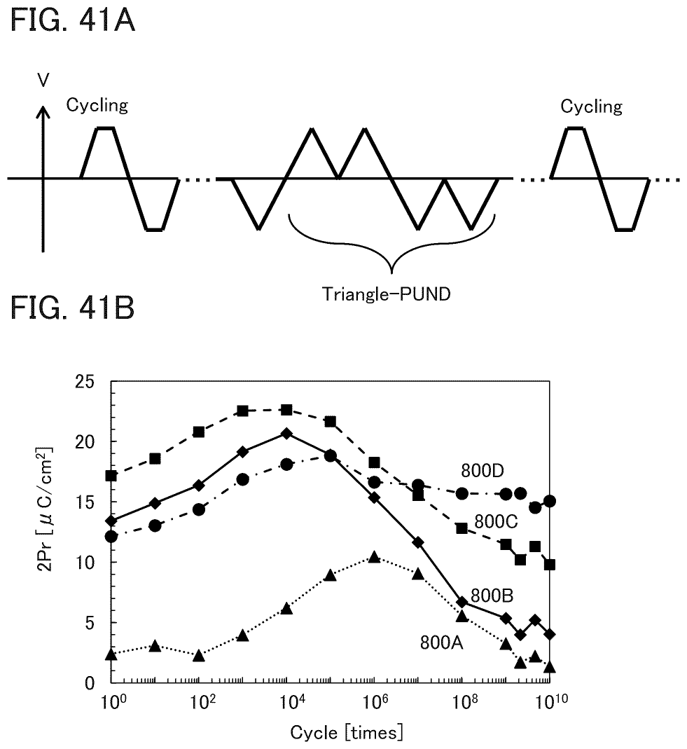

FIG. 41A shows an input voltage waveform. As shown in FIG. 41A, for the measurement of the endurance characteristics, a trapezoidal wave was repeatedly applied (“Cycling”) until the number of cycles reached a predetermined number assuming application of the trapezoidal wave for one period to be one cycle; the P-E characteristics were measured by the above-described triangular wave double pulse method after every predetermined number of cycles; and the difference 2Pr between the minimum polarization and the maximum polarization at an electric field intensity E of 0 was obtained. The trapezoidal wave to be applied had a frequency of 100 kHz and an electric field intensity fixed at 2.5 MV/cm. Note that the frequency of the trapezoidal wave to be applied is referred to as an endurance frequency in some cases. To fix the electric field intensity, the voltage was set to 1.5 V for Sample 800A, 2.0 V for Sample 800B, 2.5 V for Sample 800C, and 3.0 V for Sample 800D.

FIG. 41B shows the measurement results of the endurance characteristics of Sample 800A to Sample 800D. Note that in FIG. 41B, the vertical axis represents the difference 2Pr between the minimum polarization and the maximum polarization at the electric field intensity E of 0 MV/cm, and the horizontal axis represents the number of cycles (“Cycle”). In FIG. 41B, a plot indicated by triangles is the result of Sample 800A, a plot indicated by rhombuses is the result of Sample 800B, a plot indicated by squares is the result of Sample 800C, and a plot indicated by circles is the result of Sample 800D.

According to FIG. 41B, dielectric breakdown did not occur in each sample until the number of cycles reached 1×10¹⁰. That is, dielectric breakdown did not occur even when the thickness of the HfZrO_{X} film was as small as 6 nm. At the time of 1×10¹⁰ cycles, Sample 800D showed the largest 2Pr, Sample 800C showed the second largest 2Pr, Sample 800B showed the third largest 2Pr, and Sample 800A showed the smallest 2Pr. That is, 2Pr increased as the thickness of the insulator 130 increased.

According to FIG. 41B, wakeup and fatigue were observed with each sample depending on the number of cycles. Note that wakeup refers to a stage in which the amount of polarization charge increases or the absolute value of 2Pr increases, and fatigue refers to a stage in which the amount of polarization charge decreases or the absolute value of 2Pr decreases. With respect to initial 2Pr, 2Pr after 1×10¹⁰ cycles was approximately 40% for Sample 800B and approximately 60% for Sample 800C. Also in consideration of the results described above in <Size of crystal grain included in ferroelectric layer>, the thickness of the HfZrO_{X} film is preferably greater than or equal to 5 nm and less than or equal to 15 nm, further preferably greater than or equal to 8 nm and less than or equal to 12 nm, typically 10 nm.

The endurance characteristics of Sample 801C and Sample 802C were also measured by the above-described method.

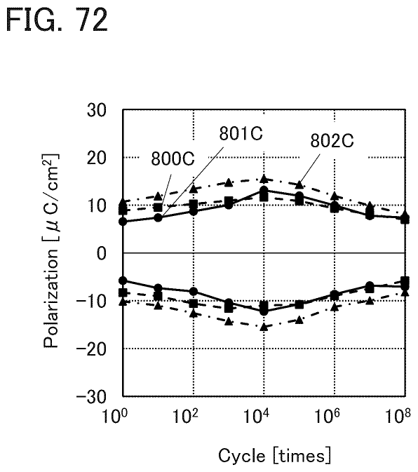

FIG. 72 shows the measurement results of the endurance characteristics. In FIG. 72, the vertical axis represents the polarization per unit area at the electric field intensity E of 0 MV/cm (“Polarization”), and the horizontal axis represents the number of cycles (“Cycle”). The solid line in FIG. 72 represents the result of Sample 801C, the dashed-dotted line in FIG. 72 represents the result of Sample 802C, and the dashed line in FIG. 72 represents the result of Sample 800C.

According to FIG. 72, dielectric breakdown did not occur in each sample until the number of cycles reached 1×10⁸, regardless of the area of the capacitor.

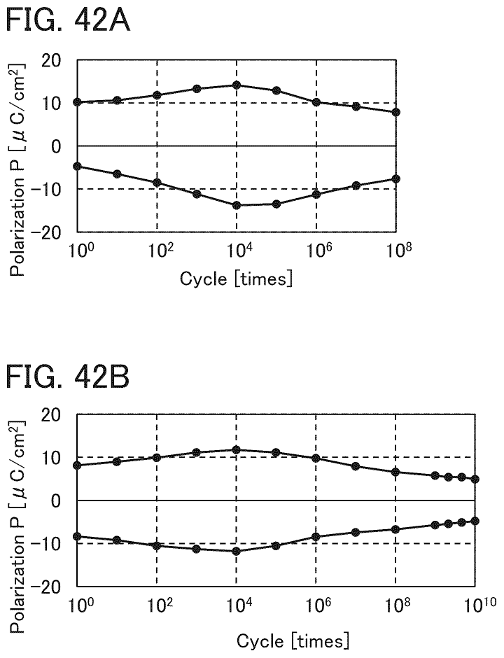

FIG. 42A and FIG. 42B show the measurement results of the endurance characteristics of Sample 803C and Sample 800C, respectively. In each of FIG. 42A and FIG. 42B, the vertical axis represents the polarization P per unit area at the electric field intensity E of 0 MV/cm, and the horizontal axis represents the number of cycles. According to FIG. 42A, dielectric breakdown did not occur in Sample 803C until the number of cycles reached 1×10⁸. According to FIG. 42B, dielectric breakdown did not occur in Sample 800C until the number of cycles reached 1×10¹⁰, as described above.

### <Retention Measurement>

The results of retention measurement performed on Sample 800C describe above are described below.

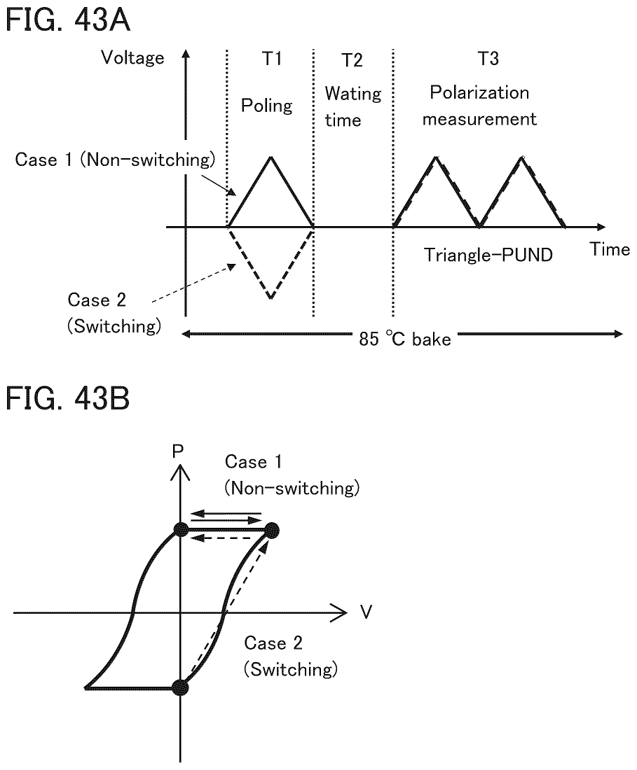

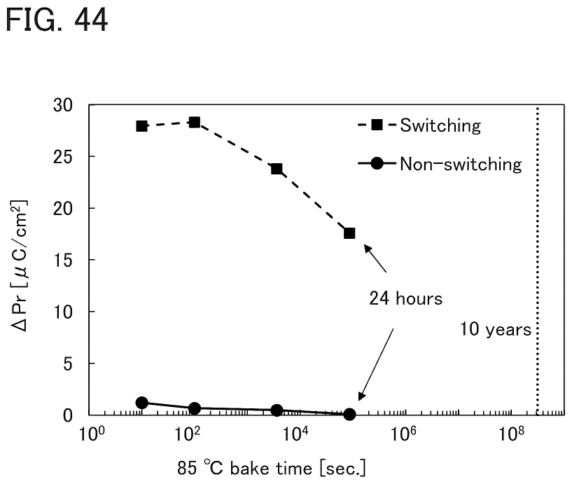

FIG. 43A shows the operation sequence of the retention measurement. FIG. 43B shows a diagram of assumed change in polarization. FIG. 44 shows the results of the retention measurement.

For the retention measurement, a ferroelectric property evaluation system “FCE10-F” produced by TOYO Corporation was used. In this example, a prober provided with a stage having a temperature adjustment function was used to perform the retention measurement under a plurality of temperature conditions.

In the retention measurement, a potential is supplied to a sample using a pulse generator and a current flowing at that time is measured. The operation sequence of the retention measurement shown in FIG. 43A is described below. Note that the retention measurement was performed under two conditions.

The first condition (Case 1) is described here. In Period T1, a positive triangular wave pulse is applied to the sample to bring the HfZrO_{X} film into a polarization state on the positive potential side (“Poling”). Next, in Period T2, the potential is retained at 0 V (“Wating time”). Next, in Period T3, P-E characteristics were measured by the above-described triangular wave double pulse method, and the difference between the minimum polarization and the maximum polarization at the electric field intensity E of 0 MV/cm was obtained (“Polarization measurement”).

Next, the second condition (Case 2) is described. In Period T1, a negative triangular wave pulse is applied to the sample to bring the HfZrO_{X} film into a polarization state on the negative potential side. A method for applying the voltage after Period T2 is the same as that in the above-described first condition.

The above-described first condition (Case 1) does not involve polarization reversal (“Non-Switching”). On the other hand, the above-described second condition (Case 2) involves polarization reversal (“Switching”). Since the retention measurement performed here does not involve polarization reversal in some cases, the difference between the minimum polarization and the maximum polarization at the electric field intensity E of 0 is expressed as ΔPr.

FIG. 44 shows the results of the retention measurement performed on Sample 800C.

The temperature condition was set to 85° C. In FIG. 44, the vertical axis represents ΔPr, and the horizontal axis represents the retention time at 85° C. (“85° C. bake time”). In FIG. 44, a plot indicated by circles is the result of the first condition (“Non-Switching”), and a plot indicated by squares is the result of the second condition (“Switching”). By thus graphing the value of ΔPr obtained by measurement data analysis and the length of the retention time of Period T2, the length of a period in which polarization can be retained can be known. Note that the dotted line in FIG. 44 indicates 10 years.

According to FIG. 44, no degradation was observed in 100 seconds in the case of involving polarization reversal. ΔPr after 24 hours was greater than or equal to 15 μC/cm², although it was decreased by 37%. On the other hand, polarization was hardly observed in the case of not involving polarization reversal.

### <Dielectric Breakdown>

A sample having a structure similar to that of Sample 800C was fabricated, and its I-V characteristics were measured.

The sample fabricated in this section is different from Sample 800C in that the conductor 120 is a stack of titanium nitride and tungsten over the titanium nitride. The titanium nitride which is the lower layer of the conductor 120 was formed using a 10-nm-thick titanium nitride film deposited by a sputtering method. The tungsten which is the upper layer of the conductor 120 was formed using a 20-nm-thick tungsten film deposited by a sputtering method.

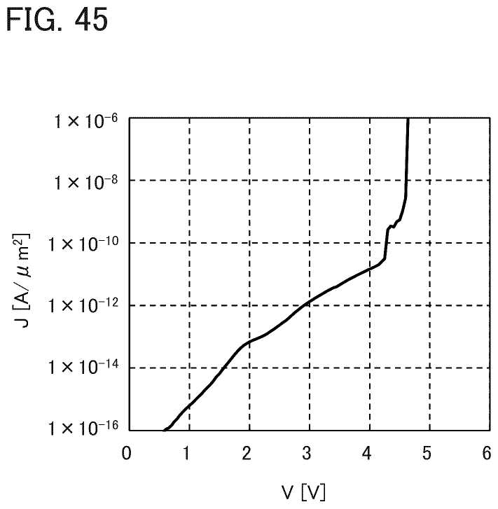

The above sample was used for measurement of J-V characteristics. FIG. 45 shows the results. In FIG. 45, the vertical axis represents the current density J [A/μm²], and the horizontal axis represents the voltage V [V].

FIG. 45 reveals that a high breakdown voltage (an increase in breakdown voltage) can be achieved when the capacitor has the structure illustrated in FIG. 24B.

The above is the evaluation results of the insulator exhibiting ferroelectricity.

### <Drain Breakdown Voltage Test on OS Transistor>

Next, transistors whose channel formation regions contain an oxide semiconductor (referred to as OS transistors) were fabricated and evaluated assuming high voltage driving. Note that the OS transistors fabricated in this example correspond to the OS transistor illustrated in FIG. 17A and FIG. 17B. Thus, the description in the above embodiment can be referred to for the structure and the like of the OS transistors fabricated in this example.

Note that OS transistors (Sample 820A to Sample 820D) having different design values of the channel length (L) and the channel width (W) were prepared in this section. Specifically, an OS transistor with L/W=20 nm/20 nm is referred to as Sample 820A, an OS transistor with L/W=30 nm/30 nm is referred to as Sample 820B, an OS transistor with L/W=40 nm/40 nm is referred to as Sample 820C, and an OS transistor with L/W=60 nm/60 nm is referred to as Sample 820D. Note that the above values of L and W represent design values.

In each of Sample 820A to Sample 820D, the EOT of the first gate insulator is 2.8 nm.

A transistor whose channel formation region contains silicon (referred to as a Si transistor) was prepared as a comparative example. In this section, an n-channel Si transistor was fabricated. The n-channel Si transistor is hereinafter referred to as Sample 820E. Note that Sample 820E has an EOT of 2.6 nm and L/W of 60 nm/120 nm.

Sample 820A to Sample 820E were fabricated, and Sample 820A to Sample 820E were each subjected to a drain breakdown voltage test.

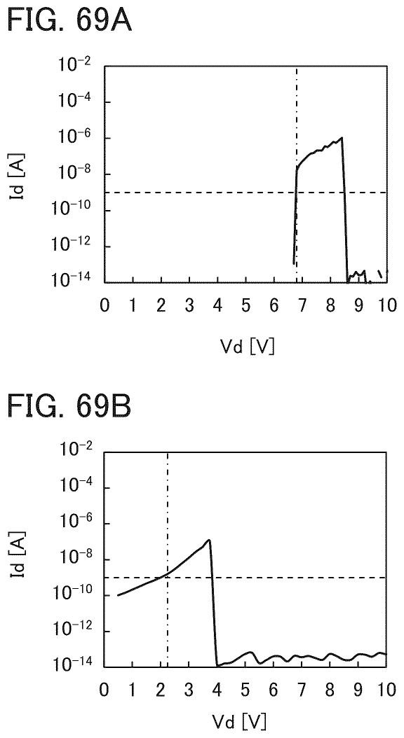

In the drain breakdown voltage test, the gate voltage (Vg) was set to 0 V, and the source voltage (Vs) and the back gate voltage (Vbg) were set to 0 V. The drain current (Id) was measured while the drain voltage (Vd) was increased from 0 V. When the drain current (Id) exceeds 1 nA, the transistor is defined as being broken, and Vd at that time is regarded as the drain breakdown voltage. The dashed line in each of FIG. 69A and FIG. 69B indicates Id=1 nA. Note that the maximum voltage of Vd was +10 V. The temperature at the time of measurement was room temperature.

FIG. 69A shows the result of the drain breakdown voltage test on Sample 820D, and FIG. 69B shows the result of the drain breakdown voltage test on Sample 820E. In each of FIG. 69A and FIG. 69B, the vertical axis represents the drain current (Id) [A], and the horizontal axis represents the drain voltage (Vd) [V]. FIG. 69A is a graph of the Id-Vd characteristics of Sample 820D, and FIG. 69B is a graph of the Id-Vd characteristics of Sample 820E.

The dashed-dotted line in FIG. 69A indicates that the drain breakdown voltage of Sample 820D is 6.8 V. The dashed-dotted line in FIG. 69B indicates that the drain breakdown voltage of Sample 820E is 2.25 V. This reveals that the OS transistor has a higher drain breakdown voltage than the Si transistor.

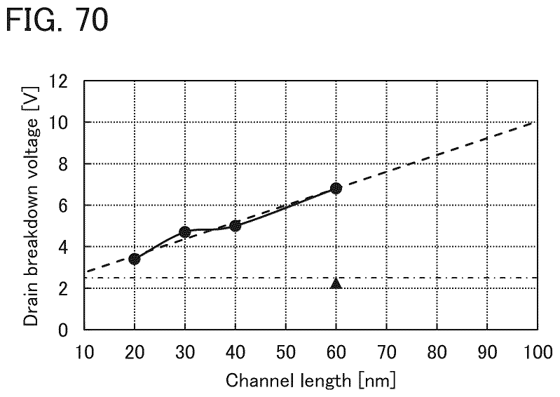

FIG. 70 shows the results of the drain breakdown voltage test on Sample 820A to Sample 820E. In FIG. 70, the vertical axis represents the drain breakdown voltage [V], and the horizontal axis represents the channel length [nm]. A plot indicated by circles in FIG. 70 represents the results of the drain breakdown voltage test on Sample 820A to Sample 820D, and a plot indicated by a triangle in FIG. 70 represents the result of the drain breakdown voltage test on Sample 820E. In FIG. 70, the dashed line represents the linear approximate line of the drain breakdown voltages of Sample 820A to Sample 820D.

FIG. 70 reveals that the OS transistor with the channel length of 20 nm has a higher drain breakdown voltage than the Si transistor with the channel length of 60 nm. It also suggests that the OS transistor has a sufficient drain breakdown voltage also when having a channel length shorter than 20 nm assuming that the driving voltage is 2.5 V (the dashed-dotted line in FIG. 70).

Accordingly, OS transistors can withstand a high driving voltage, and can be miniaturized as compared with Si transistors. Furthermore, since the off-state current of OS transistors is lower than the off-state current of Si transistors, OS transistors are suitably used as selector elements of the storage device.

Next, four samples (Sample 810A to Sample 810D) each having an element structure of 1Tr1C (one transistor and one capacitor) were fabricated, and their electrical characteristics were measured. Note that a description common to Sample 810A to Sample 810D is sometimes made as a description of Sample 810.

### <Sample Structure>

The transistor included in Sample 810 has the structure illustrated in FIG. 17A and FIG. 17B. That is, Sample 810 includes an OS transistor. The transistor of Sample 810 was designed aiming at a channel length of 60 nm and a channel width of 60 nm.

The capacitor included in Sample 810 has the structure of the capacitor included in Sample 800C described above. That is, Sample 810 includes a ferroelectric capacitor. Note that Sample 810A to Sample 810D differ in capacitor's area. The area of the capacitor was set to 0.016 μm² for Sample 810A, 0.06 μm² for Sample 810B, 0.11 μm² for Sample 810C, and 0.58 μm² for Sample 810D.

Note that the OS transistor and the ferroelectric capacitor can be fabricated in the BEOL of Si.

### <Cross-Sectional STEM>

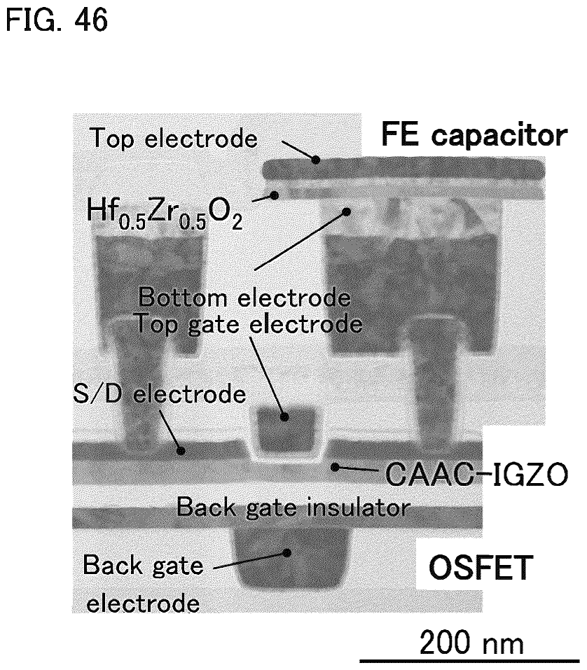

Cross-sectional STEM images of the fabricated samples were taken with “HD-2700” produced by Hitachi High-Tech Corporation. FIG. 46 shows a cross-sectional STEM image in the channel length direction of the transistor included in the sample. Note that the sample shown in FIG. 46 is equivalent to Sample 810 except that the conductor 120 included in the capacitor has a stacked-layer structure of two layers.

As shown in FIG. 46, Sample 810 includes a transistor (OSFET) and a capacitor (FE capacitor) over the transistor. Note that “Back gate electrode” in FIG. 46 corresponds to the conductor 205, “Back gate insulator” to the second stack, “CAAC-IGZO” to the oxide 230b, “Top gate electrode” to the conductor 260, and “S/D electrode” to the conductor 242a or the conductor 242b. Furthermore, “Bottom electrode” corresponds to the conductor 110, “Hf_{0.5}Zr_{0.5}O₂” to the insulator 130, and “Top electrode” to the conductor 120.

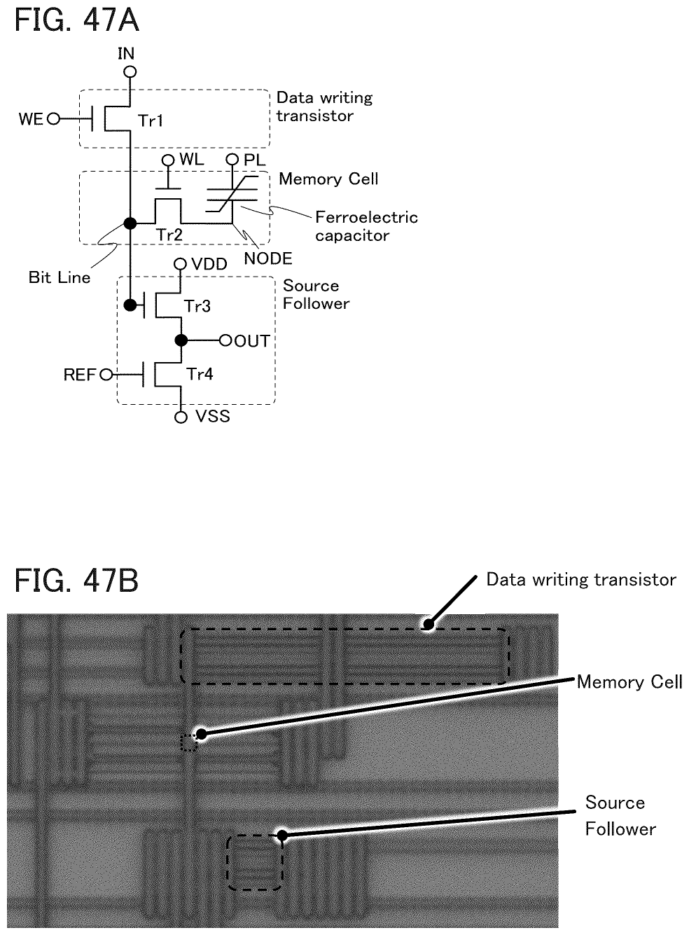

Sample 810 includes a 1Tr1C memory cell circuit. FIG. 47A illustrates a circuit diagram of the memory cell circuit included in Sample 810, and FIG. 47B shows a plan-view optical micrograph. The memory cell circuit includes a data writing transistor, a 1Tr1C memory cell, and a data reading source follower. Note that all the transistors included in the memory cell circuit are OS transistors. The capacitor included in the memory cell is a ferroelectric capacitor. The data writing transistor is hereinafter referred to as a transistor Tr1, the transistor included in the memory cell as a transistor Tr2, and the two transistors included in the source follower as a transistor Tr3 and a transistor Tr4.

A gate of the transistor Tr1 is electrically connected to a wiring WE, one of a source and a drain of the transistor Tr1 is electrically connected to a terminal IN, and the other of the source and the drain of the transistor Tr1 is electrically connected to a bit line. A gate of the transistor Tr2 is electrically connected to a wiring WL, one of a source and a drain of the transistor Tr2 is electrically connected to one of a pair of electrodes of the capacitor, and the other of the source and the drain of the transistor Tr2 is electrically connected to the bit line. The other of the pair of electrodes of the capacitor is electrically connected to a wiring PL. A region where the one of the source and the drain of the transistor Tr2 and the one of the pair of electrodes of the capacitor are electrically connected to each other functions as a node.

A gate of the transistor Tr3 is electrically connected to the bit line, one of a source and a drain of the transistor Tr3 is electrically connected to a power supply line VDD, and the other of the source and the drain of the transistor Tr3 is electrically connected to a terminal OUT. A gate of the transistor Tr4 is electrically connected to a wiring REF, one of a source and a drain of the transistor Tr4 is electrically connected to a terminal OUT, and the other of the source and the drain of the transistor Tr4 is electrically connected to a power supply line VSS.

The wiring WE and the wiring WL are wirings functioning as a word line. The wiring PL has a function of controlling the polarization state of a layer including the ferroelectric, which is included in the capacitor, and is sometimes referred to as a polarization control line.

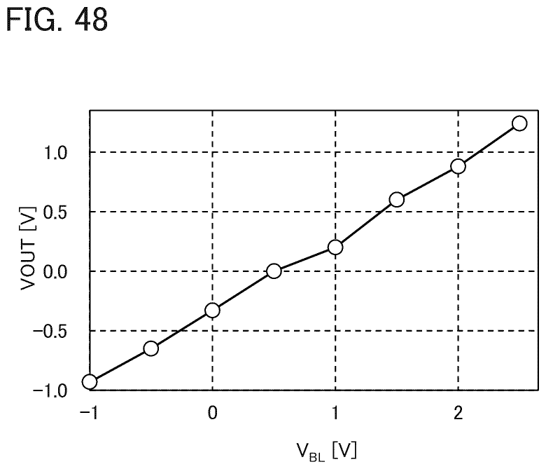

In order to evaluate the memory cell, the voltage V_{BL} of the bit line was evaluated through the source follower. Specifically, the characteristics of the source follower were measured. FIG. 48 shows the results. In FIG. 48, the vertical axis represents the voltage of the terminal OUT (“VOUT”), and the horizontal axis represents the voltage V_{BL} of the bit line.

FIG. 48 reveals that the voltage of the bit line can be observed using VOUT by measurement of the characteristics of the source follower before the evaluation of the memory cell.

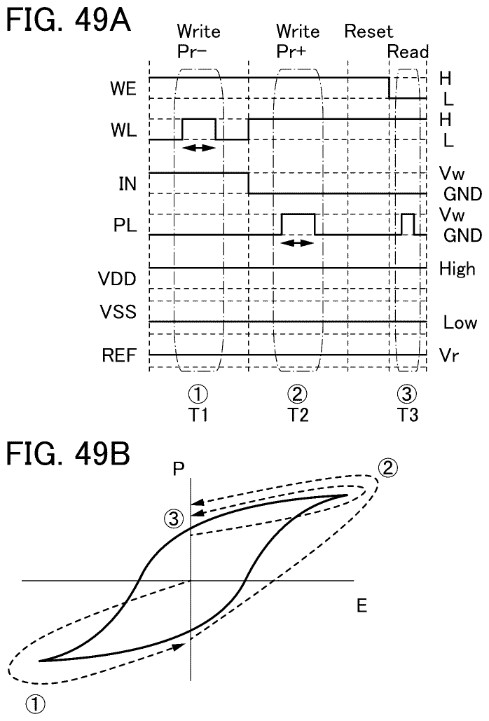

Next, a method for evaluating positive polarization writing and reading is described with reference to FIG. 49A and FIG. 49B.

In Period T1, a potential opposite to the polarization to be written is applied to perform initial writing (“Write Pr−”). Specifically, the potential of the terminal IN is set to Vw, and a positive potential (denoted as “H” in FIG. 49A]) is applied to the wiring WE and the wiring WL. Thus, the transistor Tr1 and the transistor Tr2 are turned on, and the potential of the terminal IN is supplied to the one of the pair of electrodes of the ferroelectric capacitor. Since the potential of the wiring PL is set to GND, polarization occurs between the pair of electrodes of the ferroelectric capacitor.

In this specification and the like, GND is set to a ground potential but is not necessarily the ground potential as long as the memory cell can be driven so as to achieve an object of one embodiment of the present invention. Note that Vw can be rephrased as an operation voltage.

Next, in Period T2, the potential of the polarization to be written is applied to perform writing (“Write Pr+”). Specifically, the potential of the terminal IN is set to GND, and the potential of the wiring PL is set to Vw. This leads to polarization opposite to the polarization generated in Period T1.

Then, in Period T3, a negative potential (denoted as “L” in FIG. 49A]) is applied to the wiring WE, whereby the transistor Tr1 is turned off. A negative potential (denoted as “L” in FIG. 49A) is applied to the wiring WE and the potential of the wiring PL is set to Vw to perform reading (“Read”). In the case where writing has been performed properly, polarization reversal does not occur, and a change in the voltage of the terminal OUT is small.

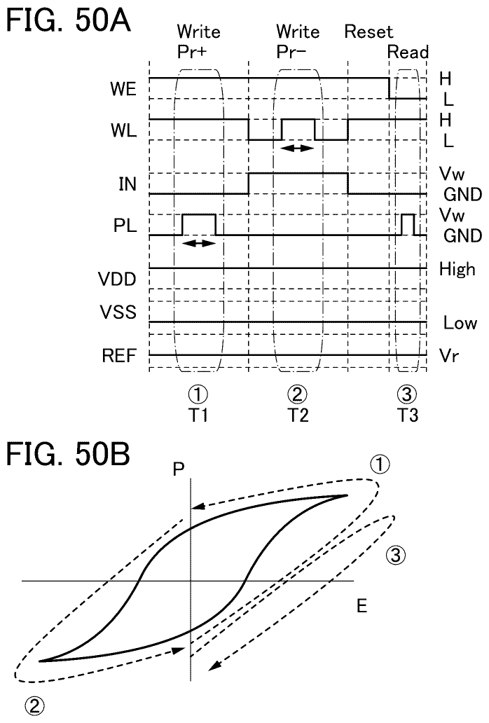

Next, a method for evaluating negative polarization writing and reading is described with reference to FIG. 50A and FIG. 50B.

In Period T1, a potential opposite to polarization to be written is applied to perform initial writing (“Write Pr+”). Specifically, the voltage of the terminal IN is set to GND, and a positive potential (denoted as “H” in FIG. 50A]) is applied to the wiring WE and the wiring WL. Thus, the transistor Tr1 and the transistor Tr2 are turned on, and the potential of the one of the pair of electrodes of the ferroelectric capacitor becomes GND. Since the potential of the wiring PL is set to Vw, a potential difference is generated between the pair of electrodes of the ferroelectric capacitor, leading to polarization.

Next, in Period T2, the potential of the polarization to be written is applied to perform writing (“Write Pr−”). Specifically, the potential of the terminal IN is set to Vw, and the potential of the wiring PL is set to GND. This leads to polarization opposite to the polarization generated in Period T1.

Then, in Period T3, the potential of the terminal IN is set to GND and then a negative potential (denoted as “L” in FIG. 50A) is applied to the wiring WE, whereby the transistor Tr1 is turned off. The potential of the wiring PL is set to Vw to perform reading (“Read”). In the case where writing has been performed properly, polarization reversal occurs, and a change in the voltage of the terminal OUT is large.

Note that in this example, the above-described positive potential was set to +3 V, the above-described negative potential to −3 V, the above-described Vw to +2.5 V, and the above-described GND to 0 V. The voltage “High” applied to the power supply line VDD was set to 2 V, the voltage “Low” applied to the power supply line VSS to −2 V, and the voltage Vr applied to the wiring REF to −1 V. In the method for evaluating positive polarization writing and reading (see FIG. 49A), the time for applying the positive potential to the wiring WL in Period T1 was set to 10 ms, the time for setting the potential of the wiring PL to Vw in Period T2 to 10 ms, and the time for setting the potential of the wiring PL to Vw in Period T3 to 1 μs.

Note that in each of the evaluation of positive polarization writing and reading and the evaluation of negative polarization writing and reading, a positive potential is applied to the wiring WL to turn on the transistor Tr2 and 0 V is applied to the bit line to set the potential of the node to 0 V (“Reset”) between Period T2 and Period T3. Thus, accurate memory evaluation can be performed in the reading operation in Period T3.

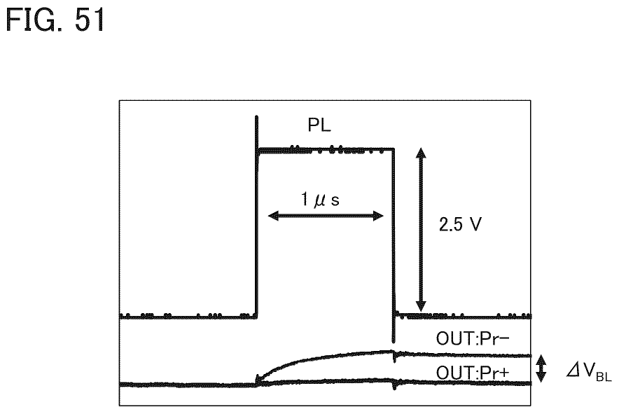

FIG. 51 shows the voltage waveforms of the wiring PL and the terminal OUT at the time of reading. In FIG. 51, the vertical direction represents the voltage, and the horizontal direction represents the time. The voltage waveform of the terminal OUT shown in FIG. 51 is the result of evaluation performed on Sample 810B. Note that the writing time was set to 100 ns, the reading time to 1 μs, and Vw to 2.5 V.

FIG. 51 reveals that the voltage of the terminal OUT (OUT:Pr−) at the time of reading in the evaluation of negative polarization writing shown in FIG. 50A and FIG. 50B is higher than the voltage of the terminal OUT (OUT:Pr+) at the time of reading in the evaluation of positive polarization writing shown in FIG. 49A and FIG. 49B. That is, it can be confirmed that positive polarization writing and negative polarization writing have been performed properly. Here, the difference between the voltage of the terminal OUT at the time of reading in the evaluation of negative polarization writing and the voltage of the terminal OUT at the time of reading in the evaluation of positive polarization writing is referred to as ΔV_{BL}.

Hereinafter, ΔV_{BL} is sometimes referred to as a potential window. In this example, the allowable minimum potential window is 0.1 V.

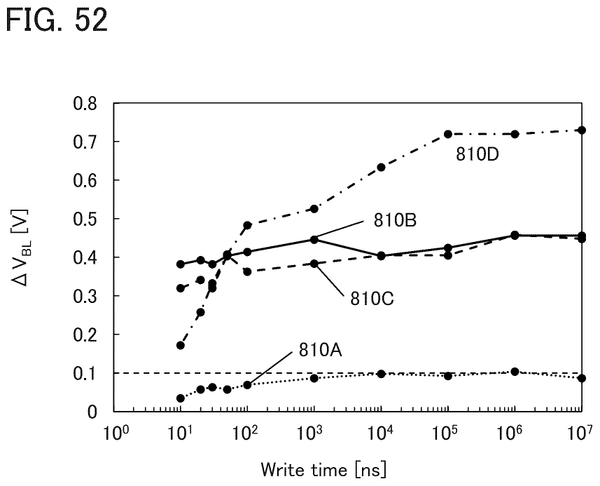

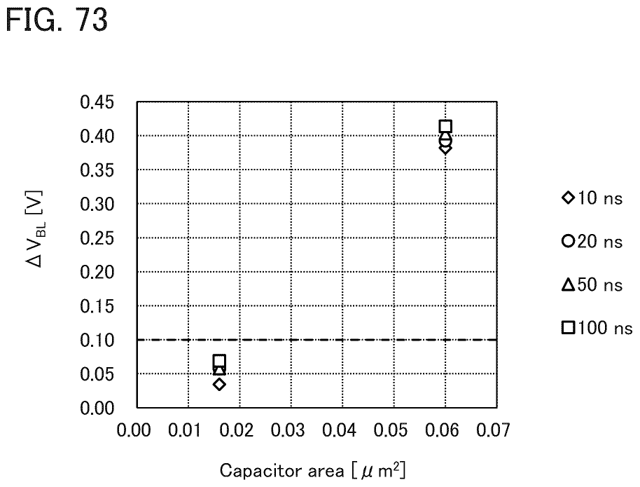

Next, changes in ΔV_{BL} of Sample 810A to Sample 810D with the writing time varying in the range of 10 ns to 10⁷ ns were evaluated. FIG. 52 and FIG. 73 show the results.

In FIG. 52, the vertical axis represents ΔV_{BL}, and the horizontal axis represents the writing time (“Write time”). In FIG. 52, a graph indicated by the dotted line is the result of Sample 810A, a graph indicated by the solid line is the result of Sample 810B, a graph indicated by the dashed line is the result of Sample 810C, and a graph indicated by the dashed-dotted line is the result of Sample 810D. The dashed line indicating ΔV_{BL}=0.1 V in FIG. 52 is the allowable minimum potential window.

According to FIG. 52, the tendency of decreasing ΔV_{BL} with decreasing writing time was observed. In the case where the writing time was short (e.g., approximately 10 ns), the amount of change in ΔV_{BL} decreased as the area of the capacitor decreased.

In the case where the writing time was 10 ns, ΔV_{BL} of Sample 810B in which the area of the capacitor was 0.06 μm² was larger than 0.1 V and larger than ΔV_{BL} of Sample 810D in which the area of the capacitor was 0.58 μm². This suggests that miniaturization of the ferroelectric capacitor enables high-speed device operation.

In FIG. 73, the vertical axis represents ΔV_{BL}, and the horizontal axis represents the area of the capacitor (“Capacitor area”). In FIG. 73, a plot indicated by rhombuses is the result of the case where the writing time was 10 ns, a plot indicated by circles is the result of the case where the writing time was 20 ns, a plot indicated by triangles is the result of the case where the writing time was 50 ns, and a plot indicated by squares is the result of the case where the writing time was 100 ns. In FIG. 73, the dashed line indicating ΔV_{BL}=0.1 V is the allowable minimum potential window. FIG. 73 shows the results of Sample 810A and Sample 810B.

According to FIG. 73, each of Sample 810A and Sample 810B showed a low writing time dependence of ΔV_{BL}. Sample 810B showed a ΔV_{BL} of approximately 0.4 V, which was relatively high. In contrast, Sample 810A showed a ΔV_{BL} smaller than 0.1 V. This confirms that writing is properly performed when the area of the capacitor is larger than 0.016 μm², especially larger than or equal to 0.06 μm², even in the case where the operating voltage is 2.5 V and the writing time is 10 ns.

Note that miniaturization of the ferroelectric capacitor in an actual memory is limited by wiring capacitance. Thus, a 3D capacitor structure allows an increase in capacitor area. Furthermore, the OSFET that can be fabricated in the BEOL can reduce wiring capacitance.

Next, a margin of reading was evaluated by varying the capacitor area and the bit line capacitance between samples. Specifically, the evaluation was performed by the methods described with reference to FIG. 49A to FIG. 50B with the operating voltage set to 2.5 V, the writing time to 100 ns, and the reading time to 1 μs.

Sample 810A to Sample 810D described above were used for the reading margin evaluation. Note that a memory cell circuit with a bit line capacitance of 2.758 fF, a memory cell circuit with a bit line capacitance of 8.582 fF, and a memory cell circuit with a bit line capacitance of 27.372 fF were prepared in each sample.

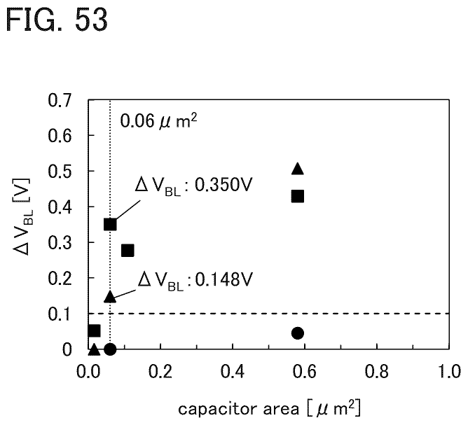

FIG. 53 shows the results. In FIG. 53, the vertical axis represents ΔV_{BL}, and the horizontal axis represents the area of the capacitor (“capacitor area”). In FIG. 53, a plot indicated by squares is the result of the memory cell circuit with the bit line capacitance of 2.758 fF, a plot indicated by triangles is the result of the memory cell circuit with the bit line capacitance of 8.582 fF, and a plot indicated by circles is the result of the memory cell circuit with the bit line capacitance of 27.372 fF. In FIG. 53, the dashed line indicating ΔV_{BL}=0.1 V is the allowable minimum potential window. The dotted line in FIG. 53 indicates a capacitor area of 0.06 μm².

According to FIG. 53, ΔV_{BL} was larger than 0.1 V when the area of the capacitor was greater than or equal to 0.06 μm² in the case where the bit line capacitance was 2.758 fF. Specifically, ΔV_{BL} was 0.350 V when the area of the capacitor was 0.06 μm².

In addition, ΔV_{BL} was larger than 0.1 V when the area of the capacitor was greater than or equal to 0.06 μm² in the case where the bit line capacitance was 8.582 fF. Specifically, ΔV_{BL} was 0.148 V when the area of the capacitor was 0.06 μm².

In addition, ΔV_{BL} was smaller than 0.1 V regardless of the area of the capacitor in the case where the bit line capacitance was 27.372 fF. Thus, sufficient writing was not confirmed in the case where the bit line capacitance was 27.372 fF.

The above results reveal that a balance between the capacitor area and the bit line capacitance is important in designing a memory cell including a ferroelectric capacitor (FeRAM).

### <Endurance Characteristics>

Next, the measurement results of endurance characteristics are described. The endurance characteristics were measured by the above-described method.

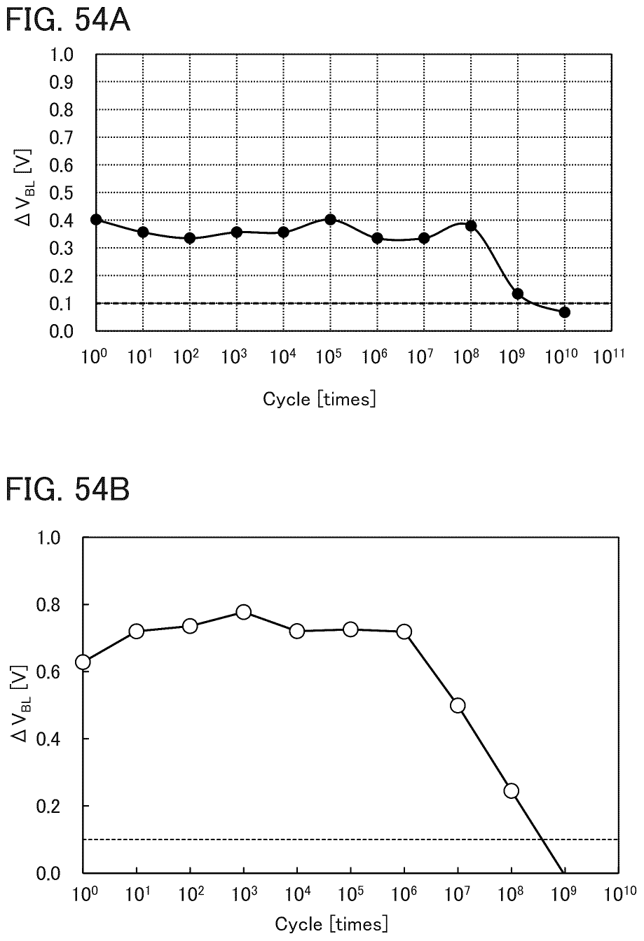

FIG. 54A and FIG. 54B show the measurement results of endurance characteristics of Sample 810B and Sample 810D. In each of FIG. 54A and FIG. 54B, the vertical axis represents ΔV_{BL}, and the horizontal axis represents the number of cycles (“Cycle”).

According to FIG. 54A, Sample 810B showed no significant change in the value of ΔV_{BL} until the number of cycles reached 1×10⁸. In addition, ΔV_{BL} was larger than 0.1 V and writing was confirmed until the number of cycles reached 1×10⁹.

According to FIG. 54B, ΔV_{BL} of Sample 810D was larger than 0.1 V and writing was confirmed until the number of cycles reached 1×10⁸.

### <Retention Measurement>

The results of a data retention test (retention measurement) performed on Sample 810B and Sample 810D described above are described below.

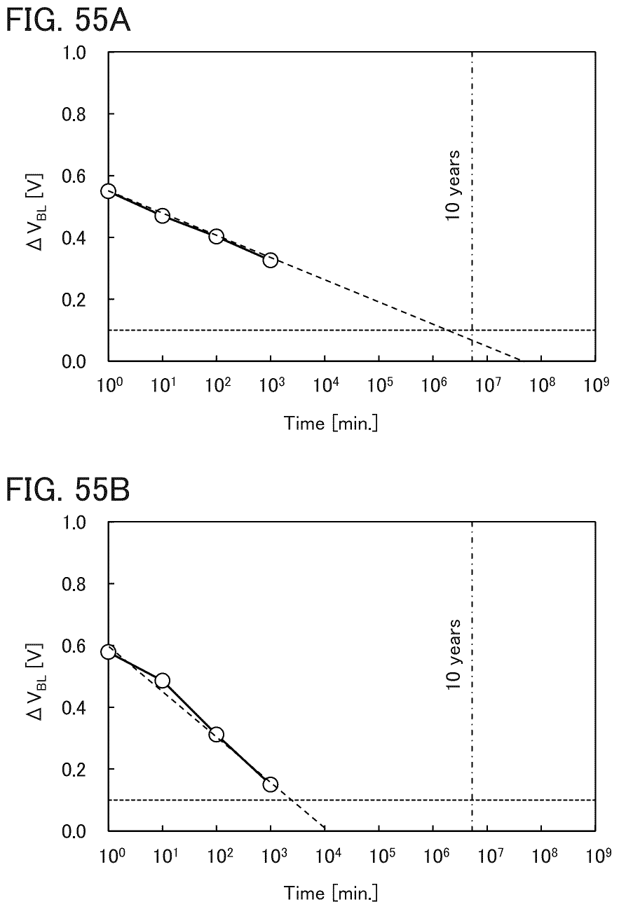

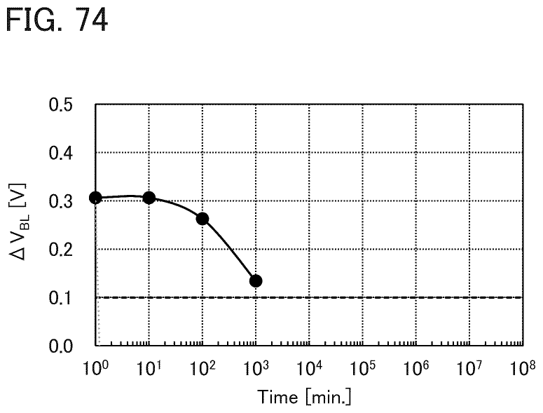

FIG. 74 shows the result of the retention measurement performed on Sample 810B, and FIG. 55A and FIG. 55B show the results of the retention measurement performed on Sample 810D. In each of FIG. 74, FIG. 55A, and FIG. 55B, the vertical axis represents ΔV_{BL}, and the horizontal axis represents the time. FIG. 74 shows the result of Sample 810B with the temperature condition set to room temperature, FIG. 55A shows the result of Sample 810D with the temperature condition set to room temperature, and FIG. 55B shows the result of Sample 810D with the temperature condition set to 85° C.

According to FIG. 74, ΔV_{BL} of Sample 810B was larger than or equal to 0.1 V until 1000 minutes in the case where the temperature condition was set to room temperature. Thus, data retention for 1000 minutes or longer was confirmed in the case where the ΔV_{BL} readable voltage was set to 0.1 V.

According to FIG. 55A and FIG. 55B, data retention for 1000 minutes or longer in Sample 810D was confirmed either in the case where the temperature condition was room temperature or 85° C.

The configuration, structure, method, or the like described in this example can be used in an appropriate combination with the configuration, structure, method, or the like described in the other embodiments and the like.

### Example 2

In this example, a storage device was fabricated by stacking a plurality of memory cell arrays similar to the structure illustrated in FIG. 22 and FIG. 30, and the results of observation of a cross-sectional TEM image, evaluation of electrical characteristics, and the like are described.

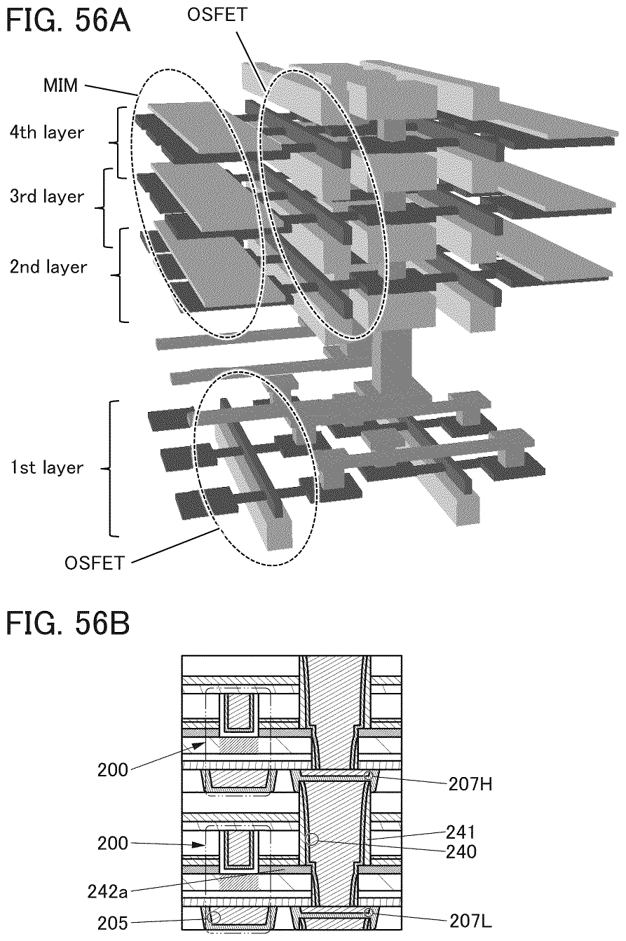

In this example, a sample including a storage device such as the one illustrated in FIG. 56A was fabricated. The sample has a structure in which four layers each including a transistor containing an oxide semiconductor (hereinafter referred to as an OSFET in some cases) are stacked (the four layers each including the OSFET are referred to as a 1st layer, a 2nd layer, a 3rd layer, and a 4th layer in some cases). Note that the 1st layer and the 2nd layer are electrically connected to each other through a wiring layer provided therebetween as illustrated in FIG. 56A. The 2nd layer to the 4th layer each include a capacitor (hereinafter referred to as MIM in some cases) that is electrically connected to one of a source and a drain of the OSFET. Note that the OSFET corresponds to the transistor 200 illustrated in FIG. 22 and FIG. 30, and the MIM corresponds to the capacitor 100 illustrated in FIG. 22 and FIG. 30; the above embodiment can be referred to for the details. Note that the MIM in this example is of a planar type, which is different in shape from the capacitors illustrated in FIG. 22 and FIG. 30. The sample in this example includes a TEG (Test Element Group) of a structure other than that illustrated in FIG. 56A.

The OSFETs included in the 1st layer to the 4th layer of the sample of this example were fabricated through similar processes. Thus, the OSFETs included in the 1st layer to the 4th layer have similar structures.

First, the structure of the OSFET is described. As illustrated in FIG. 15A to FIG. 15D, the OSFET includes the insulator 216 placed over a substrate (not illustrated), the conductor 205 (the conductor 205a and the conductor 205b) provided to be embedded in the insulator 216, the insulator 222 over the insulator 216 and the conductor 205, the insulator 224 over the insulator 222, the oxide 230 (the oxide 230a and the oxide 230b) over the insulator 224, the conductor 242a and the conductor 242b over the oxide 230, the insulator 271a over the conductor 242a, the insulator 271b over the conductor 242b, the insulator 250 (the insulator 250a to the insulator 250d) over the oxide 230, and the conductor 260 (the conductor 260a and the conductor 260b) over the insulator 250. The insulator 275 is provided over the insulator 271a and the insulator 271b, and the insulator 280 is provided over the insulator 275. The insulator 250 and the conductor 260 fill the opening provided in the insulator 280 and the insulator 275. The insulator 282 is provided over the insulator 280 and the conductor 260, and the insulator 283 is provided over the insulator 282.

The insulator 216 is a silicon oxide film deposited by a sputtering method. The conductor 205 is a stacked-layer film of the conductor 205a and the conductor 205b and is provided to fill the opening in the insulator 216. The conductor 205a is a tantalum nitride film deposited by a sputtering method. The conductor 205b is a titanium nitride film and a tungsten film over the titanium nitride film, which were deposited by a CVD method.

The insulator 222 is a stacked-layer film of a 3-nm-thick silicon nitride film and a 17-nm-thick hafnium oxide film over the silicon nitride film. The silicon nitride film was deposited by a PEALD method, and the hafnium oxide film was deposited by a thermal ALD method.

The insulator 224 is a 20-nm-thick silicon oxide film deposited by a sputtering method.

As the oxide 230a, 10-nm-thick In—Ga—Zn oxide deposited by a sputtering method was used. Note that the oxide 230a was deposited using an oxide target with In:Ga:Zn=1:3:2 [atomic ratio].

As the oxide 230b, 15-nm-thick In—Ga—Zn oxide deposited by a sputtering method was used. Note that the oxide 230b was deposited using an oxide target with In:Ga:Zn=1:1:1.2 [atomic ratio].

The conductor 242a and the conductor 242b are each a 20-nm-thick tantalum nitride film deposited by a sputtering method.

The insulator 271a and the insulator 271b are each a stacked-layer film of a 5-nm-thick silicon nitride film and a 10-nm-thick silicon oxide film over the silicon nitride film. The silicon nitride film and the silicon oxide film were each deposited by a sputtering method.

The insulator 275 is a 5-nm-thick silicon nitride film deposited by a PEALD method. The insulator 280 is a silicon oxide film deposited by a sputtering method.

As in the structure illustrated in FIG. 17A and FIG. 17B, the insulator 250 is a stacked-layer film having a four-layer structure in which the insulator 250c, the insulator 250a, the insulator 250d, and the insulator 250b are stacked in this order. The insulator 250c is a 1-nm-thick aluminum oxide film deposited by a thermal ALD method. The insulator 250a is a 4-nm-thick silicon oxide film deposited by a PEALD method. The insulator 250d is a 1.5-nm-thick hafnium oxide film deposited by a thermal ALD method. The insulator 250b is a 1-nm-thick silicon nitride film deposited by a PEALD method.

The conductor 260 is a stacked-layer film of the conductor 260a and the conductor 260b. The conductor 260a is a titanium nitride film deposited by a CVD method. The conductor 260b is a tungsten film deposited by a CVD method.

The insulator 282 is a 40-nm-thick aluminum oxide film deposited by a sputtering method. The insulator 283 is a 20-nm-thick silicon nitride film deposited by a sputtering method.

Next, the structure of the MIM is described. The MIM of the sample of this example is formed in the opening in the insulator 280 and the insulator 275 over the conductor 242b of the OSFET, and is formed in the order of the lower electrode, the dielectric film, and the upper electrode. Here, the conductor 242b of the OSFET serves also as the lower electrode of the MIM.

The dielectric film of the MIM is a stacked-layer film having a three-layer structure in which a 1-nm-thick aluminum oxide film, a 18-nm-thick hafnium oxide film, and a 1-nm-thick aluminum oxide film are stacked in this order. The aluminum oxide film and the hafnium oxide film were each deposited by a thermal ALD method.

The upper electrode of the MIM is a stacked-layer film of a titanium nitride film and a tungsten film over the titanium nitride film. The titanium nitride film and the tungsten film were each formed by a CVD method.

In the sample of this example, the conductor 240 functioning as a plug for electrically connecting the transistor 200 in an upper layer and the transistor 200 in a lower layer is formed as illustrated in FIG. 56B. The conductor 240 is formed in an opening provided in the insulator 280 and the like, and is formed in contact with the side surface and the top surface of the conductor 242a exposed in the opening. In FIG. 56B, unlike in FIG. 22 and FIG. 30, the upper portion of the conductor 240 is provided in contact with a conductor 207H that is formed in the same layer as the conductor 205 of the transistor 200 in the upper layer, and the lower portion of the conductor 240 is provided in contact with a conductor 207L that is formed in the same layer as the conductor 205 of the transistor 200 in the lower layer. The insulator 241 is provided in contact with the side surface of the conductor 240.

The conductor 240 is a stacked-layer film of the conductor 240a and the conductor 240b. The conductor 240a is a titanium nitride film deposited by a CVD method. The conductor 240b is a tungsten film deposited by a CVD method. The insulator 241 is a stacked-layer film of a 3-nm-thick aluminum oxide film and a 5-nm-thick silicon nitride film provided inside the aluminum oxide film. The aluminum oxide film was deposited by a thermal ALD method, and the silicon nitride film was deposited by a PEALD method.

The process temperature in the fabrication process of the sample including the above OSFET was set lower than or equal to 450° C. Here, the 1st layer is affected by a thermal budget in the fabrication process of the three layers after its fabrication, and the 2nd layer is affected by a thermal budget in the fabrication process of the two layers after its fabrication.

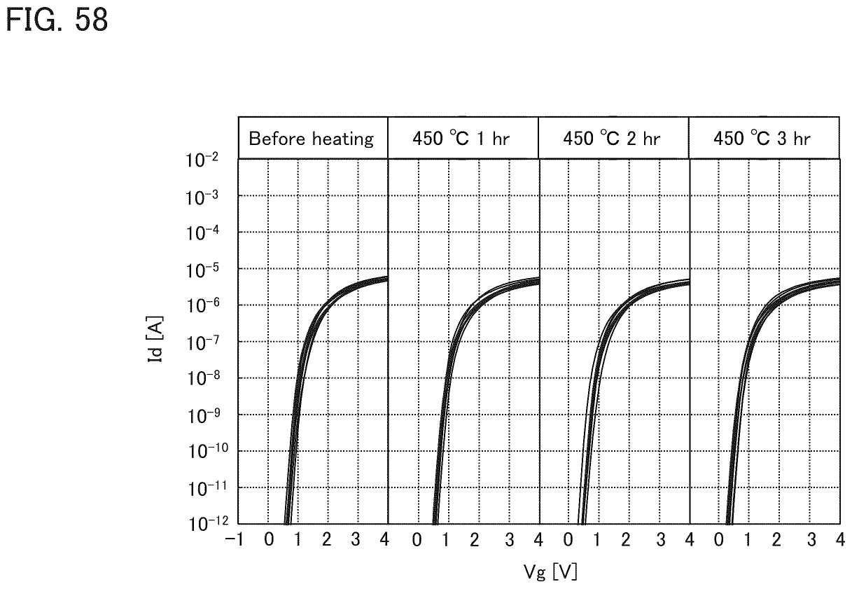

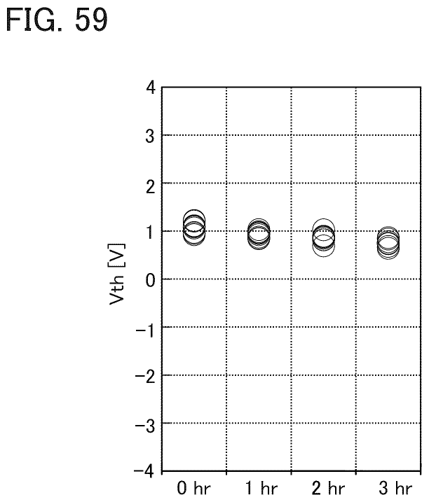

Thus, before the sample of this example was fabricated, transistors having a structure similar to that of the above-described OSFET were fabricated and subjected to heat treatment after the fabrication and then to evaluation of their electrical characteristics. The heat treatment and the evaluation of the electrical characteristics were performed in the order of the first measurement of the electrical characteristics, the first heat treatment, the second measurement of the electrical characteristics, the second heat treatment, the third measurement of the electrical characteristics, the third heat treatment, and the fourth measurement of the electrical characteristics. Each heat treatment was performed at 450° C. in a nitrogen atmosphere for one hour (“1 hr”). Thus, the heat treatment time is 2 hours (“2 hr”) after the second heat treatment, and the heat treatment time is 3 hours (“3 hr”) after the third heat treatment. FIG. 58 and FIG. 59 show the evaluation results of electrical characteristics. FIG. 58 shows the measurement results of Id-Vg characteristics, and FIG. 59 is a graph of the threshold voltage (Vth) calculated from the Id-Vg characteristics shown in FIG. 58. Since the first measurement of the electrical characteristics was performed before heat treatment was performed, the electrical characteristics measured in the first measurement are referred to as electrical characteristics before heating or electrical characteristics after a heat treatment time of 0 hours (“0 hr”) in some cases.

As shown in FIG. 58 and FIG. 59, the transistors exhibit stable characteristics regardless of the thermal budget. It can thus be considered that the OSFETs included in the 1st layer to the 4th layer also exhibit stable characteristics regardless of the thermal budget.

The OSFET of the above sample is a transistor having design values of a channel length of 60 nm and a channel width of 60 nm. Nine OSFETs were evaluated in each of the 1st layer to the 4th layer.

First, a cross-sectional STEM image of the sample was taken along a cross section including the 1st layer to the 4th layer. The cross-sectional STEM image was taken at an acceleration voltage of 200 kV using “HD-2700” produced by Hitachi High-Tech Corporation.

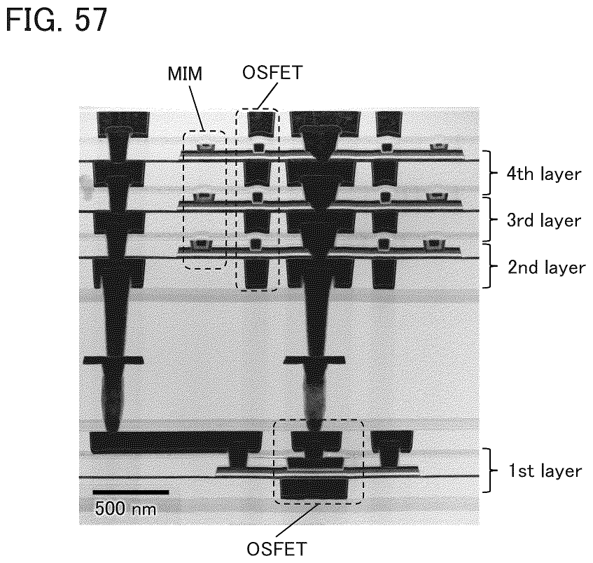

FIG. 57 shows the cross-sectional STEM image of the sample. As shown in FIG. 57, the cross sections of the OSFETs in the channel length direction can be observed in the 1st layer to the 4th layer of the sample of this example. In addition, as shown in FIG. 57, the cross sections of the MIMs can be observed in the 2nd layer to the 4th layer of the sample of this example. In this manner, fabrication of the sample in which the OSFETs and the MIMs were monolithically stacked was achieved.

Next, the electrical characteristics of the OSFETs in the 1st layer to the 4th layer were evaluated. For evaluation of the electrical characteristics, the Id-Vg characteristics (drain current-gate voltage characteristics) of each element were measured using a semiconductor parameter analyzer produced by Keysight Technologies. In the measurement of the Id-Vg characteristics, the drain potential Vd was 1.2 V, the source potential Vs was 0 V, the bottom gate potential Vbg was 0 V, and the top gate potential Vg was swept from −4.0 V to 4.0 V in increments of 0.1 V.

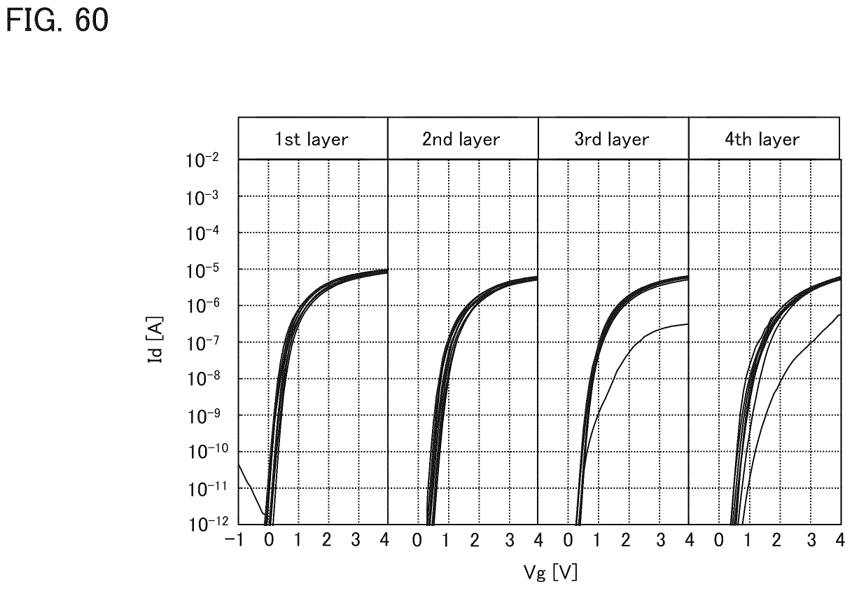

FIG. 60 shows the measurement results of the Id-Vg characteristics in the 1st layer to the 4th layer. In FIG. 60, the horizontal axis represents the top gate potential Vg [V], and the vertical axis represents the drain current Id [A]. Note that the horizontal axis shows a range from −1 V to 4 V.

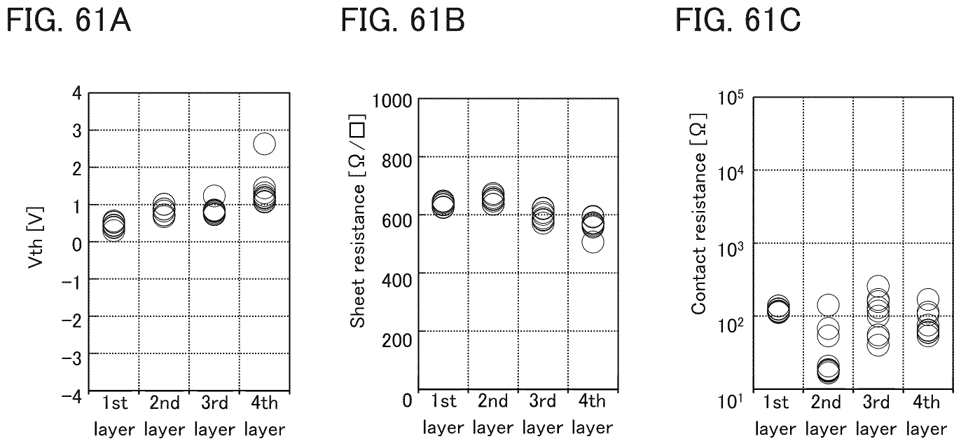

FIG. 61A shows the threshold voltage Vth calculated from the Id-Vg characteristics shown in FIG. 60. As shown in FIG. 60 and FIG. 61A, normally-off characteristics with a positive value of the threshold voltage Vth are exhibited in each of the 1st layer to the 4th layer. In addition, the drain current Id is lower than or equal to 10⁻¹² A in the range where the top gate potential Vg is negative, and a sufficient reduction in off-state current can be observed. Moreover, the electrical characteristics and the threshold voltage Vth in each of the 1st layer to the 4th layer show no clear dependence on the stacking order.

FIG. 61B shows the measurement results of the sheet resistance of the SD electrode (the conductor 242a or the conductor 242b illustrated in FIG. 22) of the OSFET in each of the 1st layer to the 4th layer. The sheet resistance of the SD electrode of the OSFET was measured using a TEG that was formed for measurement of the conductor 242a or the conductor 242b of the OSFET. FIG. 61C shows the measurement results of the contact resistance of an electrode functioning as a plug in the OSFET (the conductor 240a illustrated in FIG. 20B) in each of the 1st layer to the 4th layer. The contact resistance of the electrode functioning as a plug in the OSFET was measured using a TEG that was formed to correspond to the conductor 242a, the conductor 240a, and the conductor 112 illustrated in FIG. 20B.

As shown in FIG. 61B and FIG. 61C, the sheet resistance of the SD electrode of the OSFET and the contact resistance of the electrode functioning as a plug in the OSFET also show no clear dependence on the stacking order.

As described above, the OSFET in each of the 1st layer to the 4th layer exhibits stable characteristics regardless of the thermal budget, which is similar to the results shown in FIG. 58 and FIG. 59.

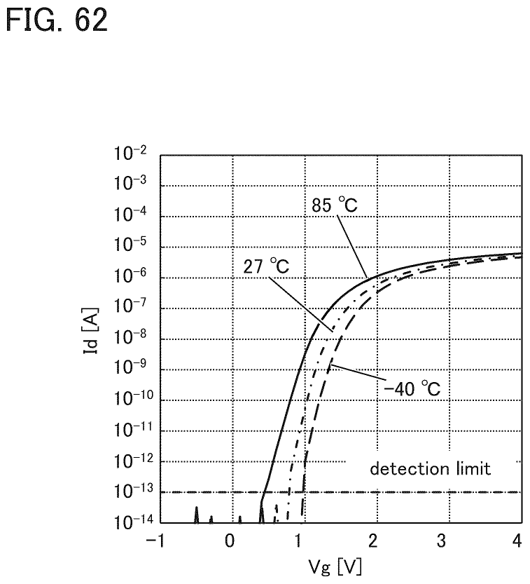

FIG. 62 shows the results of examining the temperature dependence of the Id-Vg characteristics of the OSFET in the 3rd layer. As shown in FIG. 62, the Id-Vg characteristics were measured at measurement temperatures of −40° C., 27° C., and 85° C. Note that the dashed line in FIG. 62 indicates the lower measurement limit (“detection limit”). The off-state current has been confirmed to be lower than or equal to the lower measurement limit (10⁻¹³ A) under any of the temperature conditions.

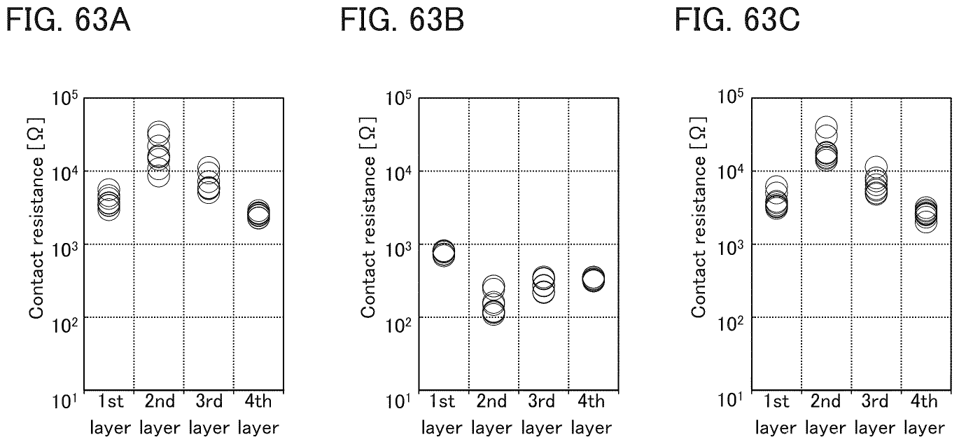

In addition, the contact resistances between the conductor 207L and the conductor 242a, between the conductor 207L and the conductor 207H, and between the conductor 242a and the conductor 207H in the structure illustrated in FIG. 56B were measured in each of the 1st layer to the 4th layer. FIG. 63A to FIG. 63C show the measurement results of the contact resistances. Here, FIG. 63A shows the contact resistance between the conductor 207L and the conductor 242a, FIG. 63B shows the contact resistance between the conductor 207L and the conductor 207H, and FIG. 63C shows the contact resistance between the conductor 242a and the conductor 207H. As shown in FIG. 63A to FIG. 63C, electrical continuity is established between the conductor 207L and the conductor 242a, between the conductor 207L and the conductor 207H, and between the conductor 242a and the conductor 207H in each of the 1st layer to the 4th layer.

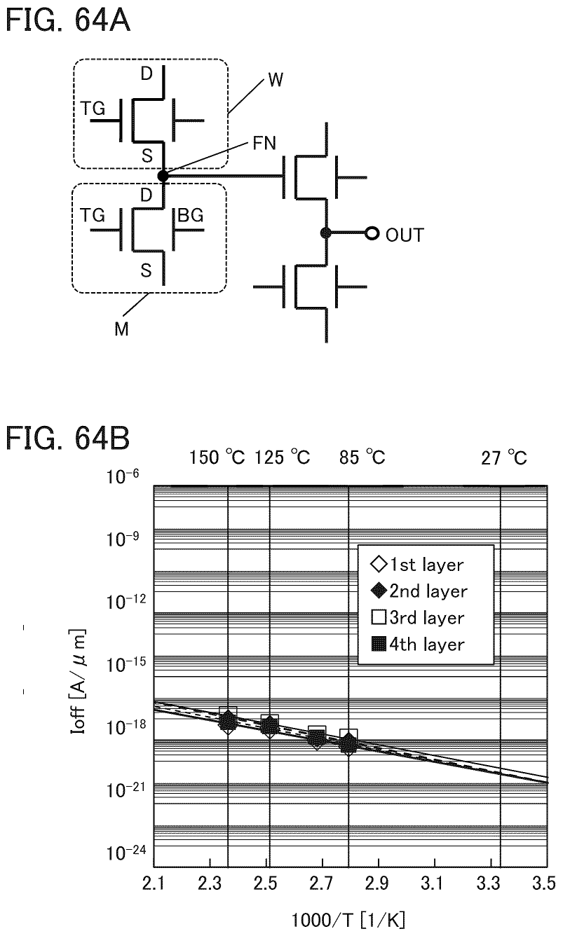

In addition, the leakage current of the OSFET in each of the 1st layer to the 4th layer was evaluated using a TEG of a circuit illustrated in FIG. 64A.

As illustrated in FIG. 64A, a source of a transistor W is electrically connected to a node FN, a drain of a transistor M is electrically connected to the node FN, and a reading circuit is electrically connected to the node FN. In the reading circuit, two transistors are connected in series; a gate of one of the transistors is electrically connected to the node FN, and a node to which sources or drains of both of the transistors are connected is electrically connected to an output terminal OUT.

The transistor W is a writing transistor, and the transistor M is a transistor subjected to evaluation of the leakage current. Although the transistor M is illustrated as one transistor in FIG. 64A, the transistor M is composed of 20000 parallel-connected OSFETs included in the sample (transistors each having design values of a channel length of 60 nm and a channel width of 60 nm). That is, the transistor M corresponds to a transistor with a channel length of 60 nm and a channel width of 1.2 mm.

Next, a method for deriving the leakage current is described. A potential of 1.2 V was applied to a drain of the transistor W to turn on the transistor W, and charge was accumulated so that the potential of the node FN became 1.2 V. After that, a potential of −3 V was applied to a gate of the transistor W to turn off the transistor W. The potential of a source of the transistor M was set to 0 V and the potential of a back gate of the transistor M was set to −3 V to turn off the transistor M. The potential of a top gate of the transistor M was set to −2 V. The above state was held for a certain time, a change in the potential of the node FN over time was read by the reading circuit, and a leakage current value was derived from the read value.

FIG. 64B shows the measurement results of the leakage current Ioff measured in environments at temperatures of 85° C., 100° C., 125° C., and 150° C. In FIG. 64B, the horizontal axis represents the value obtained by multiplying the inverse of the temperature by 1000 [1/K], and the vertical axis represents the leakage current Ioff per unit channel width [A/μm] of the transistor M on a logarithmic scale.

FIG. 64B reveals that the leakage current of the OSFET is sufficiently small with no significant difference between the 1st layer to the 4th layer.

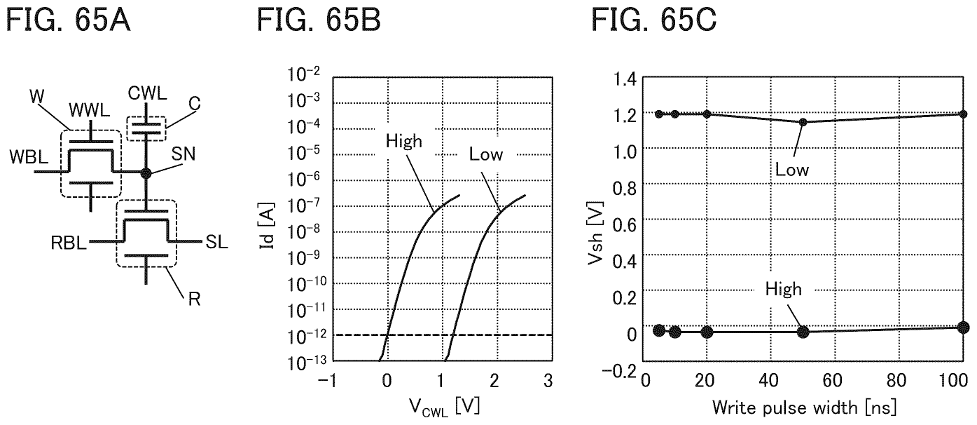

In addition, the retention characteristics of the OSFET in the 3rd layer was evaluated using a TEG of a circuit illustrated in FIG. 65A.

The TEG illustrated in FIG. 65A is a TEG of the NOSRAM described in the above embodiment. As illustrated in FIG. 65A, one of a source and a drain of a transistor W is electrically connected to a node SN, a top gate of a transistor R is electrically connected to the node SN, and one of a pair of electrodes of a capacitor C is electrically connected to the node SN. A wiring WWL is electrically connected to a top gate of the transistor W, and a wiring WBL is electrically connected to the other of the source and the drain of the transistor W. A wiring RBL is electrically connected to one of a source and a drain of the transistor R, and a wiring SL is electrically connected to the other of the source and the drain of the transistor R. A wiring CWL is electrically connected to the other of the pair of electrodes of the capacitor C.

In this example, Id-V_{CWL} characteristics of the above-described NOSRAM-TEG at the time of storing “High” data and at the time of storing “Low” data were measured. Here, to write the “High” data, 1.2 V was applied to the wiring WBL, and charge was accumulated in the capacitor C. To write the “Low” data, 0 V was applied to the wiring WBL, and charge was accumulated in the capacitor C. In the NOSRAM-TEG to which the “High” or “Low” data was written, the current Id of the transistor R was measured with the potential V_{CWL} of the wiring CWL scanned from −2.5 V to +2.5 V. At that time, the potential of the wiring WWL was set to −1.5 V, the potential of the wiring WBL to 0 V, the potential of the wiring RBL to 1.2 V, and the potential of the wiring SL to 0 V.

FIG. 65B shows the measurement results of the Id-V_{CWL} characteristics. In FIG. 65B, the horizontal axis represents the potential V_{CWL} [V] of the wiring CWL, and the vertical axis represents the current Id [A] of the transistor R. Note that the horizontal axis shows a range from −1 V to 3 V. As shown in FIG. 65B, the Id-V_{CWL} curve of the case of the “High” data was sufficiently shifted with respect to the Id-V_{CWL} curve of the case of the “Low” data, and the TEG of this example has been confirmed to operate normally as a NOSRAM memory cell.

Here, the potential V_{CWL} at the intersection of the Id-V_{CWL} curve with Id=10⁻¹² A is referred to as a potential Vsh. FIG. 65C shows the results of calculating the potential Vsh from the Id-V_{CWL} characteristics measured with the “High” or “Low” data writing time (“Write pulse width”) set to 5 ns, 10 ns, 20 ns, 50 ns, or 100 ns. Here, the data writing time (“Write pulse width”) refers to a period of time in which a high potential is applied to the wiring WWL and the transistor W is kept in an on state to write the data.

As shown in FIG. 65C, the potential Vsh shows a sufficient difference between the “High” data and the “Low” data even when the writing time is 5 ns. This demonstrates that data can be written to the memory cell of this example even in a short time of approximately 5 ns.

In addition, the above-described NOSRAM-TEG was subjected to a data retention evaluation test. In the data retention evaluation test, data was written first to the node SN so that the potential V_{SN} became approximately 2 V. Then, the potential of the node SN was retained by setting the potential of the wiring WBL to 0 V, the potential of the wiring WWL to −1.5 V, the wiring RBL to 1.2 V, the potential of the wiring SL to 0 V, and the potential of the wiring CWL to 1.3 V. The current Id of the transistor R was regularly measured while the potentials of the wirings were maintained until a predetermined time elapsed. Before the test, the Id-Vg characteristics of the transistor R were obtained, and the potential V_{SN} was calculated from the measured current Id and the Id-Vg curve of the transistor R.

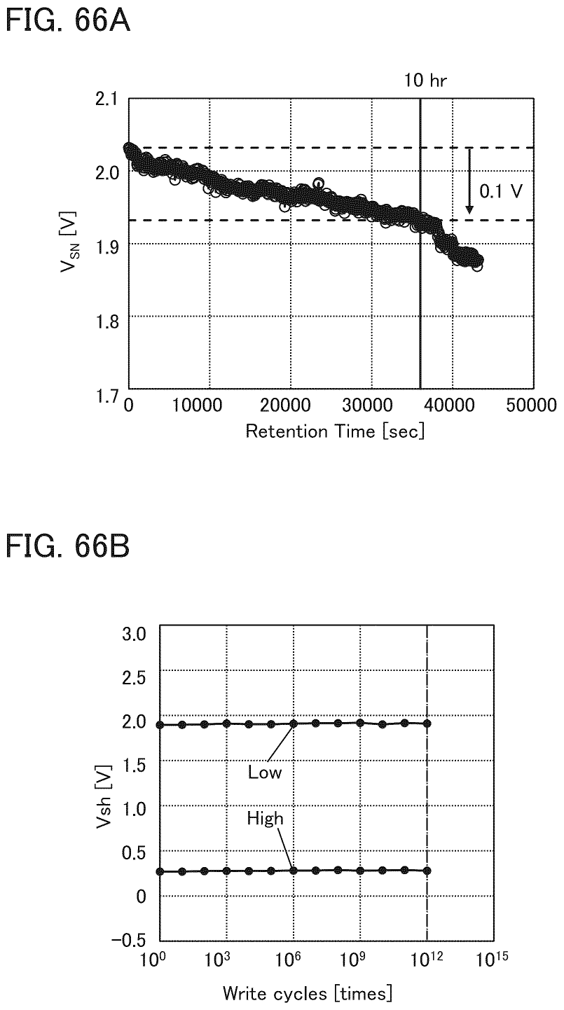

FIG. 66A shows the result of the data retention evaluation test. In FIG. 66A, the horizontal axis represents the retention time [sec], and the vertical axis represents the potential V_{SN} [V]. As shown in FIG. 66A, the voltage decrease of the node SN was approximately 0.1 V at a measurement time of 10 hours. This demonstrates that the memory cell of this example has sufficient data retention capability.

In addition, the above-described NOSRAM-TEG was subjected to a data rewriting evaluation test. In the data rewriting evaluation test, after data was written a predetermined number of times, the Id-V_{CWL} curve was measured and the potential Vsh was calculated as done for FIG. 65B and FIG. 65C. Then, these processes were repeated while the number of times of data writing was increased.

FIG. 66B shows the result of the data rewriting evaluation test. In FIG. 66B, the horizontal axis represents the number of times of data writing (“Write cycles”) [times], and the vertical axis represents the potential Vsh [V]. As shown in FIG. 66B, the potential Vsh shows a sufficient difference between the “High” data and the “Low” data even after 10¹² times of rewriting. This demonstrates that data can be normally written to the memory cell of this example even when rewriting is performed 10¹² times.

In the above-described sample, the SD electrode of the OSFET was formed using a tantalum nitride film. For miniaturization of the OSFET, the contact resistance between the SD electrode and the electrode functioning as a plug can be reduced when a conductive film with a higher conductivity, such as a tungsten film, is stacked and used for the SD electrode as illustrated in FIG. 17A.

A sample in which a 20-nm-thick tantalum nitride film (TaNₓ) was used as the SD electrode and a sample in which a stacked-layer film of a 5-nm-thick tantalum nitride film and a 15-nm-thick tungsten film formed thereover (TaNₓ\W) was used as the SD electrode were prepared, and the contact resistances and the sheet resistances thereof were measured. Note that the contact resistances were measured with plugs with different contact diameters provided in the above samples.

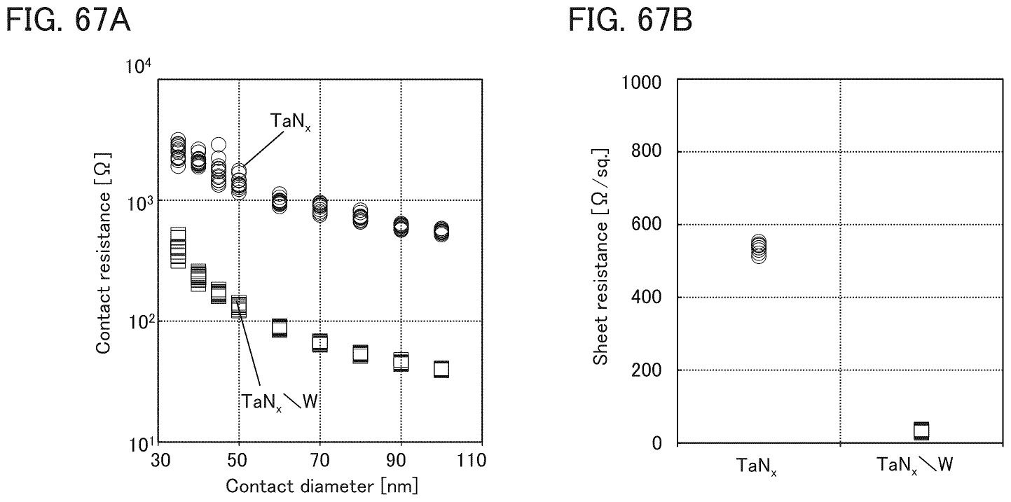

FIG. 67A shows the measurement results of the contact resistances. FIG. 67A reveals that the use of the stacked-layer film of tantalum nitride and tungsten as the SD electrode can inhibit an increase in contact resistance even when the contact diameter is decreased.

FIG. 67B shows the measurement results of the sheet resistances. FIG. 67B reveals that the use of the stacked-layer film of tantalum nitride and tungsten as the SD electrode can reduce the sheet resistance.

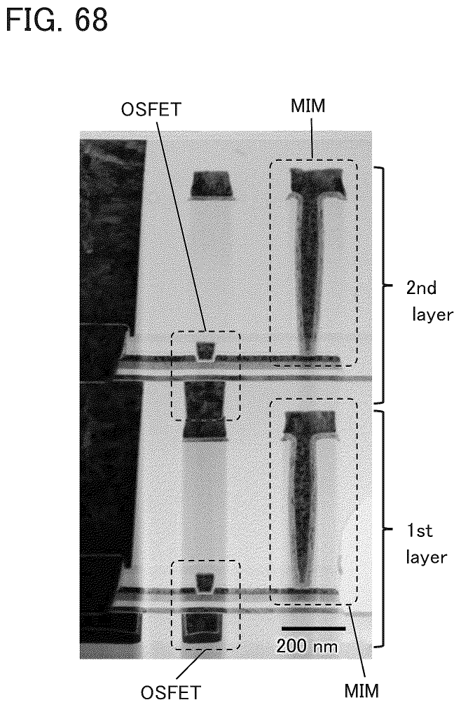

In each of the above samples, a planar-type capacitor was used as the MIM. In the case of fabricating the DOSRAM described in the above embodiment, a capacitor with high capacity is required to be formed. Memory cells each including a trench-type MIM illustrated in FIG. 68 were fabricated as memory cells each including a high-capacity capacitor. As illustrated in FIG. 68, the memory cells have a two-layer structure, and the memory cell in each layer includes the OSFET and the MIM.

The lower electrode of the MIM is a titanium nitride film deposited by a CVD method. The upper electrode of the MIM is a stacked-layer film of a titanium nitride film and a tungsten film over the titanium nitride film which were deposited by a CVD method. The dielectric film of the MIM is a stacked-layer film having a three-layer structure in which a 4-nm-thick zirconium oxide film, a 0.5-nm-thick aluminum oxide film, and a 4-nm-thick zirconium oxide film are stacked in this order. The zirconium oxide film and the aluminum oxide film were each deposited by a thermal ALD method. The capacity of the MIM was increased by using ZAZ, which is a high-dielectric-constant material, as the dielectric in this manner.

This example can be combined with the embodiments and the other example as appropriate.

### REFERENCE NUMERALS

100A: capacitor, 100: capacitor, 110a: conductor, 110b: conductor, 110c: conductor, 110: conductor, 112: conductor, 115: conductor, 120a: conductor, 120b: conductor, 120: conductor, 125: conductor, 130: insulator, 132: insulator, 140: conductor, 142: insulator, 145: insulator, 150: insulator, 151: insulator, 152a: insulator, 152b: insulator, 152: insulator, 153: conductor, 154: insulator, 155a: insulator, 155b: insulator, 155: insulator, 156: insulator, 160a: conductor, 160b: conductor, 160: conductor, 168: opening, 200A: transistor, 200B: transistor, 200C: transistor, 200D: transistor, 200E: transistor, 200: transistor, 205a: conductor, 205b: conductor, 205: conductor, 207H: conductor, 207L: conductor, 209: conductor, 210: insulator, 215a: insulator, 215b: insulator, 215: insulator, 216: insulator, 217: insulator, 218: conductor, 222a: insulator, 222b: insulator, 222c: insulator, 222d: insulator, 222: insulator, 224a: insulator, 224c: insulator, 224d: insulator, 224: insulator, 230a: oxide, 230b: oxide, 230bi: region, 230bna: region, 230bnb: region, 230i: region, 230na: region, 230nb: region, 230: oxide, 240a: conductor, 240b: conductor, 240: conductor, 241a: insulator, 241b: insulator, 241: insulator, 242a: conductor, 242b: conductor, 246: conductor, 250a: insulator, 250b: insulator, 250c: insulator, 250d: insulator, 250: insulator, 255: insulator, 260a: conductor, 260b: conductor, 260: conductor, 261: conductor, 265: sealing portion, 271a: insulator, 271b: insulator, 274: insulator, 275: insulator, 280: insulator, 282: insulator, 283: insulator, 284: insulator, 285: insulator, 286: insulator, 287: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 400: opening region, 500: semiconductor device, 700: electronic component, 702: printed circuit board, 704: mounting board, 710: semiconductor device, 711: mold, 712: land, 713: electrode pad, 714: wire, 715: driver circuit layer, 716: storage layer, 730: electronic component, 731: interposer, 732: package substrate, 733: electrode, 735: semiconductor device, 1001: wiring, 1002: wiring, 1003: wiring, 1004: wiring, 1005: wiring, 1006: wiring, 1007: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: storage device, 1411: peripheral circuit, 1420: row circuit, 1430: column circuit, 1440: output circuit, 1460: control logic circuit, 1470[1]: memory cell array, 1470[2]: memory cell array, 1470[m]: memory cell array, 1470: memory cell array, 1471: memory cell, 1472: memory cell, 1473: memory cell, 1474: memory cell, 1475: memory cell, 1476: memory cell, 1477: memory cell, 1478: memory cell, 1479: memory cell, 1480: memory cell, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: storage device, 7003: storage, 7004: storage area network

1. A semiconductor device comprising:
a first stack, a semiconductor layer under the first stack, and a second stack under the semiconductor layer,
wherein the semiconductor layer comprises a first region, and a second region and a third region provided such that the first region is sandwiched therebetween,
wherein the first stack and the second stack are provided symmetrically with respect to the first region,
wherein the first stack comprises a first insulator and a second insulator over the first insulator,
wherein the second stack comprises a third insulator and a fourth insulator under the third insulator,
wherein the second insulator is less permeable to hydrogen than the first insulator is,
wherein the fourth insulator is less permeable to hydrogen than the third insulator is,
wherein the first insulator and the third insulator each comprise silicon and oxygen, and
wherein the second insulator and the fourth insulator each comprise silicon and nitrogen.

2. The semiconductor device according to claim 1,
wherein the third insulator has an island shape, and
wherein a side end portion of the third insulator is aligned with a side end portion of the semiconductor layer in a cross-sectional view.

3. The semiconductor device according to claim 1,
wherein the first stack further comprises a fifth insulator under the first insulator,
wherein the second stack further comprises a sixth insulator over the third insulator,
wherein the fifth insulator is less permeable to oxygen than the first insulator is,
wherein the sixth insulator is less permeable to oxygen than the second insulator is, and
wherein the fifth insulator and the sixth insulator each comprise aluminum.

4. The semiconductor device according to claim 3,
wherein the third insulator and the sixth insulator form a stacked-layer structure,
wherein the stacked-layer structure has an island shape, and
wherein a side end portion of the stacked-layer structure is aligned with a side end portion of the semiconductor layer in a cross-sectional view.

5. A semiconductor device comprising:
a first stack, a semiconductor layer under the first stack, and a second stack under the semiconductor layer,
wherein the semiconductor layer comprises a first region, and a second region and a third region provided such that the first region is sandwiched therebetween,
wherein the first stack and the second stack are provided symmetrically with respect to the first region.
wherein the first stack comprises a first insulator, a second insulator over the first insulator, and a third insulator over the second insulator,
wherein the second stack comprises a first metal oxide, a fourth insulator under the first metal oxide, and a fifth insulator under the fourth insulator,
wherein the first insulator is less permeable to oxygen than the second insulator is,
wherein the third insulator is less permeable to hydrogen than the second insulator is,
wherein the first metal oxide is less permeable to oxygen than the fourth insulator is,
wherein the fifth insulator is less permeable to hydrogen than the fourth insulator is,
wherein the first insulator and the first metal oxide each comprise at least one of gallium and aluminum,
wherein the second insulator and the fourth insulator each comprise silicon and oxygen, and
wherein the third insulator and the fifth insulator each comprise silicon and nitrogen.

6. The semiconductor device according to claim 5,
wherein the semiconductor layer comprises a second metal oxide,
wherein the first metal oxide and the second metal oxide each comprise indium, and
wherein an atomic ratio of at least one of gallium and aluminum to indium in the first metal oxide is higher than an atomic ratio of at least one of gallium and aluminum to indium in the second metal oxide.

7. The semiconductor device according to claim 5, further comprising:
a sixth insulator between the fourth insulator and the fifth insulator,
wherein the sixth insulator is configured to capture or fix hydrogen.

8. The semiconductor device according to claim 7, further comprising:
a seventh insulator between the second insulator and the third insulator,
wherein the seventh insulator is configured to capture or fix hydrogen.

9. The semiconductor device according to claim 1, further comprising:
a first conductor and a second conductor,
wherein the first conductor is positioned above the first stack, and
wherein the second conductor is positioned below the second stack.

10. The semiconductor device according to claim 9, further comprising:
a third conductor and a fourth conductor,
wherein the second region overlaps with the third conductor, and
wherein the third region overlaps with the fourth conductor.

11. A storage device comprising:
the semiconductor device according to claim 10 and a capacitor,
wherein the capacitor is a ferroelectric capacitor.

12. The semiconductor device according to claim 5, further comprising:
a first conductor and a second conductor,
wherein the first conductor is positioned above the first stack, and
wherein the second conductor is positioned below the second stack.

13. The semiconductor device according to claim 12, further comprising:
a third conductor and a fourth conductor,
wherein the second region overlaps with the third conductor, and
wherein the third region overlaps with the fourth conductor.

14. A storage device comprising:
the semiconductor device according to claim 13 and a capacitor,
wherein the capacitor is a ferroelectric capacitor.
